(19) United States
(12) Patent Application Publication
(10) Pub. No.: US 2025/0008721 A1
(43) Pub. Date: Jan. 2, 2025

(54) SEMICONDUCTOR DEVICE AND ELECTRONIC DEVICE

(71) Applicant: SEMICONDUCTOR ENERGY LABORATORY CO., LTD., Atsugi-shi, Kanagawa-ken (JP)

(72) Inventors: Shunpei YAMAZAKI, Setagaya, Tokyo (JP); Hitoshi KUNITAKE, Machida, Tokyo (JP); Rihito WADA, Atsugi, Kanagawa (JP); Kiyoshi KATO, Atsugi, Kanagawa (JP); Tatsuya ONUKI, Atsugi, Kanagawa (JP)

(21) Appl. No.: 18/706,096

(22) PCT Filed: Oct. 21, 2022
(86) PCT No.: PCT/IB2022/060118

§ 371 Date: Apr. 30, 2024

(30) Foreign Application Priority Data
Nov. 5, 2021 (JP) 2021-181418
Nov. 5, 2021 (JP) 2021-181425
Nov. 19, 2021 (JP) 2021-188519

(51) Int. Cl. H10B 12/00

(52) U.S. Cl. CPC H10B 12/00

(57) ABSTRACT

A small semiconductor device is provided. The semiconductor device includes a first layer and a second layer over the first layer. The first layer includes a p-channel first transistor containing silicon in a channel formation region. The second layer includes an n-channel second transistor containing a metal oxide in a channel formation region. The first transistor and the second transistor form a CMOS circuit. A channel length of the first transistor is longer than a channel length of the second transistor.

### TECHNICAL FIELD

One embodiment of the present invention relates to a semiconductor device and an electronic device.

Note that one embodiment of the present invention is not limited to the above technical field. Examples of the technical field of one embodiment of the present invention disclosed in this specification and the like include a semiconductor device, a display device, a light-emitting device, a power storage device, a memory device, an electronic device, a lighting device, an input device, an input/output device, a driving method thereof, and a manufacturing method thereof.

### BACKGROUND ART

In recent years, semiconductor devices have been developed; an LSI, a CPU (Central Processing Unit), a memory, and the like have been mainly used for semiconductor devices. A CPU is an assembly of semiconductor elements; the CPU includes an integrated circuit (including at least a transistor and a memory) formed into a chip by processing a semiconductor wafer, and is provided with an electrode serving as a connection terminal.

An integrated circuit (IC) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an integrated circuit and an image display device (also simply referred to as a display device). A silicon-based semiconductor material is widely known as a semiconductor thin film applicable to the transistor and further, an oxide semiconductor has been attracting attention as another material.

It is known that a transistor using an oxide semiconductor has an extremely low leakage current in a non-conduction state. For example, Patent Document 1 discloses a low-power-consumption CPU utilizing a feature of a low leakage current of the transistor using an oxide semiconductor. Furthermore, for example, Patent Document 2 discloses a memory device that can retain stored contents for a long time by utilizing a feature of a low leakage current of the transistor using an oxide semiconductor.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

### Problems to be Solved by the Invention

An object of one embodiment of the present invention is to provide a small semiconductor device. Another object of one embodiment of the present invention is to provide a highly reliable semiconductor device. Another object of one embodiment of the present invention is to provide a novel semiconductor device.

Note that the description of these objects does not preclude the presence of other objects. In one embodiment of the present invention, there is no need to achieve all of these objects. Note that objects other than these can be derived from the descriptions of the specification, the drawings, the claims, and the like.

### Means for Solving the Problems

One embodiment of the present invention is a semiconductor device including a first layer and a second layer over the first layer; the first layer includes a p-channel first transistor containing silicon in a first channel formation region; the second layer includes an n-channel second transistor containing a metal oxide in a second channel formation region; the first transistor and the second transistor form a CMOS circuit; and a channel length of the first transistor is longer than a channel length of the second transistor.

In the above embodiment, the channel length of the first transistor may be greater than or equal to 15 nm, and the channel length of the second transistor may be less than 15 nm.

In the above embodiment, the channel length of the first transistor may be greater than or equal to 15 nm and less than or equal to 40 nm, and the channel length of the second transistor may be greater than or equal to 3 nm and less than 15 nm.

In the above embodiment, the first layer may include a single crystal silicon substrate, and the first transistor may include the first channel formation region in the single crystal silicon substrate.

In the above embodiment, the second layer may include a memory circuit.

In the above embodiment, the memory circuit may include a third transistor, a fourth transistor, and a capacitor; one of a source and a drain of the third transistor may be electrically connected to a gate of the fourth transistor; and the gate of the fourth transistor may be electrically connected to one electrode of the capacitor.

In the above embodiment, the third transistor and the fourth transistor may each contain the metal oxide of the second channel formation region.

An electronic device including the semiconductor device of one embodiment of the present invention and a display portion is also one embodiment of the present invention.

### Effect of the Invention

According to one embodiment of the present invention, a small semiconductor device can be provided. According to another embodiment of the present invention, a highly reliable semiconductor device can be provided. According to another embodiment of the present invention, a novel semiconductor device can be provided.

Note that the description of these effects does not preclude the presence of other effects. Note that one embodiment of the present invention does not need to have all of these effects. Note that effects other than these can be derived from the descriptions of the specification, the drawings, the claims, and the like.

### BRIEF DESCRIPTION OF THE DRAWINGS

FIG. 1 is a block diagram illustrating a structure example of a semiconductor device.

FIG. 2 is a perspective view illustrating a structure example of a semiconductor device.

FIG. 3 is a circuit diagram illustrating a structure example of a CMOS circuit.

FIG. 4A to FIG. 4H are circuit diagrams illustrating structure examples of memory circuits.

FIG. 5 is a perspective view illustrating a structure example of a semiconductor device.

FIG. 6 is a circuit diagram illustrating a structure example of a memory circuit.

FIG. 7A is a top view illustrating a structure example of a transistor. FIG. 7B to FIG. 7D are cross-sectional views illustrating a structure example of the transistor.

FIG. 8A and FIG. 8B are cross-sectional views illustrating structure examples of a transistor.

FIG. 9 is a cross-sectional view illustrating a structure example of a transistor.

FIG. 10A and FIG. 10B are cross-sectional views illustrating a structure example of a transistor.

FIG. 11A and FIG. 11B are cross-sectional views illustrating a structure example of a transistor.

FIG. 12A and FIG. 12B are cross-sectional views illustrating structure examples of transistors.

FIG. 13A to FIG. 13F are cross-sectional views illustrating structure examples of a transistor.

FIG. 14 is a cross-sectional view illustrating a structure example of a semiconductor device.

FIG. 15 is a cross-sectional view illustrating a structure example of a semiconductor device.

FIG. 16 is a cross-sectional view illustrating a structure example of a semiconductor device.

FIG. 17 is a cross-sectional view illustrating a structure example of a semiconductor device.

FIG. 18 is a cross-sectional view illustrating a structure example of a semiconductor device.

FIG. 19 is a cross-sectional view illustrating a structure example of a semiconductor device.

FIG. 20 is a cross-sectional view illustrating a structure example of a semiconductor device.

FIG. 21A and FIG. 21B are block diagrams illustrating structure examples of a semiconductor device.

FIG. 22A and FIG. 22B are diagrams illustrating examples of electronic components.

FIG. 23A to FIG. 23E are diagrams illustrating examples of memory devices.

FIG. 24A to FIG. 24H are diagrams illustrating examples of electronic devices.

FIG. 25A and FIG. 25B are diagrams showing changes in power consumption of normally-off processors.

FIG. 26 is a diagram illustrating a measurement circuit.

FIG. 27 is a graph showing temperature dependence of off-state current.

### MODE FOR CARRYING OUT THE INVENTION

Embodiments are described below with reference to the drawings. However, the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

Note that ordinal numbers such as “first” and “second” in this specification and the like are used in order to avoid confusion among components and do not denote the priority or the order such as the order of steps or the stacking order. A term without an ordinal number in this specification and the like may be provided with an ordinal number in the SCOPE OF CLAIMS in order to avoid confusion among components. Furthermore, a term with an ordinal number in this specification and the like may be provided with a different ordinal number in the SCOPE OF CLAIMS. As another example, even when a term is provided with an ordinal number in this specification, the ordinal number might be omitted in the SCOPE OF CLAIMS.

In the drawings, the size, the layer thickness, or the region is exaggerated for clarity in some cases. Therefore, they are not limited to the illustrated scale. Note that the drawings schematically show ideal examples, and embodiments of the present invention are not limited to shapes, values, and the like shown in the drawings.

Furthermore, unless otherwise specified, off-state current in this specification and the like refers to drain current of a transistor in an off state (also referred to as a non-conduction state or a cutoff state). Unless otherwise specified, an off state refers to, in an n-channel transistor, a state where a voltage V_{gs} between its gate and source is lower than a threshold voltage Vₜₕ (in a p-channel transistor, higher than Vth).

In this specification and the like, a metal oxide is an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in an active layer of a transistor, the metal oxide is referred to as an oxide semiconductor in some cases. That is, an OS transistor can also be called a transistor including a metal oxide or an oxide semiconductor.

An integrated structure with the above-described oxide semiconductor (OS) may be referred to as an OSLSI.

An oxide semiconductor used for an OSLSI contains at least indium (In) and oxygen (O). Typical examples include indium gallium zinc oxide (IGZO), indium zinc oxide (IZO (registered trademark)), and indium oxide (IO). Furthermore, the oxide semiconductor may contain hydrogen as an impurity.

### Embodiment 1

In this embodiment, a semiconductor device of one embodiment of the present invention is described with reference to drawings.

One embodiment of the present invention relates to a semiconductor device including a first layer and a second layer over the first layer. A transistor containing silicon in a channel formation region (hereinafter also referred to as a Si transistor or a SiFET) is provided in the first layer. Specifically, the first layer includes a single crystal silicon substrate, and the Si transistor can include the channel formation region in the single crystal silicon substrate. A transistor containing a metal oxide in a channel formation region (hereinafter also referred to as an OS transistor or an OSFET) is provided in the second layer. When the semiconductor device has a stacked-layer structure as described above, the number of transistors provided in one layer can be reduced and the area occupied by the semiconductor device can be reduced. Thus, the semiconductor device of one embodiment of the present invention can be reduced in size.

In this specification and the like, a transistor containing single crystal silicon in a channel formation region is referred to as a single crystal Si transistor. For example, a transistor including a channel formation region in a single crystal silicon substrate is a single crystal Si transistor.

In the semiconductor device of one embodiment of the present invention, a first transistor that is a p-channel Si transistor provided in the first layer and a second transistor that is an n-channel OS transistor provided in the second layer form a CMOS (Complementary Metal Oxide Semiconductor) circuit. Here, when the channel lengths, the channel widths, and the like are equal to each other, the mobility of the Si transistor, for example, a single crystal Si transistor is higher than the mobility of the OS transistor. Meanwhile, when the difference between the mobility of the p-channel transistor and the mobility of the n-channel transistor that form the CMOS is large, the CMOS circuit is not driven normally in some cases.

Thus, in one embodiment of the present invention, the channel length of the first transistor that is a Si transistor is longer than the channel length of the second transistor that is an OS transistor. As the channel length becomes longer, the electric resistance between the source and the drain becomes higher and the mobility becomes lower; thus, when the channel length of the first transistor is longer than the channel length of the second transistor, the difference in the mobility between the first transistor and the second transistor can be smaller than when the channel lengths of the first transistor and the second transistor are equal to each other. Accordingly, the difference in the on-state current between the first transistor and the second transistor can be small; thus, even when the first transistor that is a Si transistor and the second transistor that is an OS transistor form the CMOS circuit, the CMOS circuit can be driven normally.

Specifically, in consideration of easy fabrication of the second transistor, it is preferable that the channel length of the first transistor be greater than or equal to 15 nm and the channel length of the second transistor be less than 15 nm, for example. Alternatively, it is preferable that the channel length of the first transistor be greater than or equal to 15 nm and less than or equal to 40 nm and the channel length of the second transistor be greater than or equal to 3 nm and less than 15 nm. The channel length of the second transistor can be typically greater than or equal to 5 nm and less than or equal to 8 nm.

Note that when each of the channel lengths of the first transistor and the second transistor is within the above range, the off-state current (Ioff) of the second transistor (OSFET) can be designed to be lower than that of the first transistor (SiFET) by greater than or equal to 4 to 5 orders of magnitude. With this design, the on-state current (Ion) can be low.

The semiconductor device of one embodiment of the present invention includes a memory portion, and memory circuits are arranged in a matrix in the memory portion. The memory circuit includes a writing transistor, a reading transistor, and a selection transistor. For example, one of a source and a drain of the writing transistor is electrically connected to a gate of the reading transistor, and one of a source and a drain of the reading transistor is electrically connected to one of a source and a drain of the selection transistor.

The writing transistor has a function of a switch for controlling writing and retention of data to the memory circuit. Data is written to the memory circuit by turning on the writing transistor, and data is retained in the memory circuit by turning off the writing transistor. The reading transistor has a function of amplifying and reading data retained in the memory circuit. The selection transistor has a function of a switch for selecting a memory circuit from which data is read. When the selection transistor is turned on, data retained in the memory circuit is read. Specifically, when the selection transistor is turned on, current corresponding to data retained in the memory circuit flows between the drain and the source of the reading transistor and the drain and the source of the selection transistor; this allows data to be amplified and read.

A transistor with a low off-state current is preferably used as the writing transistor, in which case data can be retained in the memory circuit for a long period of time. As such a transistor, an OS transistor can be given. A transistor with a high on-state current is preferably used as the reading transistor and the selection transistor, in which case data can be read at a high speed from the memory circuit. As such a transistor, a Si transistor can be given.

As described above, the reading transistor and the selection transistor are provided in the first layer where the Si transistor is provided and the writing transistor is provided in the second layer where the OS transistor is provided, whereby data can be retained in the memory circuit for a long period of time and data can be read at a high speed from the memory circuit. Note that all the writing transistor, the reading transistor, and the selection transistor can be n-channel transistors.

Meanwhile, when the channel length, the channel width, and the like of the Si transistor provided in the first layer and the channel length, the channel width, and the like of the OS transistor provided in the second layer are equal to each other, a potential supplied to a gate of a transistor functioning as a switch needs to be different for each kind of transistor. For example, a potential supplied to a gate of a writing transistor in bringing the writing transistor that is an OS transistor functioning as a switch into an on state needs to be higher than a potential supplied to a gate of a selection transistor in bringing the selection transistor that is a Si transistor functioning as a switch into an on state.

In one embodiment of the present invention, the channel length of the Si transistor provided in the first layer is longer than the channel length of the OS transistor provided in the second layer as described above. Thus, a potential supplied to the gate of the Si transistor in bringing the Si transistor functioning as a switch into an on state and a potential supplied to the gate of the OS transistor in bringing the OS transistor functioning as a switch into an on state can be equal to each other. Furthermore, a potential supplied to the gate of the Si transistor in bringing the Si transistor functioning as a switch into an off state and a potential supplied to the gate of the OS transistor in bringing the OS transistor functioning as a switch into an off state can be equal to each other. Thus, a gate potential of the Si transistor functioning as a switch and a gate potential of the OS transistor functioning as a switch can be supplied from the same power source.

In the case where the channel length of the Si transistor provided in the first layer is longer than the channel length of the OS transistor provided in the second layer, the integration degree of transistors in the second layer can be lower than the integration degree of transistors in the first layer. For example, in the memory portion in which the memory circuits are arranged in a matrix, the integration degree of transistors in the second layer can be lower than the integration degree of transistors in the first layer.

### <Structure Example 1 of Semiconductor Device>

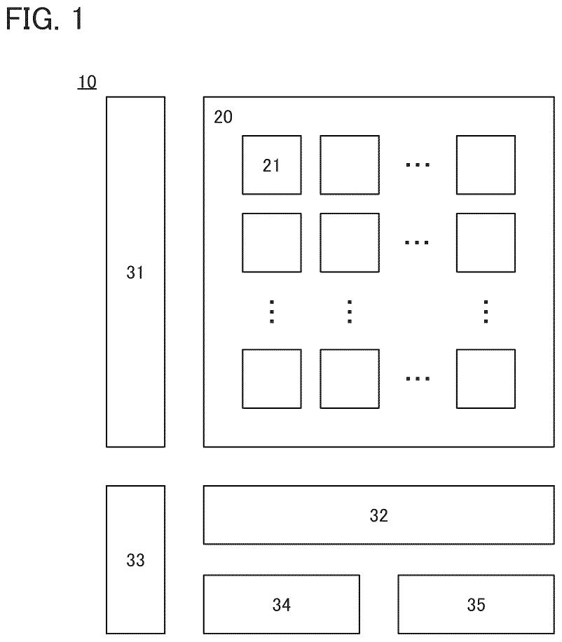

FIG. 1 is a block diagram illustrating a structure example of a semiconductor device 10 of one embodiment of the present invention. The semiconductor device 10 includes a memory portion 20, a word line driver circuit 31, a bit line driver circuit 32, a control circuit 33, a communication circuit 34, and an input/output circuit 35.

Although a block diagram in which components are classified by their functions and shown as independent blocks is shown in the drawing attached to this specification, it is difficult to completely separate actual components according to their functions and one component can relate to a plurality of functions.

In the memory portion 20, memory circuits 21 are arranged in a matrix. Each of the memory circuits 21 functions as a memory element.

In this specification and the like, a semiconductor device including a memory portion is referred to as a memory device in some cases. For example, the semiconductor device 10 can be referred to as a memory device.

Various memory systems can be used for the memory portion 20. For example, a DRAM (Dynamic Random Access Memory), an SRAM (Static Random Access Memory), a phase-change memory (PCM), a resistive random access memory (ReRAM), a magnetoresistive random access memory (MRAM), a ferroelectric random access memory (FeRAM), an antiferroelectric memory, or the like may be used.

In addition, a NOSRAM (Nonvolatile Oxide Semiconductor Random Access Memory) or a DOSRAM (Dynamic Oxide Semiconductor Random Access Memory) may be used as the memory portion 20, for example.

“NOSRAM (registered trademark)” is an abbreviation for “Nonvolatile Oxide Semiconductor Random Access Memory (RAM)”. A NOSRAM is a memory in which its memory circuit is a 2-transistor (2T) or 3-transistor (3T) gain cell, and its access transistor is an OS transistor. Current flowing between a source and a drain in an off state, that is, leakage current, is extremely low in an OS transistor. The NOSRAM is capable of reading retained data without destruction (non-destructive reading).

“DOSRAM (registered trademark)” is an abbreviation of “Dynamic Oxide Semiconductor RAM”, which indicates a RAM including 1T (transistor) 1C (capacitor)-type memory circuit. The DOSRAM, as well as the NOSRAM, is a memory utilizing a low off-state current of an OS transistor.

The word line driver circuit 31 is electrically connected to the memory circuits 21 through word lines. For example, the memory circuits 21 in the same row can be electrically connected to the same word line. The word line driver circuit 31 has a function of supplying a signal to the memory circuit 21 to which data is written and the memory circuit 21 from which data is read. That is, the word line driver circuit 31 has a function of generating a selection signal that is a signal for selecting the memory circuit 21 to which data is written and the memory circuit 21 from which data is read.

The bit line driver circuit 32 is electrically connected to the memory circuits 21 through bit lines. For example, the memory circuits 21 in the same column can be electrically connected to the same bit line. The bit line driver circuit 32 has a function of generating data to be written to the memory circuit 21. Specifically, data generated by the bit line driver circuit 32 is written to the memory circuit 21 selected by a selection signal generated by the word line driver circuit 31. The bit line driver circuit 32 has a function of amplifying and reading data retained in the memory circuit 21. Specifically, data retained in the memory circuit 21 selected by the selection signal generated by the word line driver circuit 31 is amplified and read by the bit line driver circuit 32.

The control circuit 33 has a function of controlling the driving of the word line driver circuit 31 and the bit line driver circuit 32. Specifically, the control circuit 33 can supply control signals to the word line driver circuit 31 and the bit line driver circuit 32 by processing signals such as enable signals that are supplied from the outside of the semiconductor device 10 to the control circuit 33. Note that the control circuit 33 may have a function of controlling the driving of the communication circuit 34 and the input/output circuit 35. The control circuit 33 can include a CPU, for example.

The communication circuit 34 has a wireless or wired communication function. In particular, the communication circuit 34 preferably has a wireless communication function, in which case the number of parts such as a connection cable can be decreased.

In the case where the communication circuit 34 has a wireless communication function, the communication circuit 34 can perform communication via an antenna. As a communication protocol or a communication technology, a communications standard such as LTE (Long Term Evolution), GSM (Global System for Mobile Communication: registered trademark), EDGE (Enhanced Data Rates for GSM Evolution), CDMA2000 (Code Division Multiple Access 2000), or W-CDMA (registered trademark), or an IEEE communications standard such as Wi-Fi (registered trademark), Bluetooth (registered trademark), or ZigBee (registered trademark) can be used.

The communication circuit 34 can perform input/output of information by connecting the semiconductor device 10 to another device via a computer network such as the Internet, which is an infrastructure of the World Wide Web (WWW), an intranet, an extranet, a PAN (Personal Area Network), a LAN (Local Area Network), a CAN (Campus Area Network), a MAN (Metropolitan Area Network), a WAN (Wide Area Network), or a GAN (Global Area Network).

The input/output circuit 35 has a function of supplying a signal, which is supplied from the outside of the semiconductor device 10 to the semiconductor device 10, to a circuit included in the semiconductor device 10. For example, the input/output circuit 35 has a function of receiving a signal from the outside of the semiconductor device 10 and supplying the signal to the control circuit 33. The input/output circuit 35 may have a function of supplying a signal, which is supplied to the communication circuit 34, to a circuit included in the semiconductor device 10 such as the control circuit 33.

The input/output circuit 35 also has a function of outputting a signal generated by a circuit included in the semiconductor device 10 to the outside of the semiconductor device 10. For example, the input/output circuit 35 has a function of outputting a data signal representing data read from the memory circuit 21 by the bit line driver circuit 32 to the outside of the semiconductor device 10. The input/output circuit 35 may have a function of supplying a signal generated by a circuit included in the semiconductor device 10 to the communication circuit 34. The signal supplied to the communication circuit 34 can be output to the outside of the semiconductor device 10.

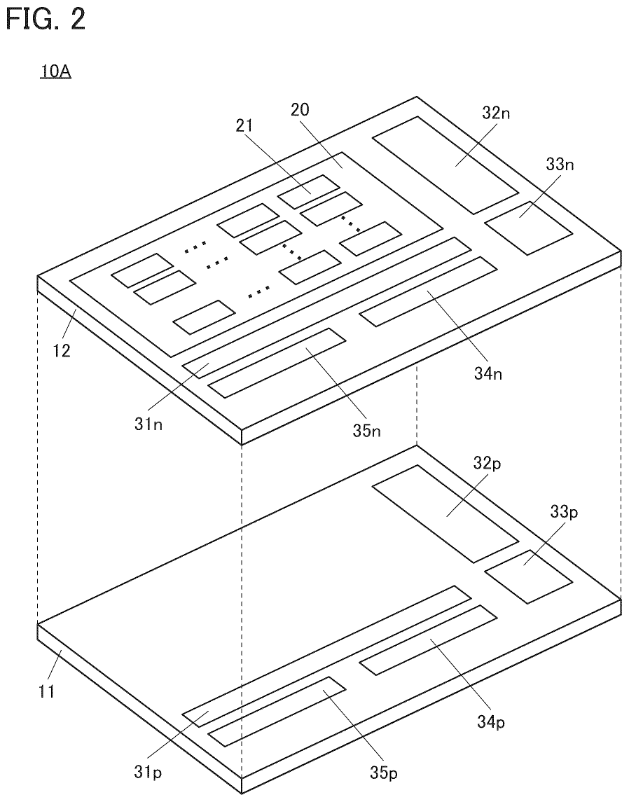

FIG. 2 is a perspective view illustrating a structure example of a semiconductor device 10A, which is a kind of the semiconductor device 10. As illustrated in FIG. 2, the semiconductor device 10A includes a layer 11 and a layer 12 over the layer 11.

Si transistors are provided in the layer 11. Specifically, the layer 11 includes a silicon substrate, and the Si transistors are provided such that channel formation regions are formed in the silicon substrate. The Si transistor can be a single crystal Si transistor, for example. For example, when a single crystal silicon substrate is provided in the layer 11 and transistors are provided such that channel formation regions are formed in the single crystal silicon substrate, single crystal Si transistors can be provided in the layer 11. Note that a transistor containing polycrystalline silicon in a channel formation region (hereinafter also referred to as a polycrystalline Si transistor) may be provided in the layer 11, for example.

N-channel transistors are provided in the layer 12, and, for example, OS transistors are provided. Specifically, an interlayer insulating film is provided over the layer 11, and the OS transistors can be provided over the interlayer insulating film.

An OS transistor has characteristics of an extremely low off-state current. Thus, when an OS transistor is used as a transistor provided in the memory circuit 21, data that is written to the memory circuit 21 can be retained for a long period of time. FIG. 2 illustrates an example in which the memory portion 20 including the memory circuits 21 is provided in the layer 12.

A metal oxide that can be used for an OS transistor is an In oxide, a Zn oxide, a Zn—Sn oxide, a Ga—Sn oxide, an In—Ga oxide, an In—Zn oxide, an In-M-Zn oxide (M is Ti, Ga, Y, Zr, La, Ce, Nd, Sn, or Hf), and the like. The use of a metal oxide containing Ga as M for the OS transistor is particularly preferable because the electrical characteristics such as field-effect mobility of the transistor can be made excellent by adjusting a ratio of elements. In addition, an oxide containing indium and zinc may contain one or more kinds selected from aluminum, gallium, yttrium, copper, vanadium, beryllium, boron, silicon, titanium, iron, nickel, germanium, zirconium, molybdenum, lanthanum, cerium, neodymium, hafnium, tantalum, tungsten, magnesium, and the like.

A variety of circuits such as a shift register, a level shifter, an inverter, a latch, an analog switch, and a logic circuit can be used as the word line driver circuit 31, the bit line driver circuit 32, the control circuit 33, the communication circuit 34, and the input/output circuit 35 illustrated in FIG. 1. These circuits each include a CMOS circuit.

As described above, the OS transistor provided in the layer 12 can be an n-channel transistor. Thus, in the semiconductor device 10A, among the transistors that form CMOS circuits, n-channel transistors are provided in the layer 12 and p-channel transistors are provided in the layer 11. In the semiconductor device 10A, a word line driver circuit 31p, a bit line driver circuit 32p, a control circuit 33p, a communication circuit 34p, and an input/output circuit 35p that are each provided with a p-channel transistor are provided in the layer 11, and a word line driver circuit 31n, a bit line driver circuit 32n, a control circuit 33n, a communication circuit 34n, and an input/output circuit 35n that are each provided with an n-channel transistor are provided in the layer 12.

The word line driver circuit 31p and the word line driver circuit 31n form the word line driver circuit 31. The bit line driver circuit 32p and the bit line driver circuit 32n form the bit line driver circuit 32. The control circuit 33p and the control circuit 33n form the control circuit 33. The communication circuit 34p and the communication circuit 34n form the communication circuit 34. The input/output circuit 35p and the input/output circuit 35n form the input/output circuit 35.

The layer 11 includes a plurality of Si transistors and the layer 12 includes a plurality of OS transistors. Thus, the layer 11 can be regarded as having a Si transistor group and the layer 12 can be regarded as having an OS transistor group. Here, all Si transistors included in the layer 11 may be collectively referred to as one Si transistor group, and all OS transistors included in the layer 12 may be collectively referred to as one OS transistor group, for example.

Alternatively, the layer 11 may be regarded as including a plurality of Si transistor groups and the layer 12 may be regarded as including a plurality of OS transistor groups. For example, the circuits may have different transistor groups from each other. For example, the word line driver circuit 31p and the bit line driver circuit 32p may be regarded as having different Si transistor groups from each other, and the word line driver circuit 31n and the bit line driver circuit 32n may be regarded as having different OS transistor groups from each other. In the case where the layer 11 includes the plurality of Si transistor groups and the layer 12 includes the plurality of OS transistor groups, it can be said one Si transistor group and one OS transistor group form a circuit having one or more functions.

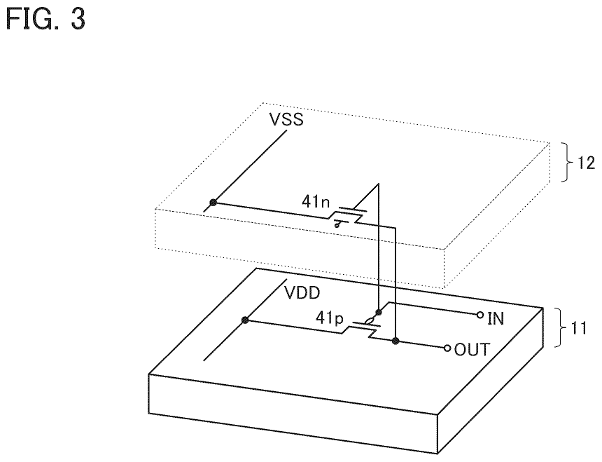

FIG. 3 is a circuit diagram illustrating an example of a CMOS circuit included in the semiconductor device 10A. FIG. 3 illustrates an inverter as an example of the CMOS circuit.

As illustrated in FIG. 3, a transistor 41p provided in the layer 11 and a transistor 41n provided in the layer 12 can form the inverter. The transistor 41p is a p-channel Si transistor and the transistor 41n is an n-channel OS transistor.

A gate of the transistor 41p and a gate of the transistor 41n are electrically connected to a terminal IN. One of a source and a drain of the transistor 41p and one of a source and a drain of the transistor 41n are electrically connected to a terminal OUT. A potential VDD is supplied to the other of the source and the drain of the transistor 41p. A potential VSS is supplied to the other of the source and the drain of the transistor 41n.

The potential VDD and the potential VSS can be power supply potentials. The potential VDD is also referred to as a high potential or a high-level-side power supply potential, and the potential VSS is also referred to as a low potential or a low-level-side power supply potential.

The inverter illustrated in FIG. 3 has a function of inverting a logic value represented by a digital signal input to the terminal IN and outputting it from the terminal OUT. Specifically, in the case where a digital signal with a logic value of “0” is input to the terminal IN, a digital signal with a logic value of “1” is output from the terminal OUT. In the case where a digital signal with a logic value of “1” is input to the terminal IN, a digital signal with a logic value of “0” is output from the terminal OUT. Specifically, in the case where a low-potential signal is input to the terminal IN as a digital signal with a logic value of “0”, the transistor 41p is turned on and the transistor 41n is turned off, and a high-potential signal is output from the terminal OUT as a digital signal with a logic value of “1”, for example. Meanwhile, in the case where a high-potential signal is input to the terminal IN, the transistor 41p is turned off and the transistor 41n is turned on, and a low-potential signal is output from the terminal OUT as a digital signal with a logic value of “0”.

The p-channel transistors are provided in the layer 11 and the n-channel transistors are provided in the layer 12. That is, when the p-channel transistors and the n-channel transistors are stacked, the number of transistors provided in the layer 11 can be reduced, for example. Accordingly, the area occupied by the semiconductor device can be reduced. Thus, the semiconductor device 10A can be a downsized semiconductor device. Note that all the n-channel transistors included in the semiconductor device 10A are not necessarily provided in the layer 12. For example, an n-channel transistor that does not form the CMOS circuit may be provided in the layer 11.

Here, when the channel lengths, the channel widths, and the like are equal to each other, the mobility of the Si transistor is higher than the mobility of the OS transistor. In particular, when a Si transistor using silicon having higher crystallinity than amorphous silicon in a channel formation region, such as a single crystal Si transistor or a polycrystalline Si transistor, is used as the Si transistor, the mobility of the Si transistor is higher than the mobility of the OS transistor. Meanwhile, when the difference between the mobility of the p-channel transistor and the mobility of the n-channel transistor that form the CMOS is large, the CMOS circuit is not driven normally in some cases. For example, when the difference between the mobility of the transistor 41p and the mobility of the transistor 41n illustrated in FIG. 3 is large, the difference between the on-state current of the transistor 41p and the on-state current of the transistor 41n is large; thus, the inverter is not driven normally in some cases. For example, a digital signal with a logic value of “0” is not output from the terminal OUT in some cases.

Thus, in the semiconductor device 10A, among the transistors that form the CMOS circuit, the channel length of the Si transistor provided in the layer 11 is longer than the channel length of the OS transistor provided in the layer 12. For example, the channel length of the transistor 41p is longer than the channel length of the transistor 41n. As the channel length becomes longer, the electric resistance between the source and the drain becomes higher and the mobility becomes lower; thus, when the channel length of the transistor 41p is longer than the channel length of the transistor 41n, for example, the difference in the mobility between the transistor 41p and the transistor 41n can be smaller than when the channel lengths of the transistor 41p and the transistor 41n are equal to each other. For example, the mobility of the transistor 41p can be lower than or equal to 300 times, lower than or equal to 100 times, lower than or equal to 50 times, lower than or equal to 30 times, or lower than or equal to 10 times the mobility of the transistor 41n.

As described above, the difference in on-state current between the transistor 41p and the transistor 41n can be small, whereby the inverter serving as a CMOS circuit can be driven normally. Specifically, both a digital signal with a logic value of “0” and a digital signal with a logic value of “1” can be output from the terminal OUT. Even in a CMOS circuit other than the inverter, the channel length of the Si transistor provided in the layer 11 is longer than the channel length of the OS transistor provided in the layer 12, whereby driving can be performed normally.

In the inverter illustrated in FIG. 3 as an example of a CMOS circuit, specific examples of the channel length of the transistor 41p that is a Si transistor provided in the layer 11 and the channel length of the transistor 41n that is an OS transistor provided in the layer 12 are described below.

For example, in consideration of easy fabrication of the transistor 41n, it is preferable that the channel length of the transistor 41p be greater than or equal to 15 nm and the channel length of the transistor 41n be less than 15 nm. Alternatively, it is preferable that the channel length of the transistor 41p be greater than or equal to 15 nm and less than or equal to 40 nm and the channel length of the transistor 41n be greater than or equal to 3 nm and less than 15 nm. The channel length of the transistor 41n can be typically greater than or equal to 5 nm and less than or equal to 8 nm.

Furthermore, the integration degree of transistors in the layer 12 can be lower than the integration degree of transistors in the layer 11. For example, the integration degree of transistors in the layer 11 including Si transistors can be higher than or equal to 50/μm², preferably higher than or equal to 100/μm². Meanwhile, the integration degree of transistors in the layer 12 including OS transistors can be lower than 50/μm². The integration degree of transistors in the layer 12 can be higher than or equal to 0.01 and lower than 1 of the integration degree of transistors in the layer 11. In particular, in the case where an n-channel transistor that does not form the CMOS circuit is provided in the layer 11, the integration degree of transistors in the layer 12 can be lower than the integration degree of transistors in the layer 11, for example.

In this specification and the like, the integration degree of transistors refers to the number of transistors per unit area. The integration degree of transistors can also be referred to as a density of transistors. Note that the integration degree of transistors may be referred to as the integration degree of a transistor group.

An OS transistor including a metal oxide in a channel formation region is likely to change its electrical characteristics when oxygen vacancies (V_{O}) exist in the channel formation region, which may degrade the reliability. In some cases, hydrogen in the vicinity of an oxygen vacancy forms a defect that is the oxygen vacancy into which hydrogen enters (hereinafter sometimes referred to as V_{O}H), which generates an electron serving as a carrier. When V_{O}H is formed in the metal oxide, a low-resistance region or an n-type region is formed in some cases. Furthermore, in the metal oxide, indium (In) and V_{O}H are bonded to each other to form InV_{O}H in some cases. The InV_{O}H functions as part of an n-type region (also referred to as an n-type conductive region). In that case, it is preferable that the metal oxide include a region where a channel is formed and an n-type region and the region where the channel is formed have less oxygen vacancies (V_{O}) than the n-type region.

More specifically, when the region of the metal oxide where a channel is formed includes oxygen vacancies, the transistor tends to have normally-on characteristics (even when no voltage is applied to the gate electrode, the channel exists and current flows through the transistor). Therefore, oxygen vacancies and V_{O}H are preferably reduced as much as possible in the channel formation region in the metal oxide. In other words, it is preferable that the region of the metal oxide where a channel is formed have a reduced carrier concentration and be of i-type (intrinsic) or substantially i-type.

As a countermeasure for the above, oxygen is supplied to the channel formation region of the metal oxide in the manufacturing process of the OS transistor, whereby oxygen vacancies and VoH can be reduced. For example, an insulator containing oxygen that is released by heating (hereinafter referred to as excess oxygen in some cases) is provided in the vicinity of the metal oxide so that oxygen can be supplied from the insulator to the metal oxide when heat treatment is performed.

The semiconductor device of one embodiment of the present invention can have a structure in which the channel lengths of the OS transistors are short and the integration degree of the OS transistors is low. Thus, particularly in the case where oxygen is supplied from an insulator containing excess oxygen to a metal oxide, the amount of oxygen supplied per unit area to the metal oxide increases. Specifically, when the channel lengths of the OS transistors are shorter than the channel lengths of the Si transistors and the integration degree of the OS transistors is lower than the integration degree of the Si transistors, the amount of oxygen supplied per unit area to the metal oxide can be favorably increased. In the above manner, oxygen vacancies and VoH in the metal oxide can be favorably reduced, and the semiconductor device of one embodiment of the present invention can have high reliability.

### <Structure Example of Memory Circuit>

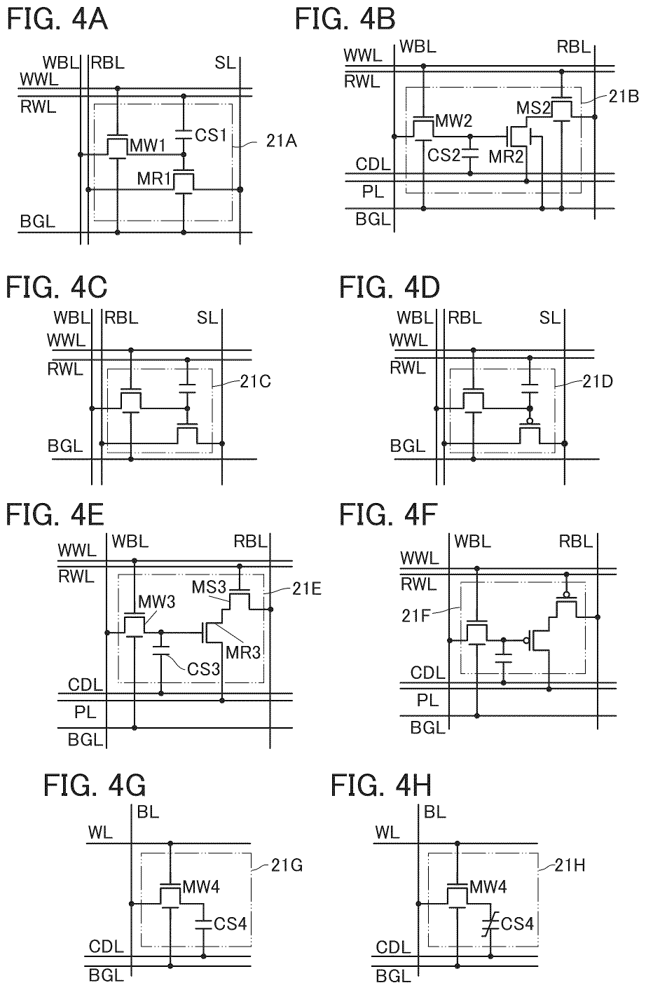

Here, structure examples of the memory circuit 21 will be described with reference to FIG. 4A to FIG. 4H. Note that a memory circuit 21A to a memory circuit 21H illustrated in FIG. 4A to FIG. 4H are memory circuits using OS transistors, which can be roughly classified into NOSRAMs in FIG. 4A to 4F and DOSRAMs in FIG. 4G and FIG. 4H.

FIG. 4A illustrates a circuit structure example applicable to the memory circuit 21. Here, the memory circuit 21A is a 2-transistor (2T) gain cell. The memory circuit 21A includes a transistor MW1, a transistor MRT, and a capacitor CST. One of a source and a drain of the transistor MW1 is electrically connected to a gate of the transistor MRT, and the gate of the transistor MRT is electrically connected to one electrode of the capacitor CST. The transistor MW1 and the transistor MRT can be OS transistors. The transistor MW1 is a writing transistor and the transistor MRT is a reading transistor.

The other of the source and the drain of the transistor MW1 is electrically connected to a bit line WBL. A gate of the transistor MW1 is electrically connected to a word line WWL. One of a source and a drain of the transistor MR1 is electrically connected to a bit line RBL. The other of the source and the drain of the transistor MR1 is electrically connected to a source line SL. A back gate of the transistor MW1 and a back gate of the transistor MR1 are electrically connected to a wiring BGL.

The writing transistor has a function of a switch for controlling writing and retention of data to the memory circuit 21. Data is written to the memory circuit 21 by turning on the writing transistor, and data is retained in the memory circuit 21 by turning off the writing transistor. The reading transistor has a function of amplifying and reading data retained in the memory circuit 21.

The memory circuit 21A includes an OS transistor as the writing transistor and thus does not consume power for data retention. Thus, the memory circuit 21A is a low-power memory circuit that can retain data for a long period of time, and the memory portion 20 can be used as a non-volatile memory device.

The memory circuit 21B illustrated in FIG. 4B is a 3T gain cell and includes a transistor MW2, a transistor MR2, a transistor MS2, and a capacitor CS2. The transistor MW2, the transistor MR2, and the transistor MS2 are a writing transistor, a reading transistor, and a selection transistor, respectively. A back gate of the transistor MW2, a back gate of the transistor MR2, and a back gate of the transistor MS2 are electrically connected to the wiring BGL. The memory circuit 21B is electrically connected to a word line RWL, the word line WWL, the bit line RBL, the bit line WBL, a capacitor line CDL, and a power supply line PL. For example, a potential GND (low-level-side power supply potential) is input to the capacitor line CDL and the power supply line PL.

The selection transistor has a function of a switch for selecting the memory circuit 21 from which data is read. When the selection transistor is turned on, data retained in the memory circuit 21 is read. Specifically, when the selection transistor is turned on, current corresponding to data retained in the memory circuit 21 flows between the drain and the source of the reading transistor and the drain and the source of the selection transistor; this allows data to be amplified and read.

FIG. 4C and FIG. 4D illustrate other structure examples of 2T gain cells. The memory circuit 21C illustrated in FIG. 4C includes an n-channel Si transistor as the reading transistor. The memory circuit 21C illustrated in FIG. 4D includes a p-channel Si transistor as the reading transistor. As illustrated in FIG. 4C and FIG. 4D, the transistors in the memory circuit may be a combination of an OS transistor and a Si transistor.

FIG. 4E and FIG. 4F illustrate other structure examples of 3T gain cells. The memory circuit 21E illustrated in FIG. 4E includes a transistor MW3, a transistor MR3, a transistor MS3, and a capacitor CS3. The transistor MW3, the transistor MR3, and the transistor MS3 are a writing transistor, a reading transistor, and a selection transistor, respectively. The memory circuit 21E includes n-channel Si transistors as the reading transistor and the selection transistor. In the example in FIG. 4E, the potential VSS is input to the power supply line PL. The memory circuit 21F illustrated in FIG. 4F includes p-channel Si transistors as the reading transistor and the selection transistor. In the example in FIG. 4F, the potential VDD is input to the power supply line PL.

In the case where the memory circuit 21 includes Si transistors as illustrated in FIG. 4C to FIG. 4F, the transistors can be provided in the layer 11. Thus, the memory circuit 21 can include Si transistors provided in the layer 11 and OS transistors provided in the layer 12.

In the above-described gain cells, a bit line serving as both the bit line RBL for reading and the bit line WBL for writing may be provided.

FIG. 4G and FIG. 4H illustrate examples of 111C (capacitor) memory circuits. The memory circuit 21G illustrated in FIG. 4G is electrically connected to a word line WL, a bit line BL, the capacitor line CDL, and the wiring BGL. The memory circuit 21G includes a transistor MW4 and a capacitor CS4. A back gate of the transistor MW4 is electrically connected to the wiring BGL. The memory circuit 21H illustrated in FIG. 4H illustrates a structure of a ferroelectric memory using a capacitor containing a ferroelectric material as the capacitor CS4. For example, HfZrO_{X} can be used as the ferroelectric material.

### <Structure Example 2 of Semiconductor Device>

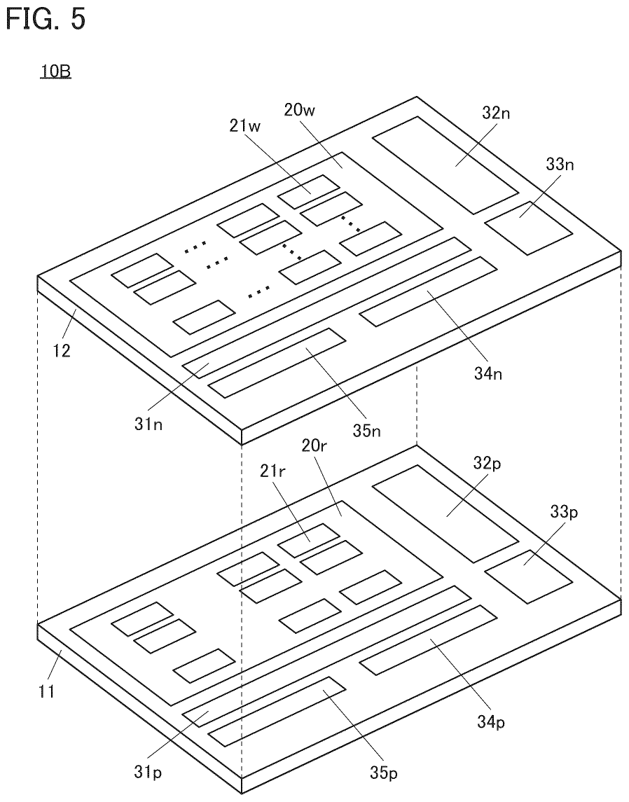

FIG. 5 is a perspective view illustrating a structure example of a semiconductor device 10B, which is a kind of the semiconductor device 10. A structure of the semiconductor device 10B that is different from that of the semiconductor device 10A is mainly described below.

In the semiconductor device 10B, a memory portion 20r is provided in the layer 11 and circuits 21r are arranged in a matrix in the memory portion 20r. A memory portion 20w is provided in the layer 12 and circuits 21w are arranged in a matrix in the memory portion 20w. The memory portion 20 includes the memory portion 20r and the memory portion 20w and the memory circuit 21 includes the circuit 21r and the circuit 21w.

In the semiconductor device 10B, any of the structures illustrated in FIG. 4C to FIG. 4F can be employed for the memory circuit 21. For example, in the case where the memory circuit 21 includes a writing transistor and a reading transistor, the reading transistor is provided in the circuit 21r and the writing transistor is provided in the circuit 21w. In the case where the memory circuit includes a selection transistor, the selection transistor is provided in the circuit 21r.

When the memory portion 20 is formed in both the layer 11 and the layer 12 as illustrated in FIG. 5, the area occupied by the memory portion 20 can be reduced as compared with the case where all components of the memory portion 20 are formed in the layer 11 or the layer 12, for example. Accordingly, the area occupied by the semiconductor device can be reduced. Thus, the semiconductor device 10B can be a downsized semiconductor device.

Note that in the semiconductor device 10B, the word line driver circuit 31, the bit line driver circuit 32, the control circuit 33, the communication circuit 34, and the input/output circuit 35 are not necessarily formed in both the layer 11 and the layer 12, for example. For example, the components of the word line driver circuit 31, the bit line driver circuit 32, the control circuit 33, the communication circuit 34, and the input/output circuit 35 can be formed only in the layer 11 and are not necessarily formed in the layer 12. In that case, all the transistors included in the word line driver circuit 31, the bit line driver circuit 32, the control circuit 33, the communication circuit 34, and the input/output circuit 35 can be Si transistors.

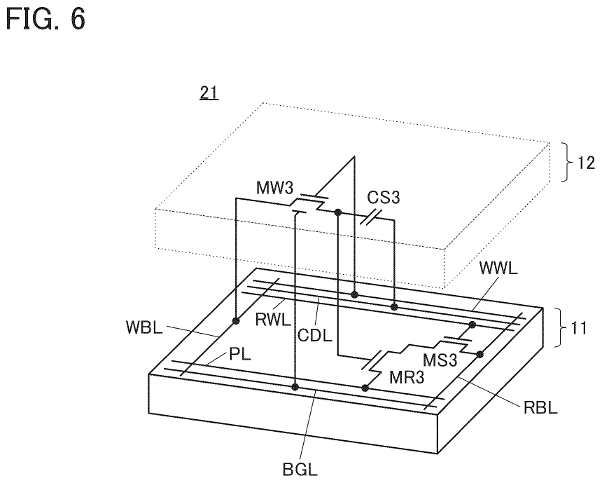

FIG. 6 is a circuit diagram illustrating an example of the memory circuit 21 included in the semiconductor device 10B. FIG. 6 illustrates an example of the memory circuit 21 having the structure illustrated in FIG. 4E.

As illustrated in FIG. 6, the memory circuit 21 included in the semiconductor device 10B includes the layer 11 and the layer 12 over the layer 11. The transistor MR3 and the transistor MS3 are provided in the layer 11. The transistor MW3 and the capacitor CS3 are provided in the layer 12. All of the transistor MR3, the transistor MS3, and the transistor MW3 can be n-channel transistors. Note that the capacitor CS3 may be provided in a layer other than the layer 12. For example, the capacitor CS3 can be provided in a layer above the layer 12.

One of a source and a drain of the transistor MR3 is electrically connected to one of a source and a drain of the transistor MS3. A gate of the transistor MR3 is electrically connected to one of a source and a drain of the transistor MW3. One of the source and the drain of the transistor MW3 is electrically connected to one electrode of the capacitor CS3.

The other of the source and the drain of the transistor MR3 is electrically connected to the power supply line PL. The other of the source and the drain of the transistor MS3 is electrically connected to the bit line RBL. A gate of the transistor MS3 is electrically connected to the word line RWL. The other of the source and the drain of the transistor MW3 is electrically connected to the bit line WBL. A gate of the transistor MW3 is electrically connected to the word line WWL. A back gate of the transistor MW3 is electrically connected to the wiring BGL. The other electrode of the capacitor CS3 is electrically connected to the capacitor line CDL.

Since the transistor MR3 and the transistor MS3 are provided in the layer 11, the transistors can be Si transistors. Since the transistor MW3 is provided in the layer 12, the transistor can be an OS transistor. As described above, when the channel length, the channel width, and the like of a Si transistor, particularly a single crystal Si transistor, a polycrystalline Si transistor, and the like are equal to the channel length, the channel width, and the like of an OS transistor, the mobility of the Si transistor is higher than that of the OS transistor, and thus the on-state current of the Si transistor is higher than that of the OS transistor. Accordingly, when the Si transistor is used as the transistor MR3 and the transistor MS3, data can be read from the memory circuit 21 at a high speed as compared with the case where the OS transistor is used as the transistor MR3 and the transistor MS3, for example. Meanwhile, the OS transistor has a lower off-state current than the Si transistor. Accordingly, when the OS transistor is used as the transistor MW3, data can be retained in the memory circuit 21 for a long period of time as compared with the case where the Si transistor is used as the transistor MW3, for example.

Meanwhile, when the channel length, the channel width, and the like of the Si transistor provided in the layer 11 and the channel length, the channel width, and the like of the OS transistor provided in the layer 12 are equal to each other, a potential supplied to a gate of a transistor functioning as a switch needs to be different for each kind of transistor. For example, a potential supplied to the word line WWL in bringing the transistor MW3 that is an OS transistor functioning as a switch into an on state needs to be higher than a potential supplied to the word line RWL in bringing the transistor MS3 that is a Si transistor functioning as a switch into an on state.

In the semiconductor device 10B, among the transistors that form the memory circuit 21, the channel length of the Si transistor provided in the layer 11 is longer than the channel length of the OS transistor provided in the layer 12. For example, each of the channel lengths of the transistor MR3 and the transistor MS3 is longer than the channel length of the transistor MW3. Thus, a potential supplied to the word line RWL in bringing the transistor MS3 into an on state and a potential supplied to the word line WWL in bringing the transistor MW3 into an on state can be equal to each other, for example. Furthermore, a potential supplied to the word line RWL in bringing the transistor MS3 into an off state and a potential supplied to the word line WWL in bringing the transistor MW3 into an off state can be equal to each other, for example. Accordingly, the potential supplied to the word line RWL and the potential supplied to the word line WWL can be supplied from the same power source, for example. Note that even in transistors functioning as switches that are provided in a circuit other than the memory portion 20 in the semiconductor device 10B, when the channel length of the Si transistor is longer than the channel length of the OS transistor, a potential supplied to the gate of the n-channel Si transistor and a potential supplied to the gate of the OS transistor can be supplied from the same power source.

In this specification and the like, a potential supplied to the word line WWL in bringing the transistor MW3 into an on state is sometimes referred to as a first potential, a potential supplied to the word line WWL in bringing the transistor MW3 into an off state is sometimes referred to as a second potential, a potential supplied to the word line RWL in bringing the transistor MS3 into an on state is sometimes referred to as a third potential, and a potential supplied to the word line RWL in bringing the transistor MS3 into an off state is sometimes referred to as a fourth potential, for example. Note that the ordinal numbers “first” to “fourth” may be interchanged with one another as appropriate.

Specific examples of the channel lengths of the transistor MR3 and the transistor MS3 that are Si transistors provided in the layer 11 and the channel length of the transistor MW3 that is an OS transistor provided in the layer 12 in the memory circuit 21 illustrated in FIG. 6 will be described below.

For example, in consideration of easy fabrication of the transistor MW3, it is preferable that the channel length of each of the transistor MR3 and the transistor MS3 be greater than or equal to 15 nm and the channel length of the transistor MW3 be less than 15 nm. Alternatively, it is preferable that the channel length of each of the transistor MR3 and the transistor MS3 be greater than or equal to 15 nm and less than or equal to 40 nm and the channel length of the transistor MW3 be greater than or equal to 3 nm and less than 15 nm. The channel length of the transistor MW3 can be typically greater than or equal to 5 nm and less than or equal to 8 nm.

Here, in the case where the memory circuit 21 has the structure illustrated in FIG. 6, two transistors are provided in the circuit 21r illustrated in FIG. 5, and one transistor is provided in the circuit 21w, for example. Thus, in the semiconductor device 10B, the integration degree of transistors in the memory portion 20w can be lower than the integration degree of transistors in the memory portion 20r, for example. For example, the integration degree of transistors in the memory portion 20r can be higher than or equal to 50/μm², preferably higher than or equal to 100/μm². Meanwhile, the integration degree of transistors in the memory portion 20w can be lower than 50/μm². As described above, since the channel length of the transistor MW3 is shorter than the channel length of the transistor MR2, even when the memory circuit 21 does not include the transistor MS3, the integration degree of transistors in the memory portion 20w can be lower than the integration degree of transistors in the memory portion 20r, for example.

As described above, the semiconductor device of one embodiment of the present invention can have a structure in which the channel lengths of the OS transistors are short and the integration degree of the OS transistors is low. Thus, particularly in the case where oxygen is supplied from an insulator containing excess oxygen to a metal oxide, the amount of oxygen supplied per unit area to the metal oxide increases. Specifically, when the channel lengths of the OS transistors are shorter than the channel lengths of the Si transistors and the integration degree of the OS transistors is lower than the integration degree of the Si transistors, the amount of oxygen supplied per unit area to the metal oxide can be favorably increased. In the above manner, oxygen vacancies and VoH in the metal oxide can be favorably reduced, and the semiconductor device of one embodiment of the present invention can have high reliability.

### <Structure Examples of Transistors>

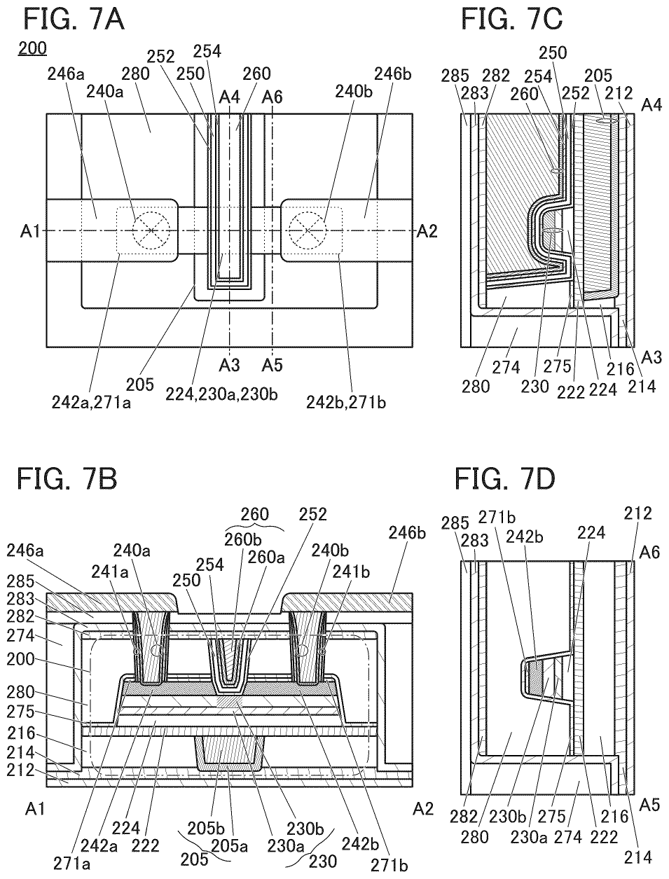

FIG. 7A is a top view illustrating a structure example of a transistor 200, which is an OS transistor, and its periphery included in the semiconductor device of one embodiment of the present invention. FIG. 7B, FIG. 7C, and FIG. 7D are cross-sectional views illustrating a structure example of the transistor 200 and its periphery. Here, FIG. 7B is a cross-sectional view of a portion indicated by the dashed-dotted line A1-A2 in FIG. 7A, and is a cross-sectional view of the transistor 200 in the channel length direction. FIG. 7C is a cross-sectional view of a portion indicated by the dashed-dotted line A3-A4 in FIG. 7A, and is a cross-sectional view of the transistor 200 in the channel width direction. FIG. 7D is a cross-sectional view of a portion indicated by the dashed-dotted line A5-A6 in FIG. 7A. Note that for clarity of the drawing, some components are omitted in the top view of FIG. 7A.

The transistor 200 can be provided in the layer 12 illustrated in FIG. 2, FIG. 3, FIG. 5, and FIG. 6. For example, the transistor 200 can be used as the transistor 41n illustrated in FIG. 3 and as the transistor MW3 illustrated in FIG. 6.

The semiconductor device of one embodiment of the present invention includes an insulator 212 over a substrate (not illustrated), an insulator 214 over the insulator 212, the transistor 200 over the insulator 214, an insulator 280 over the transistor 200, an insulator 282 over the insulator 280, an insulator 283 over the insulator 282, an insulator 274 over the insulator 283, and an insulator 285 over the insulator 283 and the insulator 274. The insulator 212, the insulator 214, the insulator 280, the insulator 282, the insulator 283, the insulator 285, the insulator 274, and the insulator 285 function as interlayer films. A conductor 240a and a conductor 240b that are electrically connected to the transistor 200 and function as plugs are also included. An insulator 241a is provided in contact with the side surface of the conductor 240a, and an insulator 241b is provided in contact with the side surface of the conductor 240b.

In this specification and the like, a plurality of conductors functioning as plugs or wirings are collectively denoted by the same reference numeral in some cases. Moreover, in this specification and the like, a wiring and a plug connected to the wiring may be a single component. That is, part of a conductor functions as a wiring in some cases and part of a conductor functions as a plug in other cases.

A conductor 246a that is electrically connected to the conductor 240a and functions as a wiring is provided over the insulator 285 and the conductor 240a, and a conductor 246b that is electrically connected to the conductor 240b and functions as a wiring is provided over the insulator 285 and the conductor 240b. The insulator 283 is in contact with part of the top surface of the insulator 214, the side surface of the insulator 280, and the side surface and the top surface of the insulator 282.

The insulator 241a is provided in contact with an inner wall of an opening formed in the insulator 280, the insulator 282, the insulator 283, and the insulator 285, and the conductor 240a is provided in contact with the side surface of the insulator 241a. The insulator 241b is provided in contact with an inner wall of an opening formed in the insulator 280, the insulator 282, the insulator 283, and the insulator 285, and the conductor 240b is provided in contact with the side surface of the insulator 241b. Each of the insulator 241a and the insulator 241b has a structure in which a first insulator is provided in contact with the inner wall of the opening and a second insulator is provided on the inner side of the first insulator. The conductor 240a has a structure in which a first conductor is provided in contact with the side surface of the insulator 241a and a second conductor is provided on the inner side of the first conductor. The conductor 240b has a structure in which a first conductor is provided in contact with the side surface of the insulator 241b and a second conductor is provided on the inner side of the first conductor. The top surface of the conductor 240a can be substantially level with the top surface of the insulator 285 in a region overlapping with the conductor 246a. Moreover, the top surface of the conductor 240b can be substantially level with the top surface of the insulator 285 in a region overlapping with the conductor 246b.

Although each of the insulator 241a and the insulator 241b has a structure in which the first insulator and the second insulator are stacked in the transistor 200, the present invention is not limited thereto. For example, each of the insulator 241a and the insulator 241b may have a single-layer structure or a stacked-layer structure of three or more layers. Note that although each of the conductor 240a and the conductor 240b has a structure in which the first conductor and the second conductor are stacked in the transistor 200, the present invention is not limited thereto. For example, each of the conductor 240a and the conductor 240b may have a single-layer structure or a stacked-layer structure of three or more layers. In the case where a component has a stacked-layer structure, layers may be distinguished by ordinal numbers given corresponding to the formation order.

The transistor 200 includes an insulator 216 over the insulator 214, a conductor 205 (a conductor 205a and a conductor 205b) placed to be embedded in the insulator 216, an insulator 222 over the insulator 216 and the conductor 205, an insulator 224 over the insulator 222, a metal oxide 230a over the insulator 224, a metal oxide 230b over the metal oxide 230a, a conductor 242a over the metal oxide 230b, an insulator 271a over the conductor 242a, a conductor 242b over the metal oxide 230b, an insulator 271b over the conductor 242b, an insulator 252 over the metal oxide 230b, an insulator 250 over the insulator 252, an insulator 254 over the insulator 250, a conductor 260 (a conductor 260a and a conductor 260b) positioned over the insulator 254 and overlapping with part of the metal oxide 230b, and an insulator 275 placed over the insulator 222, the insulator 224, the metal oxide 230a, the metal oxide 230b, the conductor 242a, the conductor 242b, the insulator 271a, and the insulator 271b. Here, as illustrated in FIG. 7B and FIG. 7C, the insulator 252 is in contact with at least parts of the top surface of the insulator 222, the side surface of the insulator 224, the side surface of the metal oxide 230a, the side surface and the top surface of the metal oxide 230b, side surfaces of the conductor 242a and the conductor 242b, side surfaces of the insulator 271a and the insulator 271b, the side surface of the insulator 275, the side surface of the insulator 280, and the bottom surface of the insulator 250. The top surface of the conductor 260 is placed to be substantially level with the uppermost portion of the insulator 254, the uppermost portion of the insulator 250, the uppermost portion of the insulator 252, and the top surface of the insulator 280. The insulator 282 is in contact with at least parts of the top surfaces of the conductor 260, the insulator 252, the insulator 250, the insulator 254, and the insulator 280.

Hereinafter, the metal oxide 230a and the metal oxide 230b are collectively referred to as the metal oxide 230 in some cases. The conductor 242a and the conductor 242b are collectively referred to as the conductor 242 in some cases. The insulator 271a and the insulator 271b are collectively referred to as the insulator 271 in some cases.

An opening reaching the metal oxide 230b is provided in the insulator 280 and the insulator 275. That is, the opening includes a region overlapping with the metal oxide 230b. It can be said that the insulator 275 includes an opening overlapping with an opening included in the insulator 280. The insulator 252, the insulator 250, the insulator 254, and the conductor 260 are placed in the opening that is provided in the insulator 280 and the insulator 275 and reaches the metal oxide 230b. That is, the conductor 260 includes a region overlapping with the metal oxide 230b with the insulator 252, the insulator 250, and the insulator 254 therebetween. The conductor 260, the insulator 252, the insulator 250, and the insulator 254 are provided between the insulator 271a and the conductor 242a, and the insulator 271b and the conductor 242b in the channel length direction of the transistor 200. The insulator 254 includes a region in contact with the side surface of the conductor 260 and a region in contact with the bottom surface of the conductor 260.

The metal oxide 230 preferably includes the metal oxide 230a placed over the insulator 224 and the metal oxide 230b placed over the metal oxide 230a. Including the metal oxide 230a under the metal oxide 230b makes it possible to inhibit diffusion of impurities into the metal oxide 230b from components formed below the metal oxide 230a.

Although a structure in which two layers, the metal oxide 230a and the metal oxide 230b, are stacked as the metal oxide 230 in the transistor 200 is described, the present invention is not limited thereto. For example, the metal oxide 230 may be provided as a single layer of the metal oxide 230b or as stacked-layer structure of three or more layers, or the metal oxide 230a and the metal oxide 230b may each have a stacked-layer structure.

The conductor 260 functions as a first gate (also referred to as a top gate) electrode, and the conductor 205 functions as a second gate (also referred to as a back gate) electrode. The insulator 252, the insulator 250, and the insulator 254 function as a first gate insulator, and the insulator 222 and the insulator 224 function as a second gate insulator. Note that the gate insulator is also referred to as a gate insulating layer or a gate insulating film in some cases. The conductor 242a functions as one of a source and a drain, and the conductor 242b functions as the other of the source and the drain. At least part of a region of the metal oxide 230 overlapping with the conductor 260 functions as a channel formation region.

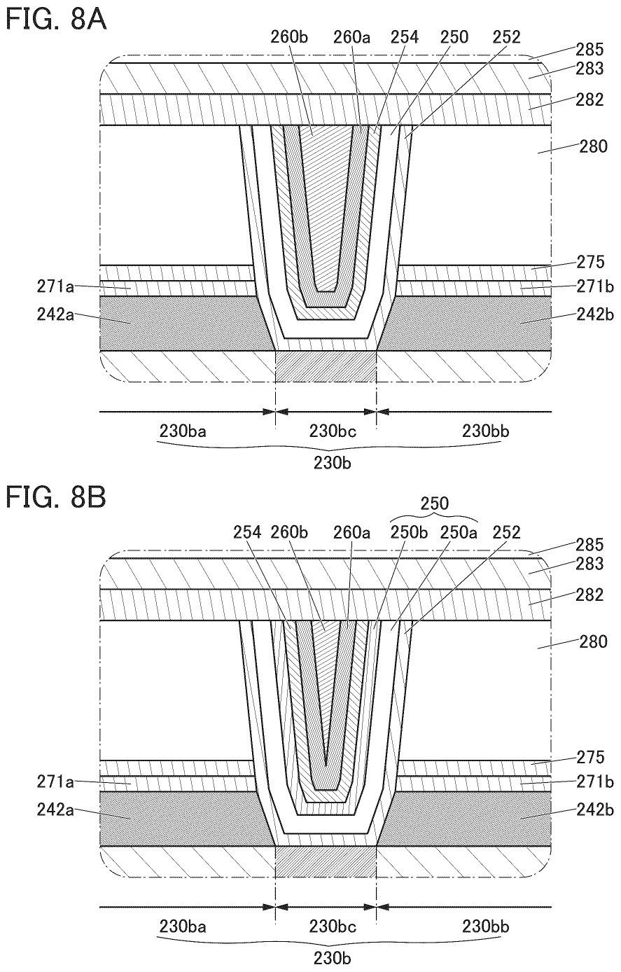

FIG. 8A is an enlarged view of the vicinity of the channel formation region in FIG. 7B. Supply of oxygen to the metal oxide 230b forms the channel formation region in a region between the conductor 242a and the conductor 242b. As illustrated in FIG. 8A, the metal oxide 230b includes a region 230bc functioning as the channel formation region of the transistor 200 and a region 230ba and a region 230bb that function as a source region and a drain region. As illustrated in FIG. 8A, the region 230ba and the region 230bb are provided so as to sandwich the region 230bc therebetween. At least part of the region 230bc overlaps with the conductor 260. In other words, the region 230bc is provided between the conductor 242a and the conductor 242b. The region 230ba is provided to overlap with the conductor 242a, and the region 230bb is provided to overlap with the conductor 242b.

The region 230bc functioning as the channel formation region has a smaller amount of oxygen vacancies or a lower impurity concentration than those of the region 230ba and the region 230bb, and thus is a high-resistance region with a low carrier concentration. Thus, the region 230bc can be regarded as being i-type (intrinsic) or substantially i-type.

The region 230ba and the region 230bb functioning as the source region and the drain region include a large amount of oxygen vacancies or have a high concentration of an impurity such as hydrogen, nitrogen, or a metal element, and thus are each a low-resistance region with an increased carrier concentration. In other words, the region 230ba and the region 230bb are each an n-type region having a higher carrier concentration and a lower resistance than the region 230bc.

The carrier concentration in the region 230bc functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. Note that the lower limit of the carrier concentration in the region 230bc functioning as the channel formation region is not particularly limited and can be, for example, 1×10⁻⁹ cm⁻³.

Between the region 230bc and the region 230ba or the region 230bb, a region having a carrier concentration that is lower than or substantially equal to the carrier concentrations in the region 230ba and the region 230bb and higher than or substantially equal to the carrier concentration in the region 230bc may be formed. That is, the region functions as a junction region between the region 230bc and the region 230ba or the region 230bb. The hydrogen concentration in the junction region is lower than or substantially equal to the hydrogen concentrations in the region 230ba and the region 230bb and higher than or substantially equal to the hydrogen concentration in the region 230bc in some cases. The amount of oxygen vacancies in the junction region is smaller than or substantially equal to the amounts of oxygen vacancies in the region 230ba and the region 230bb and larger than or substantially equal to the amount of oxygen vacancies in the region 230bc in some cases.

Although FIG. 8A illustrates an example where the region 230ba, the region 230bb, and the region 230bc are formed in the metal oxide 230b, the present invention is not limited thereto. For example, the above regions may be formed not only in the metal oxide 230b but also in the metal oxide 230a.

In the metal oxide 230, the boundaries between the regions are difficult to detect clearly in some cases. The concentration of a metal element and an impurity element such as hydrogen or nitrogen, which is detected in each region, may be not only gradually changed between the regions but also continuously changed in each region. That is, the region closer to the channel formation region preferably has a lower concentration of a metal element and an impurity element such as hydrogen or nitrogen.

In the transistor 200, a metal oxide functioning as a semiconductor (such a metal oxide is hereinafter also referred to as an oxide semiconductor) is preferably used for the metal oxide 230 (the metal oxide 230a and the metal oxide 230b) including the channel formation region.

The metal oxide functioning as a semiconductor preferably has a band gap of 2 eV or higher, further preferably 2.5 eV or higher. With use of a metal oxide having a wide bandgap, the off-state current of the transistor can be reduced.

As the metal oxide 230, it is preferable to use, for example, a metal oxide such as an In-M-Zn oxide containing indium, an element M, and zinc (the element M is one or more kinds selected from aluminum, gallium, yttrium, tin, copper, vanadium, beryllium, boron, titanium, iron, nickel, germanium, zirconium, molybdenum, lanthanum, cerium, neodymium, hafnium, tantalum, tungsten, magnesium, and the like). Alternatively, an In—Ga oxide, an In—Zn oxide, or an indium oxide may be used as the metal oxide 230.

The metal oxide 230 preferably has a stacked-layer structure of a plurality of oxide layers with different chemical compositions. For example, the atomic ratio of the element M to a metal element that is a main component of the metal oxide used as the metal oxide 230a is preferably greater than the atomic ratio of the element M to a metal element that is a main component of the metal oxide used as the metal oxide 230b. Moreover, the atomic ratio of the element M to In in the metal oxide used as the metal oxide 230a is preferably greater than the atomic ratio of the element M to In in the metal oxide used as the metal oxide 230b. With this structure, impurities and oxygen can be inhibited from diffusing into the metal oxide 230b from the components formed below the metal oxide 230a.

Furthermore, the atomic ratio of In to the element M in the metal oxide used as the metal oxide 230b is preferably greater than the atomic ratio of In to the element M in the metal oxide used as the metal oxide 230a. With this structure, the transistor 200 can have a high on-state current and high frequency characteristics.

When the metal oxide 230a and the metal oxide 230b contain a common element as the main component besides oxygen, the density of defect states at an interface between the metal oxide 230a and the metal oxide 230b can be made low. Thus, the influence of interface scattering on carrier conduction is small, and the transistor 200 can have a high on-state current and excellent frequency characteristics.

Specifically, as the metal oxide 230a, a metal oxide with a composition of In:M:Zn=1:3:4 [atomic ratio] or in the neighborhood thereof, or a composition of In M:Zn=1:1:0.5 [atomic ratio] or in the neighborhood thereof is used. As the metal oxide 230b, a metal oxide with a composition of In:M:Zn=1:1:1 [atomic ratio] or in the neighborhood thereof, a composition of In:M:Zn=1:1:1.2 [atomic ratio] or in the neighborhood thereof, a composition of In:M:Zn=1:1:2 [atomic ratio] or in the neighborhood thereof, or a composition of In:M:Zn=4:2:3 [atomic ratio] or in the neighborhood thereof can be used. Note that a composition in the neighborhood includes the range of ±30% of an intended atomic ratio. Gallium is preferably used as the element M. In the case where a single layer of the metal oxide 230b is provided as the metal oxide 230, a metal oxide that can be used as the metal oxide 230a may be used as the metal oxide 230b.

When the metal oxide is deposited by a sputtering method, the above atomic ratio is not limited to the atomic ratio of the deposited metal oxide and may be the atomic ratio of a sputtering target used for depositing the metal oxide.

The metal oxide 230b preferably has crystallinity. It is particularly preferable to use a CAAC-OS (c-axis aligned crystalline oxide semiconductor) as the metal oxide 230b.

The CAAC-OS is a metal oxide having a dense structure with high crystallinity and a small amount of impurities and defects (for example, oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including a CAAC-OS is physically stable. Therefore, the metal oxide including a CAAC-OS is resistant to heat and has high reliability.

When an oxide having crystallinity, such as CAAC-OS, is used as the metal oxide 230b, oxygen extraction from the metal oxide 230b by the source electrode or the drain electrode can be inhibited. This can reduce oxygen extraction from the metal oxide 230b even when heat treatment is performed; thus, the transistor 200 is stable with respect to high temperatures in a manufacturing process (what is called thermal budget).

If impurities and oxygen vacancies exist in a region of an oxide semiconductor where a channel is formed, a transistor using the oxide semiconductor may have variable electrical characteristics and poor reliability. In some cases, hydrogen in the vicinity of an oxygen vacancy forms a defect that is the oxygen vacancy into which hydrogen enters (hereinafter sometimes referred to as V_{O}H), which generates an electron serving as a carrier. Therefore, when the region of the oxide semiconductor where a channel is formed includes oxygen vacancies, the transistor tends to have normally-on characteristics (even when no voltage is applied to the gate electrode, the channel exists and current flows through the transistor). Thus, impurities, oxygen vacancies, and V_{O}H are preferably reduced as much as possible in the region of the oxide semiconductor where a channel is formed. In other words, it is preferable that the region of the oxide semiconductor where a channel is formed have a reduced carrier concentration and be of an i-type (intrinsic) or substantially i-type.

As a countermeasure to the above, an insulator containing oxygen that is released by heating (hereinafter, sometimes referred to as excess oxygen) is provided in the vicinity of the oxide semiconductor and heat treatment is performed, so that oxygen can be supplied from the insulator to the oxide semiconductor to reduce oxygen vacancies and V_{O}H. However, supply of an excess amount of oxygen to the source region or the drain region might cause a decrease in the on-state current or field-effect mobility of the transistor 200. Furthermore, a variation of the amount of oxygen supplied to the source region or the drain region in the substrate plane leads to a variation in characteristics of the semiconductor device including the transistor. When oxygen supplied from the insulator to the oxide semiconductor diffuses into a conductor such as the gate electrode, the source electrode, or the drain electrode, the conductor might be oxidized and the conductivity might be impaired, for example, so that electrical characteristics and reliability of the transistor might be adversely affected.

Therefore, the region 230bc functioning as the channel formation region in the oxide semiconductor is preferably an i-type or substantially i-type region with reduced carrier concentration, whereas the region 230ba and the region 230bb functioning as the source region and the drain region are preferably n-type regions with high carrier concentrations. That is, it is preferable that oxygen vacancies and V_{O}H in the region 230bc of the oxide semiconductor be reduced and the region 230ba and the region 230bb not be supplied with an excess amount of oxygen. For example, oxidation of the conductor 260, the conductor 242a, and the conductor 242b, and the like is preferably inhibited.

Thus, in this embodiment, the semiconductor device has a structure in which oxygen is efficiently supplied to the region 230bc and oxidation of the conductor 242a, the conductor 242b, and the conductor 260 is inhibited.

An insulator that is likely to transmit oxygen is preferably used as the insulator 250 to supply oxygen to the region 230bc. In particular, an insulator containing excess oxygen is preferably used as the insulator 280. This structure enables oxygen contained in the insulator 280 to be supplied to the region 230bc through the insulator 250.

Furthermore, in order to inhibit oxidation of the conductor 242a, the conductor 242b, and the conductor 260, an insulator having a function of inhibiting diffusion of oxygen is preferably provided in the vicinity of each of the conductor 242a, the conductor 242b, and the conductor 260. In the semiconductor device described in this embodiment, the insulator corresponds to the insulator 252, the insulator 254, and the insulator 275, for example.

The insulator 252 preferably has a barrier property against oxygen. The insulator 252 is provided between the insulator 250 and the conductor 242a and between the insulator 250 and the conductor 242b. Thus, oxygen contained in the insulator 250 can be inhibited from diffusing into the conductor 242a and the conductor 242b, and oxidation of the conductor 242a and the conductor 242b can be inhibited. Alternatively, the amount of oxygen diffused into the conductor 242a and the conductor 242b from the insulator 250 is reduced, and a layer formed on the side surfaces of the conductor 242a and the conductor 242b (corresponding to a layer 244a and a layer 244b described later) can be thin. The insulator 252 is provided between the insulator 250 and the metal oxide 230b. Thus, release of oxygen from the region 230bc of the metal oxide 230b in heat treatment can be inhibited, for example.

Note that the thickness of the insulator 252 is preferably small. For example, the insulator 252 preferably includes a region having a thickness smaller than the thickness of the insulator 250. The insulator 250 includes a region in contact with the top surface of the metal oxide 230b. When the thickness of the insulator 252 is small, oxygen contained in the insulator 250 can be supplied to the region 230bc of the metal oxide 230b, and oxygen contained in the insulator 250 can be inhibited from being excessively supplied. The insulator 252 is provided between the insulator 280 and the insulator 250 and includes a region in contact with a sidewall of the opening included in the insulator 280. When the thickness of the insulator 252 is small, oxygen contained in the insulator 280 can be supplied to the insulator 250, and oxygen contained in the insulator 280 can be inhibited from being excessively supplied.

The insulator 254 preferably has a barrier property against oxygen. The insulator 254 is provided between the insulator 250 and the conductor 260. Thus, diffusion of oxygen contained in the insulator 250 into the conductor 260 can be prevented, so that oxidation of the conductor 260 can be inhibited. Note that the insulator 254 is less permeable to oxygen than at least the insulator 250 is.

As the insulator 275, an insulator having a function of inhibiting passage of oxygen is preferably used. The insulator 275 is provided between the insulator 280 and the conductor 242a and between the insulator 280 and the conductor 242b. The structure can inhibit diffusion of oxygen contained in the insulator 280 into the conductor 242a and the conductor 242b. Accordingly, oxidation of the conductor 242a and the conductor 242b by oxygen contained in the insulator 280 can be inhibited, so that an increase in resistivity and a reduction in on-state current can be inhibited. The insulator 275 is less permeable to oxygen than at least the insulator 250 is.

With the above structure, the region 230bc functioning as the channel formation region can be an i-type or substantially i-type region, the region 230ba and the region 230bb functioning as the source region and the drain region can be n-type regions, and thus a semiconductor device with favorable electrical characteristics can be provided. The semiconductor device with the above structure can have favorable electrical characteristics even when being miniaturized or highly integrated. For example, the semiconductor device can have favorable electrical characteristics even when a gate length is less than or equal to 20 nm, less than or equal to 15 nm, less than or equal to 10 nm, or less than or equal to 7 nm and greater than or equal to 2 nm, greater than or equal to 3 nm, or greater than or equal to 5 nm. Note that the gate length will be described later.

Furthermore, miniaturization of the transistor 200 can improve high-frequency characteristics. Specifically, a cutoff frequency can be improved. When the gate length is within the above range, the cutoff frequency of the transistor can be greater than or equal to 50 GHz or greater than or equal to 100 GHz at room temperature, for example.

A conductive material that is less likely to be oxidized, a conductive material having a function of inhibiting diffusion of oxygen, or the like is preferably used for the conductor 242a, the conductor 242b, and the conductor 260. Examples of the conductive material include a conductive material containing nitrogen, a conductive material containing oxygen, and the like. Thus, a decrease in conductivity of the conductor 242a, the conductor 242b, and the conductor 260 can be inhibited. In the case where a conductive material containing metal and nitrogen is used for the conductor 242a, the conductor 242b, and the conductor 260, the conductor 242a, the conductor 242b, and the conductor 260 contain at least metal and nitrogen.

Any one or more of the conductor 242a, the conductor 242b, and the conductor 260 may have a stacked-layer structure. For example, in the case where the conductor 242a and the conductor 242b each have a stacked-layer structure, a conductive material that is not easily oxidized, a conductive material having a function of inhibiting diffusion of oxygen, or the like is preferably used for a layer in contact with the metal oxide 230b. For example, in the case where the conductor 260 has a stacked-layer structure of the conductor 260a and the conductor 260b as illustrated in FIG. 7B, a conductive material that is less likely to be oxidized, a conductive material having a function of inhibiting diffusion of oxygen, or the like is preferably used for the conductor 260a.

As the metal oxide 230b, an oxide having crystallinity, such as a CAAC-OS, is preferably used. As the oxide, a metal oxide that can be used as the metal oxide 230 described above is preferably used. Specifically, a metal oxide containing indium, zinc, and one or more selected from gallium, aluminum, and tin is preferably used. The CAAC-OS is an oxide including a crystal, and the c-axis of the crystal is substantially perpendicular to the surface of the oxide or a formation surface. This can inhibit the conductor 242a or the conductor 242b from extracting oxygen from the metal oxide 230b. Furthermore, it is possible to inhibit a reduction in the conductivity of the conductor 242a and the conductor 242b.

The insulator 282 provided over the insulator 280 is preferably formed by a method in which oxygen can be added to the insulator 280. Thus, excess oxygen can be contained in the insulator 280.

In addition to the above structure, the semiconductor device of this embodiment has a structure in which hydrogen is inhibited from entering the transistor 200. For example, an insulator having a function of inhibiting diffusion of hydrogen is provided to cover the transistor 200. In the semiconductor device described in this embodiment, the insulator corresponds to, for example, the insulator 212 and the insulator 283.

As the insulator 212, an insulator having a function of inhibiting diffusion of hydrogen is preferably used. This can inhibit diffusion of hydrogen into the transistor 200 from below the insulator 212.

As the insulator 283, an insulator having a function of inhibiting diffusion of hydrogen is preferably used. This can inhibit diffusion of hydrogen into the transistor 200 from above the insulator 283. Moreover, diffusion of hydrogen contained in the insulator 274 into the transistor 200 can be inhibited.

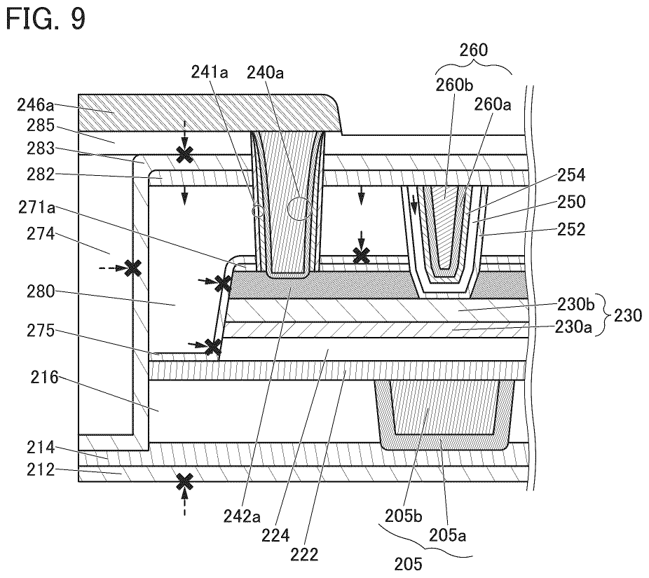

FIG. 9 is an enlarged view of the vicinity of the channel formation region in FIG. 7B. The solid arrows illustrated in FIG. 9 visualize a state where oxygen diffuses. The dotted arrows illustrated in FIG. 9 visualize a state where hydrogen diffuses. With the above structure, oxygen can be efficiently supplied to the region 230bc and oxidation of the conductor 242a, the conductor 242b, and the conductor 260 can be inhibited. Moreover, entry of hydrogen into the transistor 200 can be inhibited.

In this embodiment, microwave treatment is performed in an atmosphere containing oxygen in a state where the conductor 242a and the conductor 242b are provided over the metal oxide 230b so that oxygen vacancies and V_{O}H in the region 230bc are reduced. Here, the microwave treatment refers to, for example, treatment using an apparatus including a power source that generates high-density plasma with the use of a microwave.

The microwave treatment in an oxygen-containing atmosphere converts an oxygen gas into plasma using a high-frequency wave such as a microwave or RF and activates the oxygen plasma. At this time, the region 230bc can be irradiated with the high-frequency wave such as a microwave or RF. By the effect of the plasma, the microwave, and the like, V_{O}H in the region 230bc can be divided into an oxygen vacancy and hydrogen; the hydrogen can be removed from the region 230bc and the oxygen vacancy can be filled with oxygen. As a result, the hydrogen concentration, oxygen vacancies and V_{O}H of the region 230bc can be reduced to lower the carrier concentration.

In the microwave treatment in an oxygen-containing atmosphere, the high-frequency wave such as the microwave or RF, the oxygen plasma, or the like is blocked by the conductor 242a and the conductor 242b and does not affect the region 230ba nor the region 230bb. In addition, the effect of the oxygen plasma can be reduced by the insulator 271 and the insulator 280 that are provided to cover the metal oxide 230b and the conductor 242. Hence, a reduction in V_{O}H and supply of an excess amount of oxygen do not occur in the region 230ba or the region 230bb in the microwave treatment, preventing a decrease in carrier concentration.

Microwave treatment is preferably performed in an oxygen-containing atmosphere after deposition of an insulating film to be the insulator 252 or after deposition of an insulating film to be the insulator 250. By performing the microwave treatment in an oxygen-containing atmosphere through the insulator 252 or the insulator 250 in such a manner, oxygen can be efficiently supplied into the region 230bc. In addition, the insulator 252 is placed to be in contact with the side surface of the conductor 242 and the surface of the region 230bc, thereby inhibiting oxygen more than necessary from being supplied to the region 230bc and inhibiting the side surface of the conductor 242 from being oxidized. Furthermore, the side surface of the conductor 242 can be inhibited from being oxidized when the insulating film to be the insulator 250 is deposited.

The oxygen supplied into the region 230bc has any of a variety of forms such as an oxygen atom, an oxygen molecule, and an oxygen radical (an O radical, an atom or a molecule having an unpaired electron, or an ion). Note that the oxygen supplied into the region 230bc has any one or more of the above forms, particularly preferably an oxygen radical. Furthermore, the film quality of the insulator 252 and the insulator 250 can be improved, leading to higher reliability of the transistor 200.

In the above manner, oxygen vacancies and V_{O}H can be selectively removed from the region 230bc of the oxide semiconductor, whereby the region 230bc can be an i-type or substantially i-type region. Furthermore, supply of an excess amount of oxygen to the region 230ba and the region 230bb functioning as the source region and the drain region can be inhibited and the state of the n-type regions before the microwave treatment is performed can be maintained. As a result, a change in the electrical characteristics of the transistor 200 can be inhibited, and thus a variation in the electrical characteristics of the transistors 200 in the substrate plane can be inhibited.

With the above structure, a semiconductor device with a small variation in transistor characteristics can be provided. A semiconductor device with favorable reliability can also be provided. A semiconductor device having favorable electrical characteristics can be provided. Alternatively, a semiconductor device that can be miniaturized or highly integrated can be provided.

As illustrated in FIG. 7C, a curved surface may be provided between the side surface of the metal oxide 230b and the top surface of the metal oxide 230b in a cross-sectional view of the transistor 200 in the channel width direction. In other words, an end portion of the side surface and an end portion of the top surface may be curved (hereinafter referred to as rounded).

The radius of curvature of the curved surface is preferably greater than 0 nm and less than the thickness of the metal oxide 230b in a region overlapping with the conductor 242, or less than half of the length of a region that does not have the curved surface. Specifically, the radius of curvature of the curved surface is greater than 0 nm and less than or equal to 20 nm, preferably greater than or equal to 1 nm and less than or equal to 15 nm, and further preferably greater than or equal to 2 nm and less than or equal to 10 nm. Such a shape can improve the coverage of the metal oxide 230b with the insulator 252, the insulator 250, the insulator 254, and the conductor 260.

For example, as illustrated in FIG. 7C, the insulator 252 formed using aluminum oxide or the like is provided in contact with the top surface and the side surface of the metal oxide 230, whereby indium contained in the metal oxide 230 is unevenly distributed, in some cases, at the interface between the metal oxide 230 and the insulator 252 and in its vicinity. Accordingly, the vicinity of the surface of the metal oxide 230 has an atomic ratio close to that of an indium oxide or that of an In—Zn oxide. Such an increase in the atomic ratio of indium in the vicinity of the surface of the metal oxide 230, especially the vicinity of the surface of the metal oxide 230b, can increase the field-effect mobility of the transistor 200.

At least one of the insulator 212, the insulator 214, the insulator 271, the insulator 275, the insulator 282, the insulator 283, and the insulator 285 preferably functions as a barrier insulating film, which inhibits diffusion of impurities such as water and hydrogen from the substrate side or above the transistor 200 into the transistor 200. Thus, for at least one of the insulator 212, the insulator 214, the insulator 271, the insulator 275, the insulator 282, the insulator 283, and the insulator 285, it is preferable to use an insulating material having a function of inhibiting diffusion of impurities such as hydrogen atoms, hydrogen molecules, water molecules, nitrogen atoms, nitrogen molecules, nitrogen oxide molecules (e.g., N₂O, NO, or NO₂), or copper atoms (an insulating material through which the impurities are less likely to pass). Alternatively, it is preferable to use an insulating material having a function of inhibiting diffusion of oxygen (e.g., at least one of oxygen atoms, oxygen molecules, and the like) (an insulating material through which the oxygen is less likely to pass).

Note that in this specification, a barrier insulating film refers to an insulating film having a barrier property. A barrier property in this specification means a function of inhibiting diffusion of a targeted substance (also referred to as having low permeability). In addition, a barrier property in this specification means a function of capturing and fixing (also referred to as gettering) a targeted substance.

An insulator having a function of inhibiting diffusion of oxygen and impurities such as water and hydrogen is preferably used for the insulator 212, the insulator 214, the insulator 271, the insulator 275, the insulator 282, the insulator 283, and the insulator 285; for example, aluminum oxide, magnesium oxide, hafnium oxide, gallium oxide, indium gallium zinc oxide, silicon nitride, or silicon nitride oxide can be used. For example, silicon nitride or the like, which has a higher hydrogen barrier property, is preferably used for the insulator 212, the insulator 275, and the insulator 283. For example, aluminum oxide, magnesium oxide, or the like, which has a function of capturing or fixing hydrogen well, is preferably used for the insulator 214, the insulator 271, the insulator 282, and the insulator 285. In this case, impurities such as water and hydrogen can be inhibited from diffusing to the transistor 200 side from the substrate side through the insulator 212 and the insulator 214. Impurities such as water and hydrogen can be inhibited from diffusing to the transistor 200 side from an interlayer insulating film and the like which are provided outside the insulator 285. Alternatively, oxygen contained in the insulator 224 and the like can be inhibited from diffusing to the substrate side through the insulator 212 and the insulator 214. Alternatively, oxygen contained in the insulator 280 and the like can be inhibited from diffusing above the transistor 200 through the insulator 282 and the like. In this manner, it is preferable that the transistor 200 be surrounded by the insulator 212, the insulator 214, the insulator 271, the insulator 275, the insulator 282, the insulator 283, and the insulator 285, which have a function of inhibiting diffusion of oxygen and impurities such as water and hydrogen.

Here, an oxide having an amorphous structure is preferably used for the insulator 212, the insulator 214, the insulator 271, the insulator 275, the insulator 282, the insulator 283, and the insulator 285. For example, a metal oxide such as AlOₓ (x is a given number greater than 0) or MgO_{y} (y is a given number greater than 0) is preferably used. In such a metal oxide having an amorphous structure, an oxygen atom has a dangling bond and sometimes has a property of capturing or fixing hydrogen with the dangling bond. When such a metal oxide having an amorphous structure is used as the component of the transistor 200 or provided around the transistor 200, hydrogen contained in the transistor 200 or hydrogen around the transistor 200 can be captured or fixed. In particular, hydrogen contained in the channel formation region of the transistor 200 is preferably captured or fixed. The metal oxide having an amorphous structure is used as the component of the transistor 200 or provided around the transistor 200, whereby the transistor 200 and a semiconductor device which have favorable characteristics and high reliability can be manufactured.

Although each of the insulator 212, the insulator 214, the insulator 271, the insulator 275, the insulator 282, the insulator 283, and the insulator 285 preferably has an amorphous structure, a region having a polycrystalline structure may be partly formed. Alternatively, each of the insulator 212, the insulator 214, the insulator 271, the insulator 275, the insulator 282, the insulator 283, and the insulator 285 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

The insulator 212, the insulator 214, the insulator 271, the insulator 275, the insulator 282, the insulator 283, and the insulator 285 can be deposited by a sputtering method, for example. Since a sputtering method does not need to use a molecule containing hydrogen as a deposition gas, the hydrogen concentrations in the insulator 212, the insulator 214, the insulator 271, the insulator 275, the insulator 282, the insulator 283, and the insulator 285 can be reduced. Note that the deposition method is not limited to a sputtering method, and a chemical vapor deposition (CVD) method, a molecular beam epitaxy (MBE) method, a pulsed laser deposition (PLD) method, an atomic layer deposition (ALD) method, or the like may be used as appropriate.

The resistivities of the insulator 212, the insulator 275, and the insulator 283 are preferably low in some cases. For example, by setting the resistivities of the insulator 212, the insulator 275, and the insulator 283 to approximately 1×10¹³ Ωcm, the insulator 212, the insulator 275, and the insulator 283 can sometimes reduce charge up of the conductor 205, the conductor 242, the conductor 260, or the conductor 246 in treatment using plasma or the like in the manufacturing process of a semiconductor device. The resistivities of the insulator 212, the insulator 275, and the insulator 283 are preferably higher than or equal to 1×10¹⁰ Ωcm and lower than or equal to 1×10¹⁵ Ωcm.

The insulator 216, the insulator 274, the insulator 280, and the insulator 285 each preferably have a lower permittivity than the insulator 214. When a material with a low permittivity is used for an interlayer film, parasitic capacitance generated between wirings can be reduced. For the insulator 216, the insulator 274, the insulator 280, and the insulator 285, silicon oxide, silicon oxynitride, silicon oxide to which fluorine is added, silicon oxide to which carbon is added, silicon oxide to which carbon and nitrogen are added, porous silicon oxide, or the like is used as appropriate, for example.

In this specification and the like, silicon oxynitride refers to a material that contains oxygen at a higher proportion than nitrogen, and silicon nitride oxide refers to a material that contains nitrogen at a higher proportion than oxygen. Moreover, in this specification, aluminum oxynitride refers to a material that has a higher oxygen content than a nitrogen content, and aluminum nitride oxide refers to a material that has a higher nitrogen content than an oxygen content.

The conductor 205 is placed to overlap with the metal oxide 230 and the conductor 260. Here, the conductor 205 is preferably provided to be embedded in an opening formed in the insulator 216. Part of the conductor 205 is embedded in the insulator 214 in some cases.

The conductor 205 includes the conductor 205a and the conductor 205b. The conductor 205a is provided in contact with the bottom surface and the sidewall of the opening. The conductor 205b is provided to be embedded in a depressed portion formed in the conductor 205a. Here, the top surface of the conductor 205b is substantially level with top surfaces of the conductor 205a and the insulator 216.

Here, for the conductor 205a, it is preferable to use a conductive material having a function of inhibiting diffusion of impurities such as a hydrogen atom, a hydrogen molecule, a water molecule, a nitrogen atom, a nitrogen molecule, a nitrogen oxide molecule (N₂O, NO, NO₂, or the like), and a copper atom. Alternatively, it is preferable to use a conductive material having a function of inhibiting diffusion of oxygen (e.g., at least one of an oxygen atom, an oxygen molecule, and the like).

When the conductor 205a is formed using a conductive material having a function of inhibiting diffusion of hydrogen, impurities such as hydrogen contained in the conductor 205b can be prevented from diffusing into the metal oxide 230 through the insulator 216, the insulator 224, and the like. When the conductor 205a is formed using a conductive material having a function of inhibiting diffusion of oxygen, the conductivity of the conductor 205b can be inhibited from being lowered because of oxidation. As the conductive material having a function of inhibiting diffusion of oxygen, for example, titanium, titanium nitride, tantalum, tantalum nitride, ruthenium, or ruthenium oxide is preferably used. Thus, the conductor 205a may be a single layer or a stacked layer of the above conductive materials. For example, titanium nitride is used for the conductor 205a.

Moreover, the conductor 205b is preferably formed using a conductive material containing tungsten, copper, or aluminum as its main component. For example, tungsten is used for the conductor 205b.

The conductor 205 sometimes functions as a second gate electrode. In that case, by changing a potential applied to the conductor 205 out of synchronization with and independently of a potential applied to the conductor 260, the threshold voltage (Vth) of the transistor 200 can be controlled. In particular, Vth of the transistor 200 can be higher in the case where a negative potential is applied to the conductor 205, and the off-state current can be reduced. Thus, a drain current at the time when a potential applied to the conductor 260 is 0 V can be lower in the case where a negative potential is applied to the conductor 205 than in the case where the negative potential is not applied to the conductor 205.

The electric resistivity of the conductor 205 is designed in consideration of the potential applied to the conductor 205, and the thickness of the conductor 205 is determined in accordance with the electric resistivity. The thickness of the insulator 216 is substantially equal to that of the conductor 205. The conductor 205 and the insulator 216 are preferably as thin as possible in the allowable range of the design of the conductor 205. When the thickness of the insulator 216 is reduced, the absolute amount of impurity such as hydrogen contained in the insulator 216 can be reduced, inhibiting the diffusion of the impurity into the metal oxide 230.

As illustrated in FIG. 7A, the conductor 205 is preferably provided to be larger than a region of the metal oxide 230 that does not overlap with the conductor 242a or the conductor 242b. As illustrated in FIG. 7C, it is particularly preferable that the conductor 205 extend to a region outside end portions of the metal oxide 230a and the metal oxide 230b in the channel width direction. That is, the conductor 205 and the conductor 260 preferably overlap with each other with the insulators therebetween on the outer side of the side surface of the metal oxide 230 in the channel width direction. With this structure, the channel formation region of the metal oxide 230 can be electrically surrounded by the electric field of the conductor 260 functioning as a first gate electrode and the electric field of the conductor 205 functioning as the second gate electrode. In this specification, a transistor structure in which a channel formation region is electrically surrounded by electric fields of the first gate electrode and the second gate electrode is referred to as a surrounded channel (S-channel) structure.

In this specification and the like, a transistor having the S-channel structure refers to a transistor having a structure in which a channel formation region is electrically surrounded by an electric field of one or the other of a pair of gate electrodes. The S-channel structure disclosed in this specification and the like has a structure that is different from a Fin-type structure and a planar structure. Meanwhile, the S-channel structure disclosed in this specification and the like can also be regarded as a kind of the Fin-type structure. Note that in this specification and the like, the Fin-type structure refers to a structure in which a gate electrode is placed so as to cover at least two or more surfaces (specifically, two surfaces, three surfaces, four surfaces, or the like) of a channel. With the Fin-type structure and the S-channel structure, resistance to a short-channel effect can be enhanced, that is, a transistor in which a short-channel effect is less likely to occur can be provided.

When the transistor 200 becomes normally-off and has the above-described S-Channel structure, the channel formation region can be electrically surrounded. Accordingly, the transistor 200 can be regarded as having a GAA (Gate All Around) structure or an LGAA (Lateral Gate All Around) structure. When the transistor 200 has the S-Channel structure, the GAA structure, or the LGAA structure, the channel formation region that is formed at the interface between the metal oxide 230 and the gate insulator or in the vicinity of the interface can be formed in the entire bulk of the metal oxide 230. Accordingly, the density of current flowing in the transistor can be improved, and it can be expected to improve the on-state current of the transistor or increase the field-effect mobility of the transistor.

Note that although FIG. 7A to FIG. 7D illustrate an example of a transistor with an S-channel structure as the transistor 200, the semiconductor device of one embodiment of the present invention is not limited thereto. For example, a transistor structure that can be used in one embodiment of the present invention is one or more selected from a planar structure, a Fin-type structure, and a GAA structure.

Furthermore, as illustrated in FIG. 7C, the conductor 205 is extended to function as a wiring as well. However, without limitation to this structure, a structure in which a conductor functioning as a wiring is provided below the conductor 205 may be employed. In addition, the conductor 205 is not necessarily provided in each transistor. For example, the conductor 205 may be shared by a plurality of transistors.

Although the transistor 200 having a structure in which the conductor 205 is a stack of the conductor 205a and the conductor 205b is illustrated, the present invention is not limited thereto. For example, the conductor 205 may be provided to have a single-layer structure or a stacked-layer structure of three or more layers.

The insulator 222 and the insulator 224 function as a gate insulator.

It is preferable that the insulator 222 have a function of inhibiting diffusion of hydrogen (e.g., at least one of a hydrogen atom, a hydrogen molecule, and the like). In addition, it is preferable that the insulator 222 have a function of inhibiting diffusion of oxygen (e.g., at least one of an oxygen atom, an oxygen molecule, and the like). For example, the insulator 222 preferably has a function of inhibiting diffusion of one or both of hydrogen and oxygen more than the insulator 224.

As the insulator 222, an insulator containing an oxide of one or both of aluminum and hafnium, which is an insulating material, is preferably used. For the insulator, aluminum oxide, hafnium oxide, an oxide containing aluminum and hafnium (hafnium aluminate), or the like is preferably used. Alternatively, an oxide containing hafnium and zirconium, e.g., a hafnium-zirconium oxide is preferably used. In the case where the insulator 222 is formed using such a material, the insulator 222 functions as a layer that inhibits release of oxygen from the metal oxide 230 to the substrate side and diffusion of impurities such as hydrogen from the periphery of the transistor 200 into the metal oxide 230. Thus, providing the insulator 222 can inhibit diffusion of impurities such as hydrogen into the transistor 200 and inhibit generation of oxygen vacancies in the metal oxide 230. Moreover, the conductor 205 can be inhibited from reacting with oxygen contained in the insulator 224 and the metal oxide 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. A stack of silicon oxide, silicon oxynitride, or silicon nitride over these insulators may be used for the insulator 222.

For example, a single layer or stacked layers of an insulator(s) containing what is called a high-k material such as aluminum oxide, hafnium oxide, tantalum oxide, zirconium oxide, or hafnium-zirconium oxide may be used for the insulator 222. As miniaturization and high integration of transistors progress, a problem such as a leakage current may arise because of a thinner gate insulator. When a high-k material is used for the insulator functioning as a gate insulator, a gate potential at the time of the operation of the transistor can be reduced while the physical thickness is maintained. Furthermore, a substance with a high permittivity such as lead zirconate titanate (PZT), strontium titanate (SrTiO₃), or (Ba,Sr)TiO₃ (BST) may be used for the insulator 222.

Silicon oxide or silicon oxynitride, for example, can be used as appropriate for the insulator 224 that is in contact with the metal oxide 230.

In the manufacturing process of the transistor 200, heat treatment is preferably performed with the surface of the metal oxide 230 exposed. For example, the heat treatment is performed at higher than or equal to 100° C. and lower than or equal to 600° C., preferably higher than or equal to 350° C. and lower than or equal to 550° C. Note that the heat treatment is performed in a nitrogen gas or inert gas atmosphere, or an atmosphere containing an oxidizing gas at 10 ppm or more, 1% or more, or 10% or more. For example, the heat treatment is preferably performed in an oxygen atmosphere. This can supply oxygen to the metal oxide 230 to reduce oxygen vacancies. The heat treatment may be performed under reduced pressure. Alternatively, the heat treatment may be performed in an atmosphere containing an oxidizing gas at 10 ppm or more, 1% or more, or 10% or more in order to compensate for oxygen released, after heat treatment in a nitrogen gas or inert gas atmosphere. Alternatively, the heat treatment may be performed in a nitrogen gas or inert gas atmosphere successively after heat treatment is performed in an atmosphere containing an oxidizing gas at 10 ppm or more, 1% or more, or 10% or more.

Note that by supplying oxygen to the metal oxide 230, the amount of oxygen vacancies in the metal oxide 230 can be repaired. Furthermore, hydrogen remaining in the metal oxide 230 reacts with supplied oxygen, so that the hydrogen can be removed as H₂O (dehydration). This can inhibit recombination of hydrogen remaining in the metal oxide 230 with oxygen vacancies and formation of V_{O}H.

Note that the insulator 222 and the insulator 224 may each have a stacked-layer structure of two or more layers. In that case, without limitation to a stacked-layer structure formed of the same material, a stacked-layer structure formed of different materials may be employed. The insulator 224 may be formed into an island shape so as to overlap with the metal oxide 230a. In this case, the insulator 275 is in contact with the side surfaces of the insulator 224 and the top surface of the insulator 222. Note that in this specification and the like, the term “island shape” refers to a state where two or more layers formed using the same material in the same step are physically separated from each other.

The conductor 242a and the conductor 242b are provided in contact with the top surface of the metal oxide 230b. Each of the conductor 242a and the conductor 242b functions as a source electrode or a drain electrode of the transistor 200.

For the conductor 242 (the conductor 242a and the conductor 242b), for example, a nitride containing tantalum, a nitride containing titanium, a nitride containing molybdenum, a nitride containing tungsten, a nitride containing tantalum and aluminum, a nitride containing titanium and aluminum, or the like is preferably used. In one embodiment of the present invention, a nitride containing tantalum is particularly preferable. As another example, ruthenium oxide, ruthenium nitride, an oxide containing strontium and ruthenium, or an oxide containing lanthanum and nickel may be used. These materials are preferable because they are each a conductive material that is not easily oxidized or a material that maintains the conductivity even after absorbing oxygen.

Note that hydrogen contained in the metal oxide 230b or the like diffuses into the conductor 242a or the conductor 242b in some cases. In particular, when a nitride containing tantalum is used for the conductor 242a and the conductor 242b, hydrogen contained in the metal oxide 230b or the like is likely to diffuse into the conductor 242a or the conductor 242b, and the diffused hydrogen is bonded to nitrogen contained in the conductor 242a or the conductor 242b in some cases. That is, hydrogen contained in the metal oxide 230b or the like is absorbed by the conductor 242a or the conductor 242b in some cases.

No curved surface is preferably formed between the side surface of the conductor 242 and the top surface of the conductor 242. When no curved surface is formed in the conductor 242, the conductor 242 can have a large cross-sectional area in the channel width direction as illustrated in FIG. 7D. Accordingly, the conductivity of the conductor 242 is increased, so that the on-state current of the transistor 200 can be increased.

When heat treatment is performed in the state where the conductor 242a (conductor 242b) and the metal oxide 230b are in contact with each other, the sheet resistance of the metal oxide 230b in a region overlapping with the conductor 242a (conductor 242b) is decreased in some cases. Furthermore, the carrier concentration is sometimes increased. Thus, the resistance of the metal oxide 230b in the region overlapping with the conductor 242a (conductor 242b) can be lowered in a self-aligned manner.

The insulator 271a is provided in contact with the top surface of the conductor 242a, and the insulator 271b is provided in contact with the top surface of the conductor 242b. The insulator 271 preferably functions as at least a barrier insulating film against oxygen. Thus, the insulator 271 preferably has a function of inhibiting oxygen diffusion. For example, the insulator 271 preferably has a function of inhibiting diffusion of oxygen more than the insulator 280. As the insulator 271, an insulator such as silicon nitride, aluminum oxide, or magnesium oxide is used, for example.

The insulator 275 is provided to cover the insulator 224, the metal oxide 230a, the metal oxide 230b, the conductor 242, and the insulator 271. Specifically, the insulator 275 includes a region in contact with the side surface of the metal oxide 230b, the side surface of the conductor 242a, and the side surface of the conductor 242b. The insulator 275 preferably has a function of capturing and fixing hydrogen. In that case, the insulator 275 preferably includes silicon nitride, or a metal oxide having an amorphous structure, for example, an insulator such as aluminum oxide or magnesium oxide. Alternatively, for example, a stacked-layer film of aluminum oxide and silicon nitride over the aluminum oxide may be used as the insulator 275.

When the above insulator 271 and the insulator 275 are provided, the conductor 242 can be surrounded by the insulators having a barrier property against oxygen. That is, oxygen contained in the insulator 224 and the insulator 280 can be prevented from diffusing into the conductor 242. As a result, the conductor 242 can be inhibited from being directly oxidized by oxygen contained in the insulator 224 and the insulator 280, so that an increase in resistivity and a reduction in on-state current can be inhibited.

The insulator 252 functions as part of the gate insulator. As the insulator 252, a barrier insulating film against oxygen is preferably used. As the insulator 252, an insulator that can be used as the insulator 282 described above is preferably used. An insulator containing an oxide of one or both of aluminum and hafnium may be used as the insulator 252. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used for the insulator 252. In this case, the insulator 252 contains at least oxygen and aluminum.

As illustrated in FIG. 7C, the insulator 252 is provided in contact with the top surface and the side surface of the metal oxide 230b, the side surface of the metal oxide 230a, the side surface of the insulator 224, and the top surface of the insulator 222. That is, the regions of the metal oxide 230a, the metal oxide 230b, and the insulator 224 that overlap with the conductor 260 are covered with the insulator 252 in the cross section in the channel width direction. With this structure, the insulator 252 having a barrier property against oxygen can prevent release of oxygen from the metal oxide 230a and the metal oxide 230b at the time of heat treatment, for example. This can inhibit formation of oxygen vacancies in the metal oxide 230a and the metal oxide 230b. Therefore, oxygen vacancies and V_{O}H formed in the region 230bc can be reduced. Thus, the transistor 200 can have favorable electrical characteristics and higher reliability.

Even when an excess amount of oxygen is contained in the insulator 280, the insulator 250 and the like, oxygen can be inhibited from being excessively supplied to the metal oxide 230a and the metal oxide 230b. Thus, the region 230ba and the region 230bb are inhibited from being excessively oxidized by oxygen through the region 230bc; a reduction in on-state current or field-effect mobility of the transistor 200 can be inhibited.

As illustrated in FIG. 7B, the insulator 252 is provided in contact with the side surfaces of the conductor 242, the insulator 271, the insulator 275, and the insulator 280. This can inhibit formation of an oxide film on the side surfaces of the conductor 242 by oxidization of the side surfaces. Accordingly, a reduction in on-state current or field-effect mobility of the transistor 200 can be inhibited.

Furthermore, the insulator 252 needs to be provided in an opening formed in the insulator 280 and the like, together with the insulator 254, the insulator 250, and the conductor 260. The thickness of the insulator 252 is preferably thin for miniaturization of the transistor 200. The thickness of the insulator 252 is greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In this case, at least part of the insulator 252 preferably includes a region having the above-described thickness. The thickness of the insulator 252 is preferably smaller than that of the insulator 250. In this case, at least part of the insulator 252 preferably includes a region having a thickness smaller than that of the insulator 250.

To form the insulator 252 having a small thickness as described above, an ALD method is preferably used for deposition. Examples of an ALD method include a thermal ALD method, in which a precursor and a reactant react with each other only by a thermal energy, and a PEALD (Plasma Enhanced ALD) method, in which a reactant excited by plasma is used. The use of plasma in a PEALD method is sometimes preferable because deposition at a lower temperature is possible.

An ALD method, which enables an atomic layer to be deposited one by one has advantages such as deposition of an extremely thin film, deposition on a component with a high aspect ratio, deposition of a film with a small number of defects such as pinholes, deposition with excellent coverage, and low-temperature deposition. Therefore, the insulator 252 can be deposited on the side surface of the opening formed in the insulator 280, for example, to have a small thickness like the above-described thickness and to have favorable coverage.

Note that some of precursors usable in an ALD method contain carbon, for example. Thus, in some cases, a film provided by an ALD method contains impurities such as carbon in a larger amount than a film provided by another deposition method. Note that impurities can be quantified by secondary ion mass spectrometry (SIMS), X-ray photoelectron spectroscopy (XPS), or auger electron spectroscopy (AES).

Note that appropriate adjustment of the deposition condition of the insulating film to be the insulator 250, the microwave treatment condition in an oxygen-containing atmosphere, the amount of oxygen added to the insulator 280 by deposition of the insulator 282, and the like can reduce oxygen vacancies and V_{O}H formed in the region 230bc and inhibit excess oxidation of the region 230ba and the region 230bb in some cases. In such a case, the structure without the insulator 252 enables simplification of the manufacturing process and the improvement in productivity of the semiconductor device.

The insulator 250 functions as part of the gate insulator. The insulator 250 is preferably placed in contact with the top surface of the insulator 252. The insulator 250 can be formed using silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, or the like. In particular, silicon oxide and silicon oxynitride, which are thermally stable, are preferable. The insulator 250 in this case is an insulator containing at least oxygen and silicon.

As in the insulator 224, the concentration of impurities such as water and hydrogen in the insulator 250 is preferably reduced. The thickness of the insulator 250 is preferably greater than or equal to 1 nm and less than or equal to 20 nm, further preferably greater than or equal to 0.5 nm and less than or equal to 15 nm. In particular, in order to form a minute transistor (e.g., a transistor with a gate length less than or equal to 10 nm), the thickness of the insulator 250 is preferably greater than or equal to 0.5 nm and less than or equal to 10 nm, further preferably greater than or equal to 0.5 nm and less than or equal to 5 nm. In this case, at least part of the insulator 250 preferably includes a region having the above-described thickness.

Although FIG. 7A to FIG. 7D and FIG. 8A illustrate a single-layer structure of the insulator 250, the present invention is not limited to this structure, and a stacked-layer structure of two or more layers may be employed. For example, as illustrated in FIG. 8B, the insulator 250 may have a stacked-layer structure including two layers of an insulator 250a and an insulator 250b over the insulator 250a.

Note that the insulator 252, the insulator 250, and the insulator 254 function as a gate insulating film (also referred to as a top gate insulating film or TGI) of the transistor. The thickness of the gate insulating film is preferably within a range of 1.3 nm to 10 nm inclusive, further preferably 1.5 nm to 5 nm inclusive. Note that the thickness of the gate insulating film in the above transistor is an equivalent oxide thickness (EOT). Note that the equivalent oxide thickness is a value obtained by converting the physical thickness of a film to the electrical thickness equivalent for silicon oxide.

For example, when aluminum oxide, silicon oxide, and silicon nitride are used for the insulator 252, the insulator 250, and the insulator 254, respectively, the total thickness of the insulator 252, the insulator 250, and the insulator 254 is converted into the equivalent oxide thickness.

When the thickness of the gate insulating film is within the above-described range, a subthreshold swing value (S value) which is one of the characteristics of a transistor can be reduced. For example, when a channel length L of an OSFET is within a range of 3 nm to 10 nm inclusive and the thickness of a gate insulating film of the OSFET is within a range of 1.5 nm to 5 nm inclusive, the S value of the OSFET can be greater than or equal to 60 mV/dec. and less than or equal to 200 mV/dec., preferably greater than or equal to 60 mV/dec. and less than or equal to 100 mV/dec., further preferably greater than or equal to 60 mV/dec. and less than or equal to 80 mV/dec. When the thickness of the gate insulating film in the OSFET is within the above range, the frequency characteristics (f characteristics) of a transistor is improved in some cases. In the case of the above-described OSFET, the transistor can operate at a drain voltage (Vd) and agate voltage (Vg) that are each within a range of 0.5 V to 3 V inclusive.

In the case where the insulator 250 has a stacked-layer structure of two layers as illustrated in FIG. 8B, it is preferable that the insulator 250a in a lower layer be formed using an insulator that is likely to transmit oxygen and the insulator 250b in an upper layer be formed using an insulator having a function of inhibiting oxygen diffusion. With such a structure, oxygen contained in the insulator 250a can be inhibited from diffusing into the conductor 260. That is, a reduction in the amount of oxygen supplied to the metal oxide 230 can be inhibited. In addition, oxidation of the conductor 260 due to oxygen contained in the insulator 250a can be inhibited. For example, it is preferable that the insulator 250a be provided using any of the above-described materials that can be used for the insulator 250 and the insulator 250b be provided using an insulator containing an oxide of one or both of aluminum and hafnium. As the insulator, aluminum oxide, hafnium oxide, an oxide containing aluminum and hafnium (hafnium aluminate), an oxide containing hafnium and silicon (hafnium silicate), or the like can be used. In this embodiment, hafnium oxide is used as the insulator 250b. In this case, the insulator 250b contains at least oxygen and hafnium. The thickness of the insulator 250b is greater than or equal to 0.5 nm and less than or equal to 5.0 nm, preferably greater than or equal to 1.0 nm and less than or equal to 5.0 nm, further preferably greater than or equal to 1.0 nm and less than or equal to 3.0 nm. In that case, at least part of the insulator 250b preferably includes a region having the above-described thickness.

In the case where silicon oxide, silicon oxynitride, or the like is used for the insulator 250a, the insulator 250b may be formed using an insulating material that is a high-k material having a high relative permittivity. The gate insulator having a stacked-layer structure of the insulator 250a and the insulator 250b can be thermally stable and can have a high relative permittivity. Accordingly, a gate potential applied during the operation of the transistor can be reduced while the physical thickness of the gate insulator is maintained. In addition, the equivalent oxide thickness (EOT) of the insulator functioning as the gate insulator can be reduced. Therefore, the withstand voltage of the insulator 250 can be increased.

The insulator 254 functions as part of a gate insulator. As the insulator 254, a barrier insulating film against hydrogen is preferably used. This can prevent diffusion of impurities such as hydrogen contained in the conductor 260 into the insulator 250 and the metal oxide 230b. As the insulator 254, an insulator that can be used as the insulator 283 described above may be used. For example, silicon nitride deposited by a PEALD method may be used as the insulator 254. In this case, the insulator 254 contains at least nitrogen and silicon.

Furthermore, the insulator 254 may have a barrier property against oxygen. Thus, diffusion of oxygen contained in the insulator 250 into the conductor 260 can be inhibited.

Furthermore, the insulator 254 needs to be provided in an opening formed in the insulator 280 and the like, together with the insulator 252, the insulator 250, and the conductor 260. The thickness of the insulator 254 is preferably small for miniaturization of the transistor 200. The thickness of the insulator 254 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In this case, at least part of the insulator 254 preferably includes a region having the above-described thickness. The thickness of the insulator 254 is preferably smaller than that of the insulator 250. In this case, at least part of the insulator 254 preferably include a region having a thickness that is smaller than that of the insulator 250.

Note that in the case where the insulator 250 has a stacked-layer structure of two layers as illustrated in FIG. 8B, an insulator having a function of inhibiting the passage of oxygen and impurities such as hydrogen, e.g., hafnium oxide, is used as the insulator 250b, whereby the insulator 250b can also have the function of the insulator 254. In such a case, the structure without the insulator 254 enables simplification of the manufacturing process and the improvement in productivity of the semiconductor device.

The conductor 260 functions as the first gate electrode of the transistor 200. The conductor 260 preferably includes the conductor 260a and the conductor 260b placed over the conductor 260a. For example, the conductor 260a is preferably placed to cover the bottom surface and the side surface of the conductor 260b. Moreover, as illustrated in FIG. 7B and FIG. 7C, the top surface of the conductor 260 is substantially level with the top surface of the insulator 250. Although the conductor 260 has a two-layer structure of the conductor 260a and the conductor 260b in FIG. 7B and FIG. 7C, the conductor 260 may have a single-layer structure or a stacked-layer structure of three or more layers.

For the conductor 260a, a conductive material having a function of inhibiting diffusion of impurities such as a hydrogen atom, a hydrogen molecule, a water molecule, a nitrogen atom, a nitrogen molecule, a nitrogen oxide molecule, and a copper atom is preferably used. Alternatively, it is preferable to use a conductive material having a function of inhibiting diffusion of oxygen (e.g., at least one of an oxygen atom, an oxygen molecule, and the like).

In addition, when the conductor 260a has a function of inhibiting diffusion of oxygen, the conductivity of the conductor 260b can be inhibited from being lowered because of oxidation due to oxygen contained in the insulator 250. As the conductive material having a function of inhibiting diffusion of oxygen, for example, titanium, titanium nitride, tantalum, tantalum nitride, ruthenium, or ruthenium oxide is preferably used.

The conductor 260 also functions as a wiring and thus is preferably formed using a conductor having high conductivity. For example, a conductive material containing tungsten, copper, or aluminum as its main component can be used for the conductor 260b. The conductor 260b may have a stacked-layer structure; for example, a stacked-layer structure of the conductive material and titanium or titanium nitride may be employed.

In the transistor 200, the conductor 260 is formed in a self-aligned manner to fill the opening formed in the insulator 280, for example. The formation of the conductor 260 in this manner allows the conductor 260 to be placed properly in a region between the conductor 242a and the conductor 242b without alignment.

As illustrated in FIG. 7C, in the channel width direction of the transistor 200, with reference to the bottom surface of the insulator 222, the level of the bottom surface of the conductor 260 in a region where the conductor 260 and the metal oxide 230b do not overlap with each other is preferably lower than the level of the bottom surface of the metal oxide 230b. When the conductor 260 functioning as the gate electrode covers the side surface and the top surface of the channel formation region of the metal oxide 230b with the insulator 250, for example, therebetween, the electric field of the conductor 260 can easily act on the entire channel formation region of the metal oxide 230b. Thus, the on-state current of the transistor 200 can be increased and the frequency characteristics of the transistor 200 can be improved. With a reference to the bottom surface of the insulator 222, the difference between the level of the bottom surface of the conductor 260 in a region where the conductor 260 do not overlap with the metal oxide 230a or the metal oxide 230b and the level of the bottom surface of the metal oxide 230b is greater than or equal to 0 nm and less than or equal to 100 nm, preferably greater than or equal to 3 nm and less than or equal to 50 nm, further preferably greater than or equal to 5 nm and less than or equal to 20 nm.

The insulator 280 is provided over the insulator 275, and the opening is formed in a region where the insulator 250 and the conductor 260 are to be provided. In addition, the top surface of the insulator 280 may be planarized.

The insulator 280 functioning as an interlayer film preferably has a low permittivity. When a material with a low permittivity is used for an interlayer film, parasitic capacitance generated between wirings can be reduced. The insulator 280 is preferably provided using a material similar to that for the insulator 216, for example. In particular, silicon oxide and silicon oxynitride, which are thermally stable, are preferable. In particular, materials such as silicon oxide, silicon oxynitride, and porous silicon oxide are preferably used, in which case a region containing oxygen released by heating can be easily formed.

The concentration of impurities such as water and hydrogen in the insulator 280 is preferably reduced. An oxide containing silicon, such as silicon oxide or silicon oxynitride, is used as appropriate for the insulator 280, for example.

The insulator 282 preferably functions as a barrier insulating film that inhibits impurities such as water and hydrogen from diffusing into the insulator 280 from above and preferably has a function of capturing impurities such as hydrogen. The insulator 282 preferably functions as a barrier insulating film that inhibits passage of oxygen. For the insulator 282, a metal oxide having an amorphous structure, for example, an insulator such as aluminum oxide can be used. In this case, the insulator 282 contains at least oxygen and aluminum. The insulator 282, which has a function of capturing impurities such as hydrogen, is provided in contact with the insulator 280 in a region interposed between the insulator 212 and the insulator 283, whereby impurities such as hydrogen contained in the insulator 280, for example, can be captured and the amount of hydrogen in the region can be constant. It is preferable to use, in particular, aluminum oxide having an amorphous structure for the insulator 282, because hydrogen can be captured or fixed more effectively in some cases. Accordingly, the transistor 200 and a semiconductor device which have favorable characteristics and high reliability can be manufactured.

As the insulator 282, aluminum oxide is preferably deposited by a sputtering method, further preferably, aluminum oxide is deposited by a pulsed DC sputtering method using an aluminum target in an atmosphere containing an oxygen gas. The use of the pulsed DC sputtering method can achieve more uniform film thickness and improve the sputtering rate and film quality. Here, RF (Radio Frequency) power may be applied to the substrate. The amount of oxygen implanted to a layer below the insulator 282 can be controlled depending on the amount of the RF power applied to the substrate. For example, the amount of oxygen implanted into the layer below the insulator 282 is smaller as the RF power is lower, and the amount of oxygen is easily saturated even when the insulator 282 has a small thickness. Moreover, the amount of oxygen implanted into the layer below the insulator 282 is larger as the RF power is higher.

The RF power is higher than or equal to 0 W/cm² and lower than or equal to 1.86 W/cm², for example. In other words, an appropriate amount of oxygen for the transistor characteristics can be changed and implanted by RF power used for the formation of the insulator 282. Accordingly, an appropriate amount of oxygen for improving the reliability of the transistor can be supplied.

The RF frequency is preferably greater than or equal to 10 MHz. The typical frequency is 13.56 MHz. The higher the RF frequency is, the less damage the substrate gets.

The insulator 283 is in contact with part of the top surface of the insulator 214, the side surface of the insulator 216, the side surface of an insulator 222, the side surface of an insulator 275, the side surface of the insulator 280, and the side surface and the top surface of the insulator 282.

The insulator 283 functions as a barrier insulating film that inhibits impurities such as water and hydrogen from diffusing into the insulator 280 from above. The insulator 283 is placed over the insulator 282. The insulator 283 is preferably formed using a nitride containing silicon such as silicon nitride or silicon nitride oxide. For example, silicon nitride deposited by a sputtering method may be used for the insulator 283. When the insulator 283 is deposited by a sputtering method, a high-density silicon nitride film can be formed. To obtain the insulator 283, silicon nitride deposited by a PEALD method or a CVD method may be stacked over silicon nitride deposited by a sputtering method.

For the conductor 240a and the conductor 240b, a conductive material containing tungsten, copper, or aluminum as its main component is preferably used. The conductor 240a and the conductor 240b may each have a stacked-layer structure.

In the case where the conductor 240 has a stacked-layer structure, a conductive material having a function of inhibiting passage of impurities such as water and hydrogen is preferably used for a first conductor placed in the vicinity of the insulator 285, the insulator 283, the insulator 282, the insulator 280, the insulator 275, and the insulator 271. For example, tantalum, tantalum nitride, titanium, titanium nitride, ruthenium, ruthenium oxide, or the like is preferably used. The conductive material having a function of inhibiting passage of impurities such as water and hydrogen may be used as a single layer or stacked layers. Moreover, impurities such as water and hydrogen contained in a layer above the insulator 283 can be inhibited from entering the metal oxide 230 through the conductor 240a and the conductor 240b.

For the insulator 241a and the insulator 241b, a barrier insulating film that can be used for the insulator 275 or the like may be used. For the insulator 241a and the insulator 241b, for example, an insulator such as silicon nitride, aluminum oxide, or silicon nitride oxide may be used. Since the insulator 241a and the insulator 241b are provided in contact with the insulator 283, the insulator 282, and the insulator 271, impurities such as water and hydrogen contained in the insulator 280 or the like can be inhibited from entering the metal oxide 230 through the conductor 240a and the conductor 240b. In particular, silicon nitride is suitable because of its high blocking property against hydrogen. Furthermore, oxygen contained in the insulator 280 can be prevented from being absorbed by the conductor 240a and the conductor 240b.

When the insulator 241a and the insulator 241b each have a stacked-layer structure illustrated in FIG. 7B, a first insulator in contact with an inner wall of the opening formed in the insulator 280 and the like and a second insulator on the inner side of the first insulator are preferably formed using a combination of a barrier insulating film against oxygen and a barrier insulating film against hydrogen.

For example, aluminum oxide deposited by an ALD method may be used as the first insulator and silicon nitride deposited by a PEALD method may be used as the second insulator. With this structure, oxidation of the conductor 240 can be inhibited, and hydrogen can be inhibited from entering the conductor 240.

The conductor 246 (the conductor 246a and the conductor 246b) functioning as a wiring may be placed in contact with the top surface of the conductor 240a and the top surface of the conductor 240b. The conductor 246 is preferably formed using a conductive material containing tungsten, copper, or aluminum as its main component. Furthermore, the conductor may have a stacked-layer structure and may be a stacked layer of titanium or titanium nitride and the conductive material, for example. Note that the conductor may be formed so as to be embedded in an opening provided in an insulator.

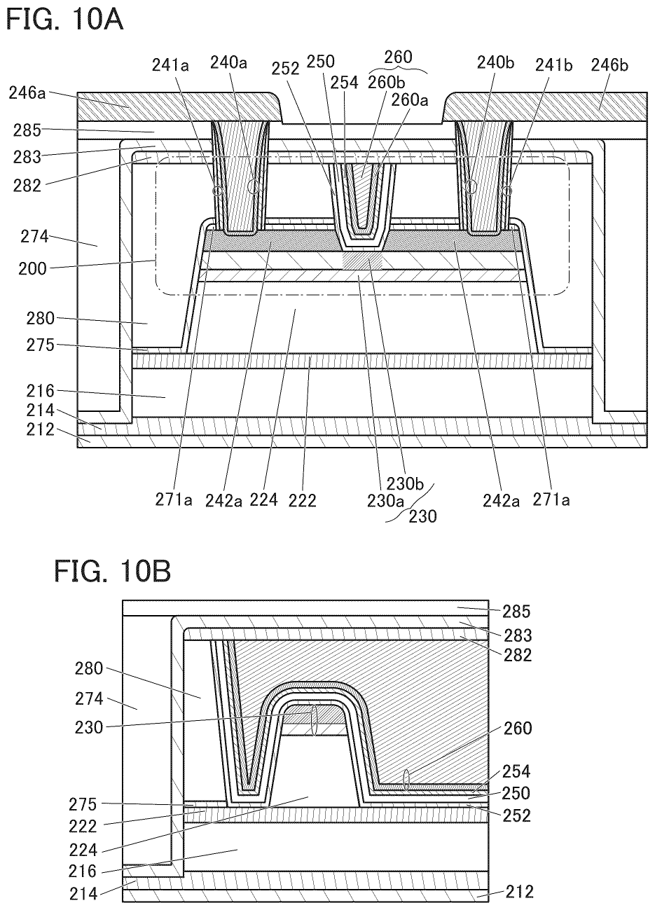

FIG. 10A and FIG. 10B are cross-sectional views illustrating a structure example of the transistor 200 and its periphery, which is a modification example of the structure illustrated in FIG. 7B and FIG. 7C. FIG. 10A illustrates a structure example of the transistor 200 in the channel length direction, and FIG. 10B illustrates a structure example of the transistor 200 in the channel width direction. The structure illustrated in FIG. 10A and FIG. 10B is different from the structure illustrated in FIG. 7B and FIG. 7C in that the conductor 205 functioning as the second gate electrode of the transistor 200 is not provided.

Since the conductor 205 is not provided in the transistor 200 illustrated in FIG. 10A and FIG. 10B, neither the insulator 222 nor the insulator 224 functions as a gate insulator. Here, since the metal oxide 230 in which the channel formation region of the transistor 200 is formed is provided over the insulator 224, it can be said that the transistor 200 is provided over the insulator 224. Thus, the insulator 224 can be referred to as a base insulator.

The insulator 224 can be separated for each transistor. Thus, a plurality of insulators 224 are provided in the semiconductor device including a plurality of transistors 200. The plurality of insulators 224 are collectively referred to as a base insulator group in some cases.

As illustrated in FIG. 10B, the conductor 260 functioning as the gate electrode of the transistor 200 covers the top surfaces of the metal oxide 230 and the insulator 224 and the side surfaces of the metal oxide 230 and the insulator 224 in the channel width direction with the insulator 252, the insulator 250, and the insulator 254 functioning as the gate insulator of the transistor 200 therebetween. For example, the conductor 260 covers the top surfaces of the metal oxide 230 and the insulator 224, the entire side surface of the metal oxide 230 in the channel width direction of the transistor 200, and at least part of the side surface of the insulator 224 in the channel width direction of the transistor 200 with the insulator 252, the insulator 250, and the insulator 254 therebetween. That is, the transistor 200 illustrated in FIG. 10B can be referred to as a Fin-type transistor.

The effective channel width is increased in the transistor 200 that is an OS transistor, whereby the on-state characteristics of the transistor 200 can be improved. In addition, contribution of the electric field of the gate electrode can be increased, so that the off-state characteristics of the transistor 200 can be improved.

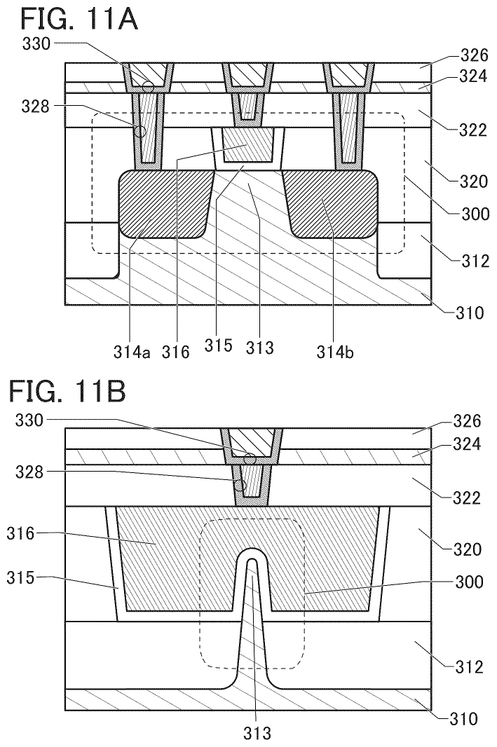

FIG. 11A and FIG. 11B are cross-sectional views illustrating a structure example of a transistor 300, which is a Si transistor included in the semiconductor device of one embodiment of the present invention, and its periphery. Here, FIG. 11A is a cross-sectional view of the transistor 300 in the channel length direction and FIG. 11B is a cross-sectional view of the transistor 300 in the channel width direction.

The transistor 300 can be provided in the layer 11 illustrated in FIG. 2, FIG. 3, FIG. 5, and FIG. 6. For example, the transistor 300 can be used as the transistor 41p illustrated in FIG. 3 and as the transistor MR3 and the transistor MS3 illustrated in FIG. 6.

The transistor 300 is provided on a substrate 310 and includes an element isolation layer 312, a conductor 316, an insulator 315, a semiconductor region 313 that is part of the substrate 310, and a low-resistance region 314a and a low-resistance region 314b functioning as a source region and a drain region. The semiconductor region 313 can be a channel formation region of the transistor 300. The insulator 315 functions as a gate insulator of the transistor 300, and the conductor 316 functions as a gate electrode of the transistor 300.

A silicon substrate, for example, a single crystal silicon substrate is used as the substrate 310. The substrate 310 may contain Ge (germanium), SiGe (silicon germanium), GaAs (gallium arsenide), GaAlAs (gallium aluminum arsenide), GaN (gallium nitride), or the like. For the substrate 310, a structure using silicon whose effective mass is controlled by applying stress to the crystal lattice and changing the lattice spacing may be employed. Alternatively, the transistor 300 may be a HEMT (High Electron Mobility Transistor) by using GaAs and GaAlAs, or the like for the substrate 310.

As illustrated in FIG. 11B, the semiconductor region 313 that is a part of the substrate 310 has a convex portion. In the transistor 300, the top surface and the side surface in the channel width direction of the semiconductor region 313 are covered with the conductor 316 with the insulator 315 therebetween. Such a Fin-type transistor 300 can have an increased effective channel width, and thus the transistor 300 can have improved on-state characteristics. In addition, contribution of the electric field of the gate electrode can be increased, so that the off-state characteristics of the transistor 300 can be improved.

The low-resistance region 314a and the low-resistance region 314b contain an element that imparts n-type conductivity, such as arsenic or phosphorus, or an element that imparts p-type conductivity, such as boron, in addition to the semiconductor material used in the semiconductor region 313.

For the conductor 316 functioning as a gate electrode, a semiconductor material such as silicon containing an element that imparts n-type conductivity, such as arsenic or phosphorus, or an element that imparts p-type conductivity, such as boron, or a conductive material such as a metal material, an alloy material, or a metal oxide material can be used.

Note that since the work function of a conductor depends on the material of the conductor, the threshold voltage of the transistor can be adjusted by selecting the material of the conductor. Specifically, it is preferable to use a material such as titanium nitride or tantalum nitride for the conductor. Moreover, in order to ensure both conductivity and embeddability, it is preferable to use stacked layers of metal materials such as tungsten or aluminum for the conductor, and it is particularly preferable to use tungsten in terms of heat resistance.

The element isolation layer 312 is provided to separate a plurality of transistors formed on the substrate 310 from each other. The element isolation layer can be formed by, for example, a LOCOS (LOCal Oxidation of Silicon) method, an STI (Shallow Trench Isolation) method, a mesa isolation method, or the like.

Over the transistor 300, an insulator 320, an insulator 322, an insulator 324, and an insulator 326 are stacked in this order from the substrate 310 side.

For the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride can be used, for example.

The insulator 322 may have a function of a planarization film for planarizing a level difference caused by the transistor 300 or the like covered with the insulator 320 and the insulator 322. For example, the top surface of the insulator 322 may be planarized by planarization treatment using a chemical mechanical polishing (CMP) method to improve planarity.

As the insulator 324, it is preferable to use a film having a barrier property that prevents diffusion of hydrogen, impurities, and the like from the substrate 310, the transistor 300, or the like into a region where the transistor 200 that can be an OS transistor is provided. As described above, the transistor 300 is provided in the layer 11 illustrated in FIG. 2, FIG. 3, FIG. 5, and FIG. 6, and the transistor 200 is provided in the layer 12 over the layer 11.

For the film having a barrier property against hydrogen, silicon nitride deposited by a CVD method can be used, for example. Here, diffusion of hydrogen to an OS transistor such as the transistor 200 degrades the characteristics of the transistor in some cases. Therefore, a film that inhibits hydrogen diffusion is preferably provided between the transistor 200 and the transistor 300. The film that inhibits hydrogen diffusion is specifically a film from which a small amount of hydrogen is released.

The amount of released hydrogen can be analyzed by thermal desorption spectroscopy (TDS), for example. The amount of hydrogen released from the insulator 324 that is converted into hydrogen atoms per unit area of the insulator 324 is less than or equal to 10×10¹⁵ atoms/cm², preferably less than or equal to 5×10¹⁵ atoms/cm² in TDS analysis in a film-surface temperature range of 50° C. to 500° C., for example.

Note that the permittivity of the insulator 326 is preferably lower than that of the insulator 324. For example, the relative permittivity of the insulator 326 is preferably lower than 4, further preferably lower than 3. The relative permittivity of the insulator 326 is, for example, preferably 0.7 times or less, further preferably 0.6 times or less the relative permittivity of the insulator 324. When a material with a low permittivity is used for an interlayer film, the parasitic capacitance generated between wirings can be reduced.

Moreover, a conductor 328, a conductor 330, and the like are embedded in the insulator 320, the insulator 322, the insulator 324, and the insulator 326. Note that the conductor 328 and the conductor 330 each function as a plug or a wiring.

As a material for each of the conductor 328 and the conductor 330, a single layer or stacked layers of a conductive material such as a metal material, an alloy material, a metal nitride material, or a metal oxide material can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

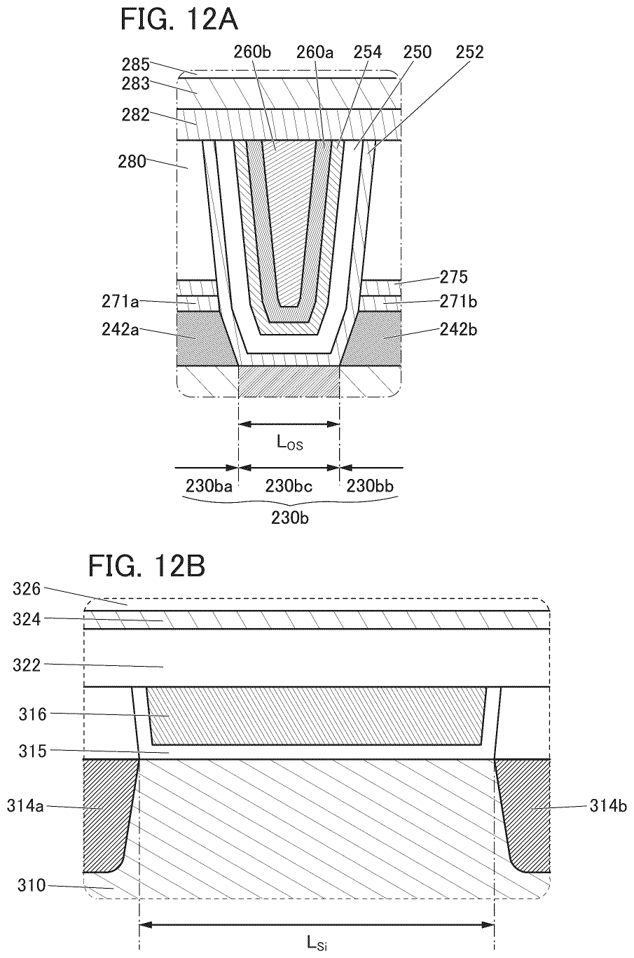

FIG. 12A is a cross-sectional view in the channel length direction illustrating a structure example of the gate electrode of the transistor 200, which is an OS transistor, and its periphery. FIG. 12B is a cross-sectional view in the channel length direction illustrating a structure example of the gate electrode of the transistor 300, which is a Si transistor, and its periphery.

In FIG. 12A, the channel length of the transistor 200 is denoted by a distance L_{OS}. The distance L_{OS} can be, for example, the distance between a lower end portion of the conductor 242a and a lower end portion of the conductor 242b. In FIG. 12B, the channel length of the transistor 300 is denoted by a distance L_{Si}. The distance L_{Si} can be, for example, the distance between an upper end portion of the low-resistance region 314a and an upper end portion of the low-resistance region 314b.

For example, in a silicon transistor, a semiconductor process node (e.g., a 5 nm node) and the channel length of an actual product do not correspond to each other in many cases. For example, when a transistor is formed in a 5-nm semiconductor process node, the channel length is greater than or equal to 14 nm and less than or equal to 16 nm, a line (L) is greater than or equal to 5 nm and less than or equal to 7 nm, and a space (S) is greater than or equal to 30 nm and less than or equal to 35 nm in some cases. Note that the line (L) represents the minimum line width of the transistor, and the space (S) represents the minimum pitch width of the transistor. Accordingly, the numerical value of the semiconductor process node is a mere indicator which indicates the degree of miniaturization. Thus, in the semiconductor device of one embodiment of the present invention, comparison between the distance L_{OS} that is the channel length of the transistor 200 and the distance L_{Si} that is the channel length of the transistor 300 as illustrated in FIG. 12A and FIG. 12B is an important component.

Note that a channel width (W) of the transistor depends on the on-state current (Ion) of the required transistor in circuit design. Thus, an optimal range of the channel width (W) of the transistor may be selected as appropriate by a practitioner.

In the case where the transistor 200 illustrated in FIG. 12A and the transistor 300 illustrated in FIG. 12B form a CMOS circuit, the distance L_{Si} is longer than the distance L_{OS}, whereby the difference between the mobility of the transistor 200 and mobility of the transistor 300 can be small as described above. Thus, even when the transistor 200 that is an OS transistor and the transistor 300 that is a Si transistor form the CMOS circuit, the CMOS circuit can be driven normally.

When the transistor 200 illustrated in FIG. 12A and the transistor 300 illustrated in FIG. 12B form the memory circuit 21, the distance L_{Si} is longer than the distance L_{OS}, whereby a potential supplied to a gate of the transistor 200 and a potential supplied to a gate of the transistor 300 can be supplied from the same power source as described above.

As described above, it is preferable that the distance L_{OS} be less than 15 nm and the distance L_{Si} be greater than or equal to 15 nm. Alternatively, it is preferable that the distance L_{OS} be greater than or equal to 3 nm and less than 15 nm, and the distance L_{Si} be greater than or equal to 15 nm and less than or equal to 40 nm. The distance L_{OS} can be typically greater than or equal to 5 nm and less than or equal to 8 nm.

A gate length of the transistor 200 that is an OS transistor is described below.

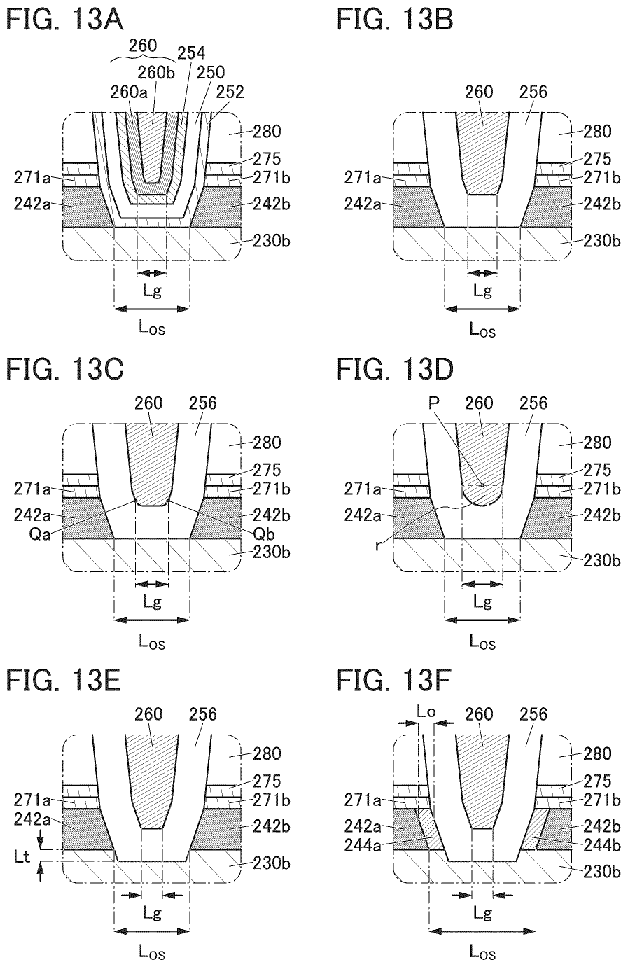

FIG. 13A is an enlarged view of the vicinity of the channel formation region in FIG. 7B. FIG. 13A is a cross-sectional view of the transistor 200 in the channel length direction. As described above, the insulator 252, the insulator 250, and the insulator 254 function as the first gate insulator.

Hereinafter, the insulator 252, the insulator 250, and the insulator 254 are collectively referred to as an insulator 256 in some cases. In this case, the insulator 256 includes the insulator 252, the insulator 250 over the insulator 252, and the insulator 254 over the insulator 250. The insulator 256 serves as the first gate insulator.

FIG. 13B is a cross-sectional view in which the insulator 252, the insulator 250, and the insulator 254 included in FIG. 13A are replaced with the insulator 256. In FIG. 13B, the conductor 260 is illustrated as a single layer for simplification of the drawing. Note that as described above, the conductor 260 may have a stacked-layer structure of the conductor 260a and the conductor 260b or a stacked-layer structure of three or more layers.

A width Lg illustrated in FIG. 13A and FIG. 13B is the width of the bottom surface of the conductor 260 in a region overlapping with the metal oxide 230b in a cross-sectional view in the channel length direction. Hereinafter, the bottom surface of the conductor 260 in the region overlapping with the metal oxide 230b in a cross-sectional view in the channel length direction is simply referred to as the bottom surface of the conductor 260 in the region overlapping with the metal oxide 230b in some cases. That is, the bottom surface of the conductor 260 in the region overlapping with the metal oxide 230b described later can be rephrased as the bottom surface of the conductor 260 in the region overlapping with the metal oxide 230b in a cross-sectional view in the channel length direction in some cases.

The gate length refers to the length of a gate electrode in a direction in which carriers move inside a channel formation region during operation of the transistor and to the width of the bottom surface of the gate electrode in a top view of the transistor. In this specification and the like, the gate length is the width of the bottom surface of the conductor 260 in the region overlapping with the metal oxide 230b in a cross-sectional view in the channel length direction. That is, the gate length is the width Lg illustrated in FIG. 13A and FIG. 13B. Note that the conductor 260 is provided in the opening included in the insulator 275 and the insulator 280. The sidewall of the opening is perpendicular to a substrate surface or inclined to the substrate surface. In particular, in the case where the angle formed between the sidewall of the opening and the substrate surface is less than or equal to 90°, the minimum width of the conductor 260 in the region overlapping with the metal oxide 230b is the width Lg. Thus, the conductor 260 can be regarded as having a region with the width Lg in a cross-sectional view in the channel length direction.

The bottom surface of the conductor 260 in the region overlapping with the metal oxide 230b preferably includes a flat region. As illustrated in FIG. 13A and FIG. 13B, in the case where the bottom surface of the conductor 260 in the region overlapping with the metal oxide 230b includes a flat region, the width Lg is the width of the flat region. When the bottom surface of the conductor 260 in the region overlapping with the metal oxide 230b includes the flat region, an electric field can be uniformly generated in the channel formation region of the metal oxide 230.

Although FIG. 13A and FIG. 13B each illustrate a structure in which the bottom surface of the conductor 260 in the region overlapping with the metal oxide 230b includes the flat region, the present invention is not limited thereto. In a cross-sectional view in the channel length direction, the bottom surface of the conductor 260 in the region overlapping with the metal oxide 230b may have a curve.

FIG. 13C illustrates a modification example of the transistor 200 in FIG. 13B. FIG. 13C is a cross-sectional view of the transistor 200 in the channel length direction. For example, as illustrated in FIG. 13C, the bottom surface of the conductor 260 in the region overlapping with the metal oxide 230b may include a flat region and a region having a curve. Note that the region having a curve is positioned at an end portion of each side of the bottom surface. Here, a point where the curve of the bottom surface on the conductor 242a side is in contact with the side surface of the conductor 260 on the conductor 242a side is referred to as a point Qa. A point where the curve of the bottom surface on the conductor 242b side is in contact with the side surface of the conductor 260 on the conductor 242b side is referred to as a point Qb. In this structure, the width Lg is the length of a line segment connecting the point Qa and the point Qb.

FIG. 13D illustrates a modification example of the transistor 200 in FIG. 13B. FIG. 13D is a cross-sectional view of the transistor 200 in the channel length direction. For example, as illustrated in FIG. 13D, the bottom surface of the conductor 260 may have an arc shape. Note that the arc has a radius r and a curvature center P is positioned in the conductor 260. In this structure, the width Lg is the width of a region where a straight line that includes the curvature center P and is parallel to the bottom surface of the metal oxide 230b overlaps with the conductor 260. In other words, the width Lg is twice as long as the radius r. Note that the straight line indicated by a dashed line in FIG. 13D is the straight line that includes the curvature center P and is parallel to the bottom surface of the metal oxide 230b.

Note that in the case where the radius r is large (e.g., the case where the radius r is larger than the channel length) in the shape of the bottom surface of the conductor 260 illustrated in FIG. 13D, the distance becomes large from the curvature center P to the channel formation region of the metal oxide 230b. At this time, the width Lg illustrated in FIG. 13C may be applied as the gate length of the shape. That is, the width Lg may be calculated by determining the point Qa and the point Qb in the shape of the bottom surface of the conductor 260 illustrated in FIG. 13D.

It is sometimes difficult to determine the point Qa and the point Qb in the shape of the bottom surface of the conductor 260 illustrated in FIG. 13C. At this time, the width Lg illustrated in FIG. 13D may be applied as the gate length of the shape. That is, the width Lg may be calculated by determining the curvature center P in the shape of the bottom surface of the conductor 260 illustrated in FIG. 13C.

The above is the description of the gate length. Next, the channel length is described.

As described above, the channel length of the transistor 200 is denoted by the distance L_{OS}. The distance L_{OS} can be, for example, the distance between the lower end portion of the conductor 242a and the lower end portion of the conductor 242b.

In the above structure, the channel length is set in accordance with a material used for the conductor 260, the gate length, a material used for the first gate insulator, the thickness of the first gate insulator, and the like. In the case where the gate length is within the above range, the channel length can be less than or equal to 60 nm, less than or equal to 50 nm, less than or equal to 40 nm, or less than or equal to 30 nm and greater than or equal to 10 nm, greater than or equal to 15 nm, or greater than or equal to 20 nm, for example.

Although details will be described later, in forming an opening in the insulator 280 and the insulator 275, an upper portion of the metal oxide 230b in a region overlapping with the opening is removed in some cases. In that case, as illustrated in FIG. 13E, the thickness of a region of the metal oxide 230b that overlaps with the conductor 260 is smaller than the thickness of a region of the metal oxide 230b that overlaps with the conductor 242a. Note that the transistor 200 illustrated in FIG. 13E is a modification example of the transistor 200 illustrated in FIG. 13B. FIG. 13E is a cross-sectional view of the transistor 200 in the channel length direction.

Here, the difference between the thickness of the region of the metal oxide 230b that overlaps with the conductor 260 and the thickness of the region of the metal oxide 230b that overlaps with the conductor 242a is referred to as a difference Lt (see FIG. 13E). When the difference Lt is small, the distance between the lower end portion of the conductor 242a and the lower end portion of the conductor 242b may be regarded as the channel length, for example.

In the case where the insulator 252 is formed to have a small thickness as described above, the layer 244a is sometimes formed between the conductor 242a and the insulator 256 as illustrated in FIG. 13F. In a similar manner, the layer 244b is sometimes formed between the conductor 242b and the insulator 256. In other words, the transistor 200 may include the layer 244a positioned between the conductor 242a and the insulator 256 and the layer 244b positioned between the conductor 242b and the insulator 256. Note that the transistor 200 illustrated in FIG. 13F is a modification example of the transistor 200 illustrated in FIG. 13E. FIG. 13F is a cross-sectional view of the transistor 200 in the channel length direction.

Each of the layer 244a and the layer 244b is formed by oxidation of the side surfaces of the conductor 242a and the conductor 242b. Thus, the layer 244a contains an element contained in the conductor 242a and oxygen. Furthermore, the layer 244b contains an element contained in the conductor 242b and oxygen. For example, in the case where the conductor 242a and the conductor 242b each contain a metal and nitrogen, the layer 244a and the layer 244b each contain the metal and oxygen.

The layer 244a has lower conductivity than the conductor 242a. Furthermore, the layer 244b has lower conductivity than the conductor 242b. Accordingly, even in the case where the transistor 200 includes the layer 244a and the layer 244b, the distance L between the lower end portion of the conductor 242a and the lower end portion of the conductor 242b may be regarded as the channel length. That is, when the layer 244a and the layer 244b are formed, the channel length can be increased. Accordingly, the source-drain withstand voltage of the transistor 200 can be improved, so that the transistor can be highly reliable.

Note that in the cross-sectional view in the channel length direction, the length in the channel length direction of the layer 244a is a length Lo (see FIG. 13F). Note that the length in the channel length direction of the layer 244b is equal to or substantially equal to the length Lo. The length Lo is preferably small. For example, the length Lo is preferably smaller than the width Lg. Specifically, the length Lo is preferably greater than or equal to 1 nm and less than 8 nm, further preferably greater than or equal to 2 nm and less than 5 nm. With this structure, even when the gate length is within the above range, the transistor 200 can have favorable electrical characteristics.

### <Structure Example 3 of Semiconductor Device>

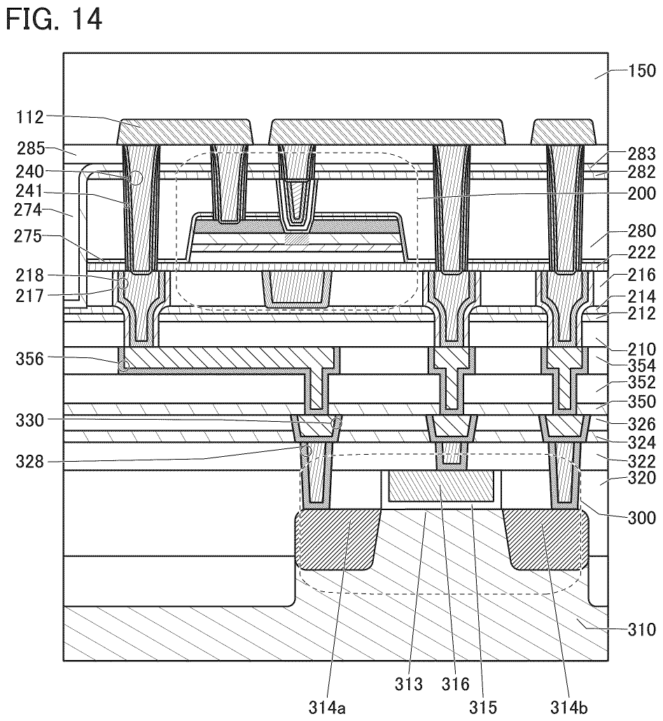

FIG. 14 is a cross-sectional view illustrating a structure example of a semiconductor device including the transistor 200 and the transistor 300. FIG. 14 illustrates an example in which the n-channel transistor 200 and the p-channel transistor 300 form an inverter. That is, in the example illustrated in FIG. 14, the transistor 200 corresponds to the transistor 41n illustrated in FIG. 3 and the transistor 300 corresponds to the transistor 41p illustrated in FIG. 3. FIG. 14 illustrates an example in which the transistor 200 has the structure illustrated in FIG. 7B and the transistor 300 has the structure illustrated in FIG. 11A.

### [Wiring Layer]

A wiring layer provided with an interlayer film, a wiring, a plug, and the like may be provided between the components. A plurality of wiring layers can be provided in accordance with design. Here, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases and part of a conductor functions as a plug in other cases.

For example, the insulator 320, the insulator 322, the insulator 324, and the insulator 326 are sequentially stacked over the transistor 300 as interlayer films. Moreover, the conductor 328, the conductor 330, and the like are embedded in the insulator 320, the insulator 322, the insulator 324, and the insulator 326. Note that the conductor 328 and the conductor 330 function as plugs or wirings.

The insulators functioning as interlayer films may also function as planarization films that cover uneven shapes therebelow. For example, the top surface of the insulator 322 may be planarized by planarization treatment using a chemical mechanical polishing (CMP) method to improve planarity.

A wiring layer may be provided over the insulator 326 and the conductor 330. For example, in FIG. 14, an insulator 350, an insulator 352, and an insulator 354 are stacked in this order. Furthermore, the conductor 356 is formed in the insulator 350, the insulator 352, and the insulator 354. The conductor 356 functions as a plug or a wiring.

Similarly, a conductor 218, the conductor (the conductor 205) included in the transistor 200, and the like are embedded in an insulator 210, the insulator 212, the insulator 214, and the insulator 216. Note that the conductor 218 has a function of a plug or a wiring. An insulator 150 is provided over a conductor 112.

Here, like the insulator 241 described in the above embodiment, an insulator 217 is provided in contact with the side surface of the conductor 218 functioning as a plug. The insulator 217 is provided in contact with an inner wall of an opening formed in the insulator 210, the insulator 212, the insulator 214, and the insulator 216. That is, the insulator 217 is provided between the conductor 218 and each of the insulator 210, the insulator 212, the insulator 214, and the insulator 216. Note that the conductor 205 and the conductor 218 can be formed in parallel; thus, the insulator 217 is sometimes formed in contact with the side surface of the conductor 205.

As the insulator 217, for example, an insulator such as silicon nitride, aluminum oxide, or silicon nitride oxide may be used. Since the insulator 217 is provided in contact with the insulator 210, the insulator 212, the insulator 214, and the insulator 222, entry of an impurity such as water and hydrogen into the metal oxide 230 through the conductor 218 from the insulator 210, the insulator 216, or the like can be inhibited. In particular, silicon nitride is suitable because of its high blocking property against hydrogen. Moreover, oxygen contained in the insulator 210 or the insulator 216 can be prevented from being absorbed by the conductor 218.

The insulator 217 can be formed in a manner similar to that of the insulator 241. For example, silicon nitride can be deposited by a PEALD method and an opening reaching the conductor 356 can be formed by anisotropic etching.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material with a low relative permittivity is used for the insulator functioning as an interlayer film, the parasitic capacitance generated between wirings can be reduced. Thus, a material is preferably selected depending on the function of an insulator.

For example, for the insulator 150, the insulator 210, the insulator 352, the insulator 354, and the like, an insulator having a low relative permittivity is preferably used. For example, the insulator preferably includes silicon oxide to which fluorine is added, silicon oxide to which carbon is added, silicon oxide to which carbon and nitrogen are added, porous silicon oxide, or a resin. Alternatively, the insulator preferably has a stacked-layer structure of a resin and silicon oxide, silicon oxynitride, silicon nitride oxide, silicon nitride, silicon oxide to which fluorine is added, silicon oxide to which carbon is added, silicon oxide to which carbon and nitrogen are added, or porous silicon oxide. When silicon oxide and silicon oxynitride, which are thermally stable, are combined with a resin, the stacked-layer structure can have thermal stability and a low relative permittivity. Examples of the resin include polyester, polyolefin, polyamide (nylon, aramid, or the like), polyimide, polycarbonate, and acrylic.

When a transistor using an oxide semiconductor is surrounded by an insulator having a function of inhibiting passage of oxygen and impurities such as hydrogen, the electrical characteristics of the transistor can be stable. Thus, the insulator having a function of inhibiting passage of oxygen and impurities such as hydrogen can be used as the insulator 214, the insulator 212, the insulator 350, and the like.

An insulator having a function of inhibiting passage of oxygen and impurities such as hydrogen can be formed to have a single layer or a stacked layer including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide; silicon nitride oxide; silicon nitride; or the like can be used.

As the conductor that can be used for a wiring or a plug, a material containing one or more kinds of metal elements selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, and the like can be used. A semiconductor having high electrical conductivity, typified by polycrystalline silicon containing an impurity element such as phosphorus may be used. Silicide such as nickel silicide may be used.

For example, for the conductor 328, the conductor 330, the conductor 356, the conductor 218, the conductor 112, and the like, a single-layer structure or a stacked-layer structure using a conductive material such as a metal material, an alloy material, a metal nitride material, or a metal oxide material that is formed using the above materials can be used. It is preferable to use a high-melting-point material that has both heat resistance and conductivity, such as tungsten or molybdenum, and it is preferable to use tungsten. Alternatively, a low-resistance conductive material such as aluminum or copper is preferably used. The use of a low-resistance conductive material can reduce wiring resistance.

### [Wiring or Plug in Layer Including Oxide Semiconductor]

In the case where an oxide semiconductor is used in the transistor 200, an insulator including an excess-oxygen region is provided in the vicinity of the oxide semiconductor in some cases. In that case, an insulator having a barrier property is preferably provided between the insulator including the excess-oxygen region and a conductor provided in the insulator including the excess-oxygen region.

For example, the insulator 241 is preferably provided between the insulator 280 containing excess oxygen and the conductor 240 in FIG. 14. Since the insulator 241 is provided in contact with the insulator 222, the insulator 282, and the insulator 283, the insulator 224 and the transistor 200 can be sealed with the insulators having a barrier property.

That is, the insulator 241 can inhibit excess oxygen included in the insulator 224 and the insulator 280 from being absorbed by the conductor 240. In addition, providing the insulator 241 can inhibit diffusion of hydrogen, which is an impurity, into the transistor 200 through the conductor 240.

Note that an insulating material having a function of inhibiting diffusion of oxygen and impurities such as water and hydrogen is preferably used for the insulator 241. For example, silicon nitride, silicon nitride oxide, aluminum oxide, hafnium oxide, or the like is preferably used. In particular, silicon nitride is preferable because of its high blocking property against hydrogen. Alternatively, a metal oxide such as magnesium oxide, gallium oxide, germanium oxide, yttrium oxide, zirconium oxide, lanthanum oxide, neodymium oxide, or tantalum oxide can be used, for example.

As described in the above embodiment, the transistor 200 may be sealed with the insulator 212, the insulator 214, the insulator 282, and the insulator 283. Such a structure can inhibit entry of hydrogen contained in the insulator 274, the insulator 150, or the like into the insulator 280, for example.

Here, the conductor 240 penetrates the insulator 283 and the insulator 282, and the conductor 218 penetrates the insulator 214 and the insulator 212; however, as described above, the insulator 241 is provided in contact with the conductor 240, and the insulator 217 is provided in contact with the conductor 218. This can reduce the amount of hydrogen entering the inside of the insulator 212, the insulator 214, the insulator 282, and the insulator 283 through the conductor 240 and the conductor 218. In this manner, the transistor 200 is sealed with the insulator 212, the insulator 214, the insulator 282, the insulator 283, the insulator 241, and the insulator 217, so that impurities such as hydrogen contained in the insulator 274 or the like can be inhibited from entering from the outside.

### [Dicing Line]

A dicing line (sometimes referred to as a scribe line, a dividing line, or a cutting line) which is provided when a large-sized substrate is divided into semiconductor elements so that a plurality of semiconductor devices are each taken as a chip is described below. Examples of a dividing method include the case where a groove (a dicing line) for dividing the semiconductor elements is formed on the substrate, and then the substrate is cut along the dicing line to divide (split) it into a plurality of semiconductor devices.

Here, for example, as illustrated in FIG. 14, a region in which the insulator 283 and the insulator 214 are in contact with each other is preferably designed to overlap with the dicing line. That is, an opening is provided in the insulator 282, the insulator 280, the insulator 275, the insulator 224, the insulator 222, and the insulator 216 in the vicinity of a region to be the dicing line that is provided on an outer edge of the memory circuit including the plurality of transistors 200.

That is, in the opening provided in the insulator 282, the insulator 280, the insulator 275, the insulator 224, the insulator 222, and the insulator 216, the insulator 214 is in contact with the insulator 283.

For example, an opening may be provided in the insulator 282, the insulator 280, the insulator 275, the insulator 224, the insulator 222, the insulator 216, and the insulator 214. With such a structure, in the opening provided in the insulator 282, the insulator 280, the insulator 275, the insulator 224, the insulator 222, the insulator 216, and the insulator 214, the insulator 212 is in contact with the insulator 283. In that case, the insulator 212 and the insulator 283 may be formed using the same material, and the insulator 212 and the insulator 283 may be formed by the same method. When the insulator 212 and the insulator 283 are formed using the same material and the same method, the adhesion therebetween can be increased. For example, silicon nitride is preferably used.

With the structure, the transistors 200 can be surrounded by the insulator 212, the insulator 214, the insulator 282, and the insulator 283. Since at least one of the insulator 212, the insulator 214, the insulator 282, and the insulator 283 has a function of inhibiting diffusion of oxygen, hydrogen, and water, even when the substrate is divided into circuit regions each of which is provided with the semiconductor elements described in this embodiment to be processed into a plurality of chips, entry and diffusion of impurities such as hydrogen and water from the direction of the side surface of the divided substrate into the transistor 200 can be prevented.

With the structure, excess oxygen in the insulator 280 and the insulator 224 can be prevented from diffusing to the outside. Accordingly, excess oxygen in the insulator 280 and the insulator 224 is efficiently supplied to the oxide where the channel is formed in the transistor 200. The oxygen can reduce oxygen vacancies in the oxide where the channel is formed in the transistor 200. Thus, the oxide where the channel is formed in the transistor 200 can be an oxide semiconductor with a low density of defect states and stable characteristics. That is, the transistor 200 can have a small variation in the electrical characteristics and higher reliability.

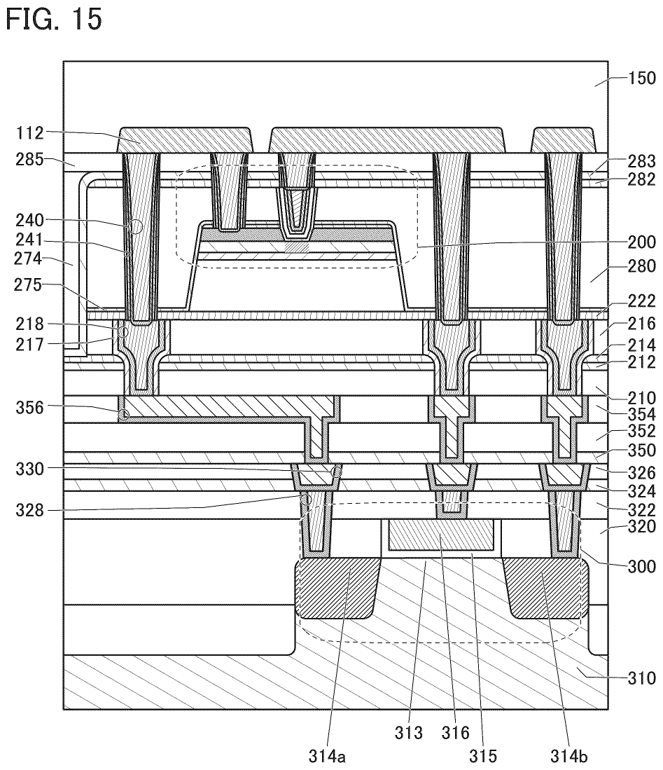

FIG. 15 is a cross-sectional view illustrating a structure example of a semiconductor device, which is a modification example of the structure illustrated in FIG. 14. The semiconductor device illustrated in FIG. 15 has a structure of the transistor 200 illustrated in FIG. 10A.

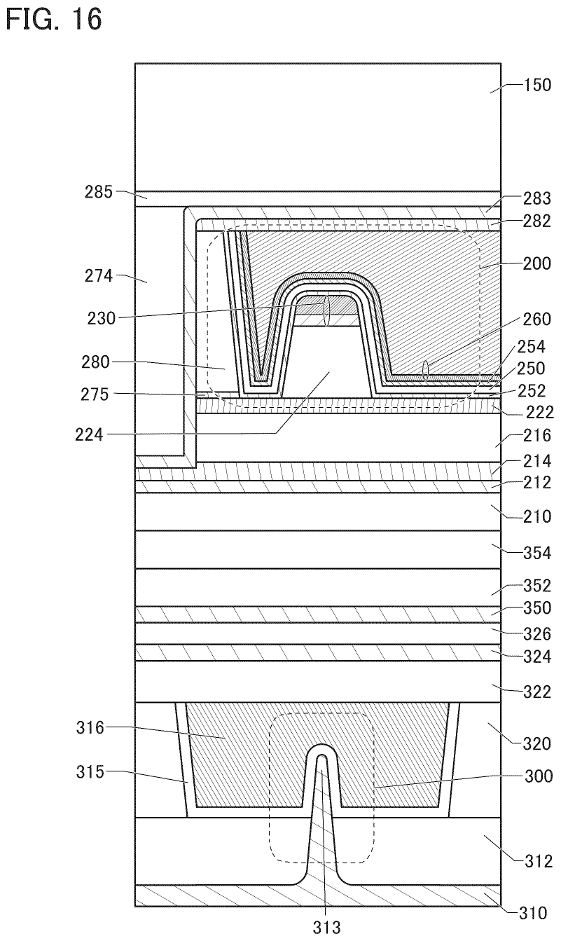

FIG. 16 is a cross-sectional view in the channel width direction of the transistor 200 and the transistor 300 of the semiconductor device illustrated in FIG. 15. As illustrated in FIG. 16, it is preferable that both the transistor 200 and the transistor 300 be Fin-type transistors, in which case both the transistor 200 and the transistor 300 can be transistors with high on-state characteristics and high off-state characteristics.

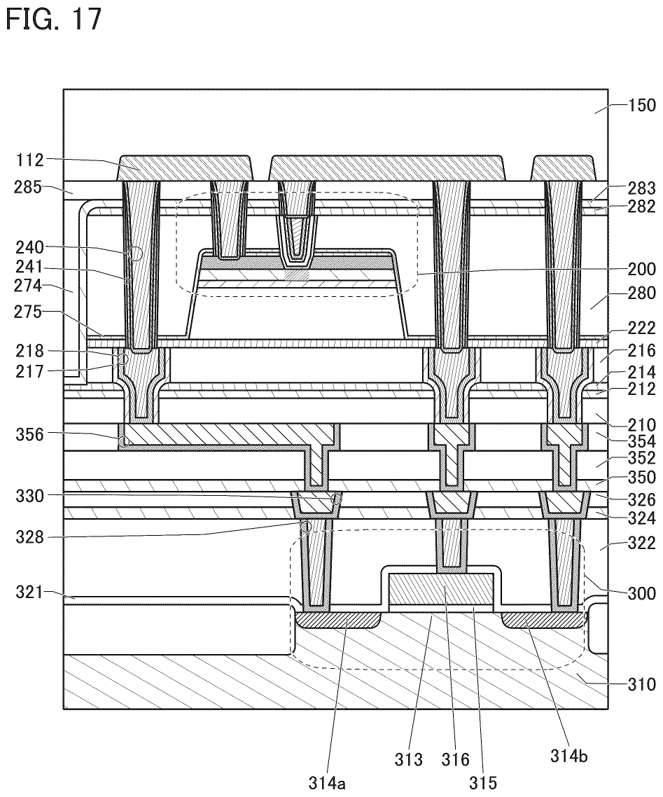

The transistor 300 is not necessarily a Fin-type transistor. FIG. 17 illustrates an example in which the transistor 300 is a planar type, which is a modification example of the semiconductor device illustrated in FIG. 15. When the transistor 300 is a planar type, the manufacturing process of the transistor 300 can be simplified.

### <Structure Example 4 of Semiconductor Device>

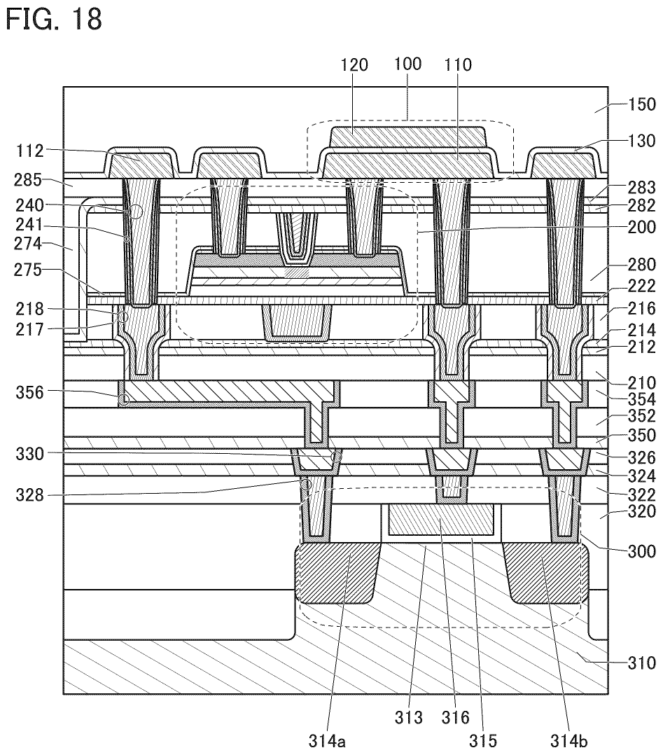

FIG. 18 is a cross-sectional view illustrating a structure example of a semiconductor device including the transistor 200 and the transistor 300. In FIG. 18, the transistor 200 corresponds to, for example, the transistor MW3 illustrated in FIG. 6, and the transistor 300 corresponds to, for example, the transistor MR3 illustrated in FIG. 6. FIG. 18 illustrates an example in which a capacitor 100 is provided above the transistor 200. The capacitor 100 corresponds to, for example, the capacitor CS3 illustrated in FIG. 6. FIG. 18 illustrates an example in which the transistor 200 has the structure illustrated in FIG. 7B and the transistor 300 has the structure illustrated in FIG. 11A.

### [Capacitor]

The capacitor 100 is provided above the transistor 200. The capacitor 100 includes a conductor 110 functioning as one of a pair of electrodes, a conductor 120 functioning as the other of the pair of electrodes, and an insulator 130 functioning as a dielectric. Here, for the insulator 130, the insulator that can be used as the insulator 283 described above is preferably used.

For example, the conductor 112 and the conductor 110 provided over the conductor 240 can be formed in parallel. Note that the conductor 112 functions as a plug or a wiring that is electrically connected to the capacitor 100, the transistor 200, or the transistor 300.

Although an example in which the conductor 112 and the conductor 110 having a single-layer structure is illustrated in FIG. 18, the structure is not limited thereto; a stacked-layer structure of two or more layers may be employed. For example, between a conductor having a barrier property and a conductor having high conductivity, a conductor that is highly adhesive to the conductor having a barrier property and the conductor having high conductivity may be formed.

For the insulator 130, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like may be used. A stack or a single layer including any of these materials can be provided in the insulator 130.

For example, for the insulator 130, a stacked-layer structure of a material with high dielectric strength such as silicon oxynitride and a high permittivity (high-k) material is preferably used. With this structure, electrostatic breakdown can be inhibited while sufficient capacitance of the capacitor 100 is maintained.

Examples of the high permittivity material (a material having a high relative permittivity) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. Alternatively, for the insulator 130, the above-described high permittivity material may be stacked. Examples of the stack include a three-layer structure of zirconium oxide, aluminum oxide over the zirconium oxide, and zirconium oxide over the aluminum oxide.

Examples of a material with high dielectric strength (a material having a low relative permittivity) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

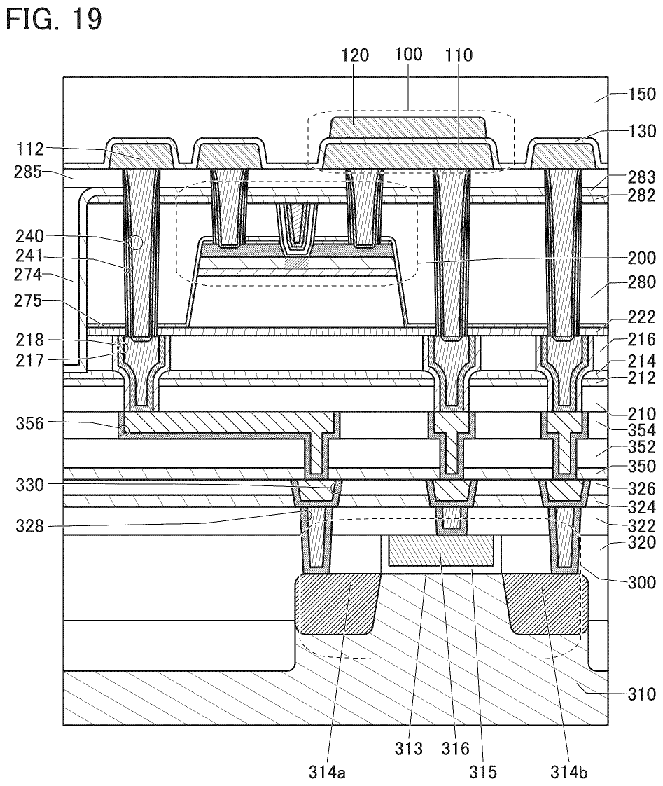

FIG. 19 is a cross-sectional view illustrating a structure example of a semiconductor device, which is a modification example of the structure illustrated in FIG. 18. The semiconductor device illustrated in FIG. 19 has a structure of the transistor 200 illustrated in FIG. 10A. Here, the cross sections of the transistor 200 and the transistor 300 in the channel width direction can have the structure illustrated in FIG. 16. Each of the transistor 200 and the transistor 300 illustrated in FIG. 19 is a Fin-type transistor. As described above, it is preferable that both the transistor 200 and the transistor 300 be Fin-type transistors, in which case both the transistor 200 and the transistor 300 can be transistors with high on-state characteristics and high off-state characteristics.

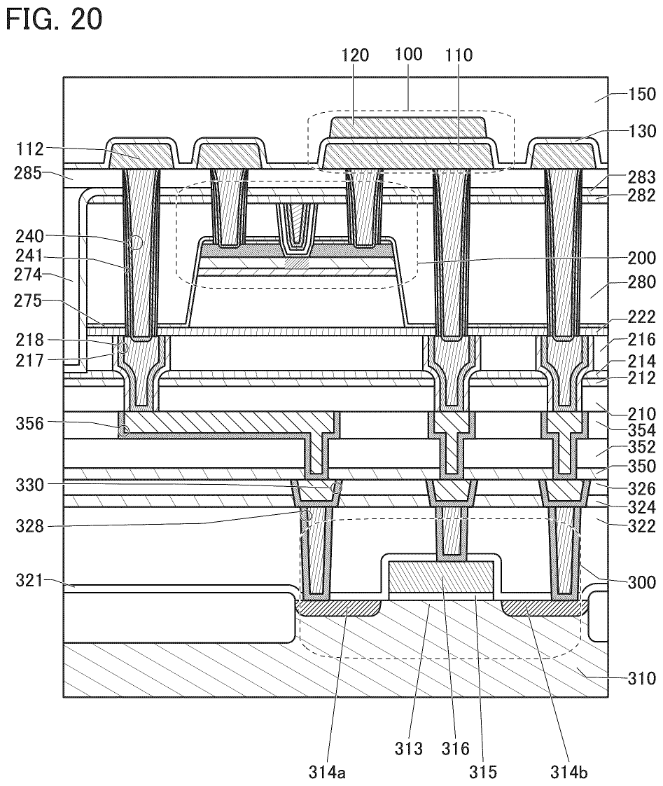

As described above, the transistor 300 is not necessarily a Fin-type transistor. FIG. 20 illustrates an example in which the transistor 300 is a planar type, which is a modification example of the semiconductor device illustrated in FIG. 19. As described above, when the transistor 300 is a planar type, the manufacturing process of the transistor 300 can be simplified.

At least part of the structure, method, and the like described in this embodiment can be implemented in appropriate combination with other embodiments, an example, and the like described in this specification.

### Embodiment 2

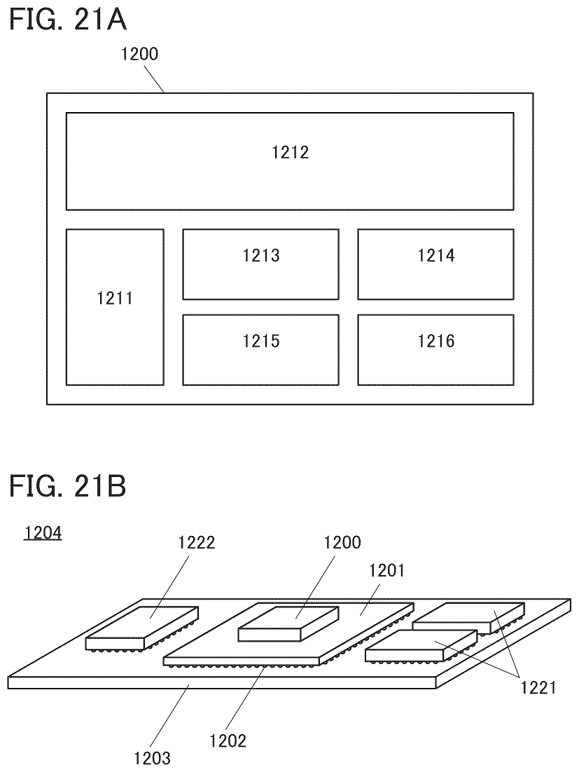

In this embodiment, an example of a chip 1200 on which the semiconductor device of the present invention is mounted will be described with reference to FIG. 21A and FIG. 21B. A plurality of circuits (systems) are mounted on the chip 1200. A technique for integrating a plurality of circuits (systems) into one chip is referred to as system on chip (SoC) in some cases.

As illustrated in FIG. 21A, the chip 1200 includes a CPU 1211, a GPU 1212, one or more analog arithmetic units 1213, one or more memory controllers 1214, one or more interfaces 1215, one or more network circuits 1216, and the like.

A bump (not illustrated) is provided on the chip 1200, and as illustrated in FIG. 21B, the chip 1200 is connected to a first surface of a package board 1201. In addition, a plurality of bumps 1202 are provided on a rear side of the first surface of the package board 1201, and the package board 1201 is connected to a motherboard 1203.

Memory devices such as DRAMs 1221 and a flash memory 1222 may be provided over the motherboard 1203. For example, the DOSRAM described in the above embodiment can be used as the DRAM 1221. In addition, for example, the NOSRAM described in the above embodiment can be used as the flash memory 1222.

The CPU 1211 preferably includes a plurality of CPU cores. In addition, the GPU 1212 preferably includes a plurality of GPU cores. Furthermore, the CPU 1211 and the GPU 1212 may each include a memory for temporarily storing data. Alternatively, a common memory for the CPU 1211 and the GPU 1212 may be provided in the chip 1200. The NOSRAM or the DOSRAM described above can be used as the memory. Moreover, the GPU 1212 is suitable for parallel computation of a number of data and thus can be used for image processing or product-sum operation. When an image processing circuit or a product-sum operation circuit using an oxide semiconductor of the present invention are provided in the GPU 1212, image processing and product-sum operation can be performed with low power consumption.

In addition, since the CPU 1211 and the GPU 1212 are provided on the same chip, a wiring between the CPU 1211 and the GPU 1212 can be shortened, and the data transfer from the CPU 1211 to the GPU 1212, the data transfer between memories included in the CPU 1211 and the GPU 1212, and the transfer of arithmetic operation results from the GPU 1212 to the CPU 1211 after the arithmetic operation in the GPU 1212 can be performed at a high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus) and an HDMI (registered trademark) (High-Definition Multimedia Interface) can be used, for example.

The network circuit 1216 includes a network circuit such as a LAN (Local Area Network). The network circuit 1216 may further include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be manufactured at low cost.

The motherboard 1203 provided with the package board 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 is excellent in image processing, and thus is suitably used in a portable electronic device such as a smartphone, a tablet terminal, a laptop PC, or a portable (mobile) game machine. Furthermore, the product-sum operation circuit using the GPU 1212 can perform a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

At least part of the structure, method, and the like described in this embodiment can be implemented in appropriate combination with other embodiments, an example, and the like described in this specification.

### Embodiment 3

Shown in this embodiment are examples of electronic components and electronic devices in which the memory device, for example, described in the above embodiment is incorporated.

### <Electronic Component>

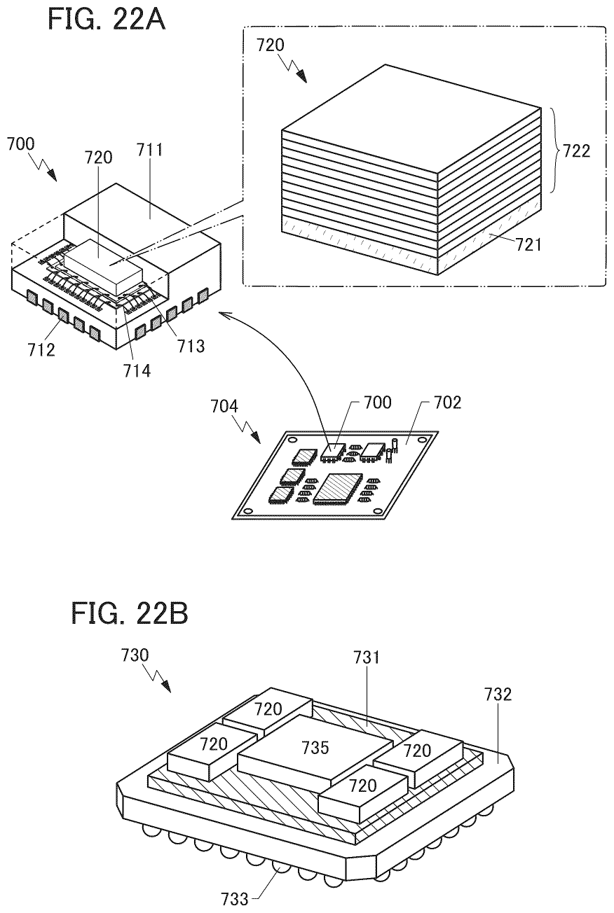

First, examples of an electronic component including a memory device 720 are described with reference to FIG. 22A and FIG. 22B.

FIG. 22A is a perspective view of an electronic component 700 and a substrate (circuit board 704) on which the electronic component 700 is mounted. The electronic component 700 in FIG. 22A includes the memory device 720 in a mold 711. FIG. 22A omits part of the electronic component to show the inside of the electronic component 700. The electronic component 700 includes a land 712 outside the mold 711. The land 712 is electrically connected to an electrode pad 713, and the electrode pad 713 is electrically connected to the memory device 720 via a wire 714. The electronic component 700 is mounted on a printed circuit board 702, for example. A plurality of such electronic components are combined and electrically connected to each other on the printed circuit board 702, which forms the circuit board 704.

The memory device 720 includes a driver circuit layer 721 and a memory circuit layer 722.

FIG. 22B is a perspective view of an electronic component 730. The electronic component 730 is an example of a SiP (System in Package) or an MCM (Multi Chip Module). In the electronic component 730, an interposer 731 is provided over a package board 732 (printed circuit board) and a semiconductor device 735 and a plurality of memory devices 720 are provided over the interposer 731.

The electronic component 730 using the memory device 720 as a high bandwidth memory (HBM) is illustrated as an example. An integrated circuit (a semiconductor device) such as a CPU, a GPU, or an FPGA can be used as the semiconductor device 735.

As the package board 732, a ceramic substrate, a plastic substrate, a glass epoxy substrate, or the like can be used. As the interposer 731, a silicon interposer, a resin interposer, or the like can be used.

The interposer 731 includes a plurality of wirings and has a function of electrically connecting a plurality of integrated circuits with different terminal pitches. The plurality of wirings are provided in a single layer or multiple layers. The interposer 731 has a function of electrically connecting an integrated circuit provided on the interposer 731 to an electrode provided on the package board 732. Accordingly, the interposer is referred to as a “redistribution substrate” or an “intermediate substrate” in some cases. A through electrode may be provided in the interposer 731 to be used for electrically connecting the integrated circuit and the package board 732. In a silicon interposer, a TSV (Through Silicon Via) can also be used as the through electrode.

A silicon interposer is preferably used as the interposer 731. A silicon interposer can be manufactured at lower cost than an integrated circuit because it is not necessary to provide an active element. Meanwhile, since wirings of a silicon interposer can be formed through a semiconductor process, formation of minute wirings, which is difficult for a resin interposer, is easy.

In order to achieve a wide memory bandwidth, many wirings need to be connected to an HBM. Therefore, formation of minute and high-density wirings is required for an interposer on which an HBM is mounted. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, the surface of a silicon interposer has high planarity, so that a poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on an interposer.

A heat sink (radiator plate) may be provided to overlap with the electronic component 730. In the case of providing a heat sink, the heights of integrated circuits provided on the interposer 731 are preferably the same. In the electronic component 730 of this embodiment, the heights of the memory device 720 and the semiconductor device 735 are preferably the same, for example.

An electrode 733 may be provided on the bottom portion of the package board 732 to mount the electronic component 730 on another substrate. FIG. 22B illustrates an example in which the electrode 733 is formed of a solder ball. Solder balls are provided in a matrix on the bottom portion of the package board 732, whereby a BGA (Ball Grid Array) can be achieved. Alternatively, the electrode 733 may be formed of a conductive pin. When conductive pins are provided in a matrix on the bottom portion of the package board 732, a PGA (Pin Grid Array) can be achieved.

The electronic component 730 can be mounted on another substrate by various mounting methods not limited to BGA and PGA. For example, a mounting method such as SPGA (Staggered Pin Grid Array), LGA (Land Grid Array), QFP (Quad Flat Package), QFJ (Quad Flat J-leaded package), or QFN (Quad Flat Non-leaded package) can be employed.

At least part of the structure, method, and the like described in this embodiment can be implemented in appropriate combination with other embodiments, an example, and the like described in this specification.

### Embodiment 4

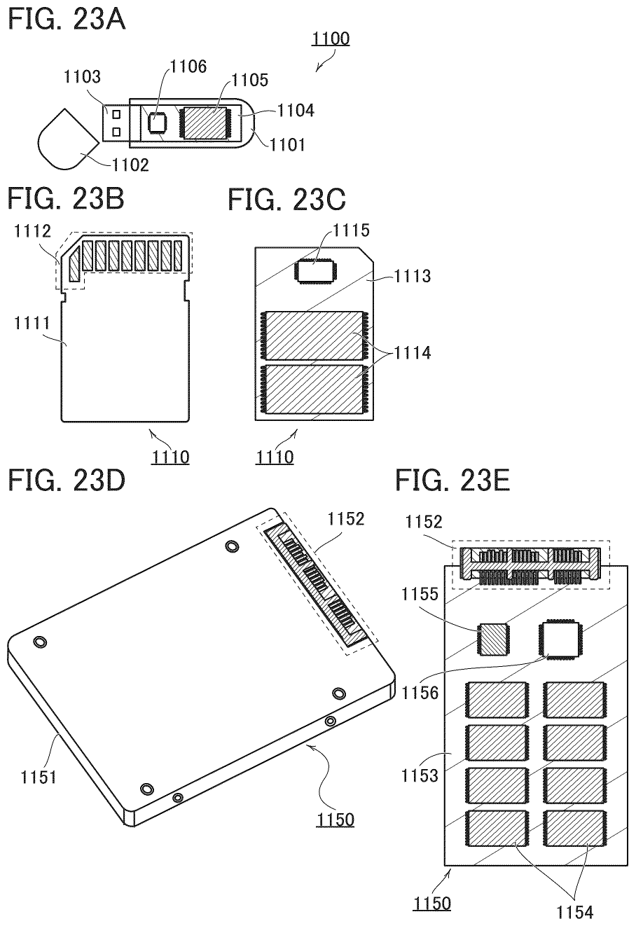

In this embodiment, application examples of the memory device using the semiconductor device described in the above embodiment are described. The semiconductor device described in the above embodiment can be applied to, for example, memory devices of a variety of electronic devices (e.g., information terminals, computers, smartphones, e-book readers, digital cameras (including video cameras), video recording/reproducing devices, and navigation systems). Here, the computers refer not only to tablet computers, notebook computers, and desktop computers, but also to large computers such as server systems. Alternatively, the semiconductor device described in the above embodiment is applied to a variety of removable memory devices such as memory cards (e.g., SD cards), USB memories, and SSDs (solid state drives). FIG. 23A to FIG. 23E schematically illustrate some structure examples of removable memory devices. The semiconductor device described in the above embodiment is processed into a packaged memory chip and used in a variety of storage devices and removable memories, for example.

FIG. 23A is a schematic view of a USB memory. A USB memory 1100 includes a housing 1101, a cap 1102, a USB connector 1103, and a substrate 1104. The substrate 1104 is held in the housing 1101. The substrate 1104 is provided with a memory chip 1105 and a controller chip 1106, for example. The semiconductor device described in the above embodiment can be incorporated in the memory chip 1105, for example.

FIG. 23B is a schematic external view of an SD card, and FIG. 23C is a schematic view of the internal structure of the SD card. An SD card 1110 includes a housing 1111, a connector 1112, and a substrate 1113. The substrate 1113 is held in the housing 1111. The substrate 1113 is provided with a memory chip 1114 and a controller chip 1115, for example. When the memory chip 1114 is also provided on the back side of the substrate 1113, the capacity of the SD card 1110 can be increased. In addition, a wireless chip with a radio communication function may be provided on the substrate 1113. With this, data can be read from and written in the memory chip 1114 by radio communication between a host device and the SD card 1110. The semiconductor device described in the above embodiment can be incorporated in the memory chip 1114, for example.

FIG. 23D is a schematic external view of an SSD, and FIG. 23E is a schematic view of the internal structure of the SSD. An SSD 1150 includes a housing 1151, a connector 1152, and a substrate 1153. The substrate 1153 is held in the housing 1151. The substrate 1153 is provided with a memory chip 1154, a memory chip 1155, and a controller chip 1156, for example. The memory chip 1155 is a work memory of the controller chip 1156, and a DOSRAM chip can be used, for example. When the memory chip 1154 is also provided on the back side of the substrate 1153, the capacity of the SSD 1150 can be increased. The semiconductor device described in the above embodiment can be incorporated in the memory chip 1154, for example. At least part of the structure, method, and the like described in this embodiment can be implemented in appropriate combination with other embodiments, an example, and the like described in this specification.

### Embodiment 5

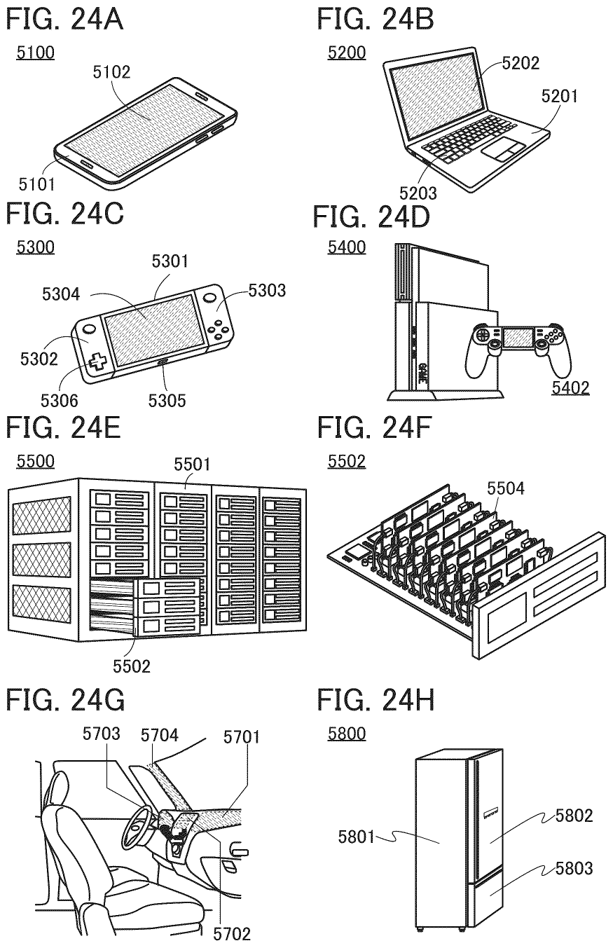

The semiconductor device of one embodiment of the present invention can be used as a chip or a processor such as a CPU or a GPU. FIG. 24A to FIG. 24H illustrate specific examples of electronic devices including a chip or a processor such as a CPU or a GPU of one embodiment of the present invention.

### <Electronic Device and System>

The GPU or the chip of one embodiment of the present invention can be mounted on a variety of electronic devices. Examples of electronic devices include a digital camera, a digital video camera, a digital photo frame, an e-book reader, a mobile phone, a portable game machine, a portable information terminal, and an audio reproducing device in addition to electronic devices provided with a relatively large screen, such as a television device, a monitor for a desktop or notebook information terminal or the like, digital signage, and a large game machine like a pachinko machine. When the GPU or the chip of one embodiment of the present invention is provided in the electronic device, the electronic device can include artificial intelligence.

The electronic device of one embodiment of the present invention may include an antenna. When a signal is received by the antenna, the electronic device can display a video, information, or the like on a display portion. When the electronic device includes the antenna and a secondary battery, the antenna may be used for contactless power transmission.

The electronic device of one embodiment of the present invention may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device of one embodiment of the present invention can have a variety of functions. For example, the electronic device can have a function of displaying a variety of kinds of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium. FIG. 24A to FIG. 24H illustrate examples of electronic devices.

### [Information Terminal]

FIG. 24A illustrates a mobile phone (smartphone), which is a type of information terminal. An information terminal 5100 includes a housing 5101 and a display portion 5102. As input interfaces, a touch panel is provided in the display portion 5102 and a button is provided in the housing 5101.

When the chip of one embodiment of the present invention is applied to the information terminal 5100, the information terminal 5100 can execute an application utilizing artificial intelligence. Examples of the application utilizing artificial intelligence include an application for recognizing a conversation and displaying the content of the conversation on the display portion 5102; an application for recognizing letters, figures, or the like input to the touch panel of the display portion 5102 by a user and displaying them on the display portion 5102; and an application for performing biometric authentication using fingerprints, voice prints, or the like.

FIG. 24B illustrates a notebook information terminal 5200. The notebook information terminal 5200 includes a main body 5201 of the information terminal, a display portion 5202, and a keyboard 5203.

Like the information terminal 5100 described above, when the chip of one embodiment of the present invention is applied to the notebook information terminal 5200, the notebook information terminal 5200 can execute an application utilizing artificial intelligence. Examples of the application utilizing artificial intelligence include design-support software, text correction software, and software for automatic menu generation. Furthermore, with use of the notebook information terminal 5200, novel artificial intelligence can be developed.

Note that although FIG. 24A and FIG. 24B illustrate a smartphone and a notebook information terminal, respectively, as examples of the electronic device in the above description, an information terminal other than a smartphone and a notebook information terminal can be used. Examples of information terminals other than a smartphone and a notebook information terminal include a PDA (Personal Digital Assistant), a desktop information terminal, and a workstation.

### [Game Machine]

FIG. 24C illustrates a portable game machine 5300 as an example of a game machine. The portable game machine 5300 includes a housing 5301, a housing 5302, a housing 5303, a display portion 5304, a connection portion 5305, an operation key 5306, and the like. The housing 5302 and the housing 5303 can be detached from the housing 5301. When the connection portion 5305 provided in the housing 5301 is attached to another housing (not illustrated), an image to be output to the display portion 5304 can be output to another video device (not illustrated). In that case, the housing 5302 and the housing 5303 can each function as an operating unit. Thus, a plurality of players can play a game at the same time. The chip described in the above embodiment can be incorporated into the chip or the like provided on a substrate in the housing 5301, the housing 5302 and the housing 5303.

FIG. 24D illustrates a stationary game machine 5400 as an example of a game machine. A controller 5402 is wired or connected wirelessly to the stationary game machine 5400.

Using the GPU or the chip of one embodiment of the present invention in a game machine such as the portable game machine 5300 and the stationary game machine 5400 achieves a low-power-consumption game machine. Moreover, heat generation from a circuit can be reduced owing to low power consumption; thus, the influence of heat generation on the circuit itself, a peripheral circuit, and a module can be reduced.

Furthermore, when the GPU or the chip of one embodiment of the present invention is applied to the portable game machine 5300, the portable game machine 5300 including artificial intelligence can be achieved.

In general, the progress of a game, the actions and words of game characters, and expressions of an event and the like occurring in the game are determined by the program in the game; however, the use of artificial intelligence in the portable game machine 5300 enables expressions not limited by the game program. For example, it becomes possible to change expressions such as questions posed by the player, the progress of the game, time, and actions and words of game characters.

In addition, when a game requiring a plurality of players is played on the portable game machine 5300, the artificial intelligence can create a virtual game player; thus, the game can be played alone with the game player created by the artificial intelligence as an opponent.

Although the portable game machine and the stationary game machine are shown as examples of game machines in FIG. 24C and FIG. 24D, the game machine using the GPU or the chip of one embodiment of the present invention is not limited thereto. Examples of the game machine to which the GPU or the chip of one embodiment of the present invention is applied include an arcade game machine installed in entertainment facilities (a game center, an amusement park, and the like), and a throwing machine for batting practice installed in sports facilities.

### [Large Computer]

The GPU or the chip of one embodiment of the present invention can be used in a large computer.

FIG. 24E is a diagram illustrating a supercomputer 5500 as an example of a large computer. FIG. 24F is a diagram illustrating a rack-mount computer 5502 included in the supercomputer 5500.

The supercomputer 5500 includes a rack 5501 and a plurality of rack-mount computers 5502. The plurality of computers 5502 are stored in the rack 5501. The computer 5502 includes a plurality of substrates 5504 on which the GPU or the chip shown in the above embodiment can be mounted.

The supercomputer 5500 is a large computer mainly used for scientific computation. In scientific computation, an enormous amount of arithmetic operation needs to be processed at a high speed; hence, power consumption is large and chips generate a large amount of heat. Using the GPU or the chip of one embodiment of the present invention in the supercomputer 5500 achieves a low-power-consumption supercomputer. Moreover, heat generation from a circuit can be reduced owing to low power consumption; thus, the influence of heat generation on the circuit itself, a peripheral circuit, and a module can be reduced.

Although a supercomputer is shown as an example of a large computer in FIG. 24E and FIG. 24F, a large computer using the GPU or the chip of one embodiment of the present invention is not limited thereto. Other examples of large computers in which the GPU or the chip of one embodiment of the present invention is usable include a computer that provides service (a server) and a large general-purpose computer (a mainframe).

### [Moving Vehicle]

The GPU or the chip of one embodiment of the present invention can be applied to an automobile, which is a moving vehicle, and the periphery of a driver's seat in the automobile.

FIG. 24G illustrates an area around a windshield inside an automobile, which is an example of a moving vehicle. FIG. 24G illustrates a display panel 5701, a display panel 5702, and a display panel 5703 that are attached to a dashboard and a display panel 5704 that is attached to a pillar.

The display panel 5701 to the display panel 5703 can provide a variety of kinds of information by displaying a speedometer, a tachometer, mileage, a fuel gauge, a gear state, air-condition setting, or the like. In addition, the content, layout, and the like of the display on the display panels can be changed as appropriate to suit the user's preference, so that the design quality can be increased. The display panel 5701 to the display panel 5703 can also be used as lighting devices.

The display panel 5704 can compensate for view obstructed by the pillar (a blind spot) by showing an image taken by an imaging device (not illustrated) provided for the automobile. That is, displaying an image taken by the imaging device provided outside the automobile leads to compensation for the blind spot and an increase in safety. Display of an image that complements for the area that cannot be seen makes it possible to confirm safety more naturally and comfortably. The display panel 5704 can also be used as a lighting device.

Since the GPU or the chip of one embodiment of the present invention can be applied to a component of artificial intelligence, the chip can be used for an automatic driving system of the automobile, for example. The chip can also be used for a system for navigation, risk prediction, or the like. A structure may be employed in which the display panel 5701 to the display panel 5704 display navigation information, risk prediction information, or the like.

Note that although an automobile is described above as an example of a moving vehicle, the moving vehicle is not limited to an automobile. Examples of the moving vehicle include a train, a monorail train, a ship, and a flying vehicle (a helicopter, an unmanned aircraft (a drone), an airplane, and a rocket), and these moving vehicles can each include a system utilizing artificial intelligence when the chip of one embodiment of the present invention is applied to each of these moving vehicles.

### [Household Appliance]

FIG. 24H illustrates an electric refrigerator-freezer 5800 as an example of a household appliance. The electric refrigerator-freezer 5800 includes a housing 5801, a refrigerator door 5802, a freezer door 5803, and the like.

When the chip of one embodiment of the present invention is applied to the electric refrigerator-freezer 5800, the electric refrigerator-freezer 5800 including artificial intelligence can be achieved. Utilizing the artificial intelligence enables the electric refrigerator-freezer 5800 to have a function of automatically making a menu based on expiration dates of foods stored in the electric refrigerator-freezer 5800 and a function of automatically adjusting temperature to be appropriate for the foods stored in the electric refrigerator-freezer 5800, for example.

Although the electric refrigerator-freezer is described in this example as a household appliance, examples of other household appliances include a vacuum cleaner, a microwave oven, an electric oven, a rice cooker, a water heater, an IH cooker, a water server, a heating-cooling combination appliance such as an air conditioner, a washing machine, a drying machine, and an audio visual appliance.

The electronic devices, the functions of the electronic devices, the application examples of artificial intelligence, their effects, and the like described in this embodiment can be combined as appropriate with the description of another electronic device.

At least part of the structure, method, and the like described in this embodiment can be implemented in appropriate combination with other embodiments, an example, and the like described in this specification.

### Embodiment 6

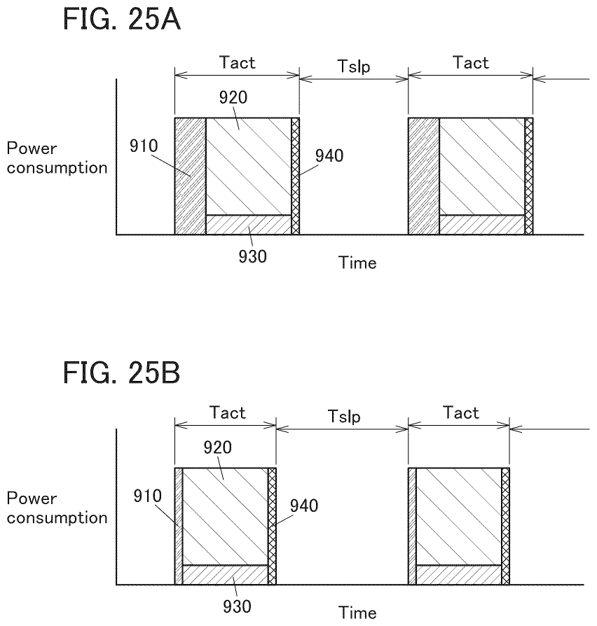

The semiconductor device of one embodiment of the present invention can be suitably used for a processor using power gating that reduces unnecessary power consumption, for example. Furthermore, the semiconductor device of one embodiment of the present invention can be suitably used in a memory using an OSFET (also referred to as an OS memory). More specific structures will be described with reference to FIG. 25A and FIG. 25B.

Power gating is known for reducing unnecessary power consumption by temporarily stopping power supply to an arithmetic circuit that is not operating. A processor using power gating is referred to as a “normally-off processor” or an “Noff processor” in some cases. In a normally-off processor, data necessary in restoration needs to be saved to a nonvolatile memory before power supply is stopped and read in restoration.

As a nonvolatile memory, a flash memory, a ferroelectric memory (FeRAM), and the like are known. These have low access speed and a limited number of times of rewriting, and thus the memories thereof are unsuitable as a nonvolatile memory used for a normally-off processor. Examples of the nonvolatile memory used for the normally-off processor include a magnetoresistive memory (MRAM) including an MTJ element, a resistive random access memory (ReRAM), and a phase change memory (PCM).

An OS memory is suitably used as a nonvolatile memory used for the normally-off processor. An OS memory is a memory element using an OS transistor. As the OS memory, DOSRAM (registered trademark) and NOSRAM (registered trademark) are known.

An OS memory can retain written data for a period of one year or longer, or ten years or longer even after power supply is stopped. In an OS memory, written charge amount is less likely to change over a long period of time; hence, the OS memory can hold multilevel (multibit) data or analog value data as well as binary (1-bit) data.

In the OS memory, charge is written to a node through the OS transistor; hence, a high voltage, which is required for a conventional flash memory, is unnecessary and a high-speed writing operation is possible, for example. The OS memory does not need electric charge injection and electric charge extraction into/from a charge trap layer, which are performed in a flash memory and is not accompanied with a structure change at the atomic level as in an MRAM, a ReRAM, or the like. Thus, the OS memory enables substantially unlimited number of times of data writing and reading, and deteriorates less than the above memories, offering high reliability.

FIG. 25A and FIG. 25B are diagrams showing changes in power consumption of normally-off processors. In FIG. 25A and FIG. 25B, the horizontal axis represents time and the vertical axis represents power consumption. In FIG. 25A and FIG. 25B, the operation period and the stop period (sleep period) of an arithmetic circuit are shown as a period Tact and a period Tslp, respectively.

In FIG. 25A and FIG. 25B, electric power consumed in reading saved data when power supply is restarted is referred to as restoration electric power 910, electric power consumed by the arithmetic circuit in normal operation is referred to as active electric power 920, electric power consumed by leakage current in the normal operation is referred to as leakage electric power 930, and electric power consumed by saving data immediately before the period Tslp is referred to as saving electric power 940. In normal operation, the active electric power 920 and the leakage electric power 930 are consumed. Note that the restoration electric power 910 may be referred to as rising electric power.

FIG. 25A shows changes in power consumption when an MTJ element is used for the nonvolatile memory used for the normally-off processor. FIG. 25B shows changes in power consumption when an OS memory is used for the nonvolatile memory used for the normally-off processor.

Since the MTJ element cannot retain multi-level data and analog data, more time is needed for restoration (i.e., the rise time is long) and more restoration electric power 910 is necessary than the normally-off processor using the OS memory, which is capable of retaining multi-level data and analog data. By contrast, in the normally-off processor using the OS memory, data can be restored in a short time (i.e., the rise time is short) and a high voltage is not necessary for data reading and writing. With use of the OS memory, a normally-off processor with lower power consumption can be achieved.

### Example

### <High-Temperature Characteristics of CAAC-OS FET>

A field-effect OS transistor (hereinafter, referred to as a CAAC-OS FET) that can be provided in the semiconductor device of one embodiment of the present invention has low temperature dependence and can operate stably even in a high-temperature environment. In this example, an experiment on high-temperature characteristics of the CAAC-OS FET and the results thereof will be described.

The CAAC-OS FET can be manufactured by a BEOL (Back End Of Line) process in a semiconductor manufacturing process for CMOS or the like. Thus, stacking with a Si transistor (in this example, among Si transistors, a field-effect Si transistor is also referred to as a “Si FET”) is possible. For example, a circuit that requires high-speed operation can be formed by a Si FET process, and a circuit that requires low leakage current can be formed by a CAAC-OS FET process.

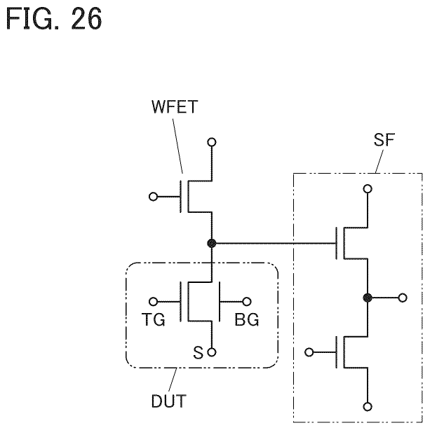

The off-state current of the Si FET increases as the temperature increases, whereas the off-state current of the CAAC-OS FET is always below the measurement limit. Accordingly, the temperature characteristics of the off-state current of a Si FET with L (channel length)/W (channel width)=60 nm/120 nm and the off-state current of a CAAC-OS FET with L/W=21 nm/25 nm were compared. The off-state current of both FETs was measured using the circuit illustrated in FIG. 26.

A circuit illustrated in FIG. 26 includes an FET serving as a DUT (Device Under Test), a writing transistor WFET, and a read circuit SF. The writing transistor WFET is a CAAC-OS FET. The read circuit SF includes CAAC-OS FETs connected in series. A terminal S of the FET serving as the DUT functions as a terminal to which a source voltage is input. Note that a CAAC-OS FET including a top gate TG and a back gate BG is illustrated as the DUT in FIG. 26. In practice, 20000 CAAC-OS FETs were connected in parallel as the DUT. Note that in the case where the DUT is a Si FET, the structure is not limited thereto.

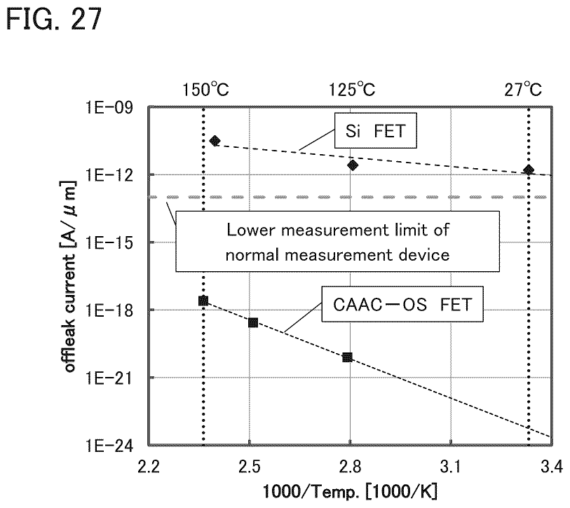

In the case where a Si FET was the DUT in FIG. 26, the measurement conditions of the off-state current of the Si FET were as follows: a gate voltage V_{G}=−0.4 V, a source voltage V_{S}=0 V, a drain voltage V_{D}=1.2 V, and a body voltage V_{B}=0 V. In the case where a CAAC-OS FET was the DUT in FIG. 26, the measurement conditions of the off-state current of the CAAC-OS FET were as follows: the gate voltage V_{G}=−1.0 V, the source voltage V_{S}=0 V, the drain voltage V_{D}=1.2 V, and a back gate voltage V_{BG}=−5.0 V. FIG. 27 shows the measurement results. In FIG. 27, the horizontal axis represents 1000/absolute temperature (Temp.), and the vertical axis represents off-state current (offleak current). Note that in FIG. 27, a broken line denoted by 1.0×10⁻¹³ A/μm is a lower measurement limit of a normal measurement device.

As shown in FIG. 27, the off-state current of the Si FET was approximately 3.1×10⁻¹¹ A/μm at a measurement temperature of 144° C. In a measurement temperature of 150° C., the off-state current of the CAAC-OS FET was approximately 2.5×10⁻¹⁸ A/μm. The CAAC-OS FET can maintain a low off-state current even in a high-temperature environment. By adjusting the back gate voltage, the off-state current can be further reduced.

### REFERENCE NUMERALS

10A: semiconductor device, 10B: semiconductor device, 10: semiconductor device, 11: layer, 12: layer, 20r: memory portion, 20w: memory portion, 20: memory portion, 21A: memory circuit, 21B: memory circuit, 21C: memory circuit, 21E: memory circuit, 21F: memory circuit, 21G: memory circuit, 21H: memory circuit, 21r: circuit, 21w: circuit, 21: memory circuit, 31n: word line driver circuit, 31p: word line driver circuit, 31: word line driver circuit, 32n: bit line driver circuit, 32p: bit line driver circuit, 32: bit line driver circuit, 33n: control circuit, 33p: control circuit, 33: control circuit, 34n: communication circuit, 34p: communication circuit, 34: communication circuit, 35n: input/output circuit, 35p: input/output circuit, 35: input/output circuit, 41n: transistor, 41p: transistor, 100: capacitor, 110: conductor, 112: conductor, 120: conductor, 130: insulator, 150: insulator, 200: transistor, 205a: conductor, 205b: conductor, 205: conductor, 210: insulator, 212: insulator, 214: insulator, 216: insulator, 217: insulator, 218: conductor, 222: insulator, 224: insulator, 230a: metal oxide, 230b: metal oxide, 230ba: region, 230bb: region, 230bc: region, 230: metal oxide, 240a: conductor, 240b: conductor, 240: conductor, 241a: insulator, 241b: insulator, 241: insulator, 242a: conductor, 242b: conductor, 242: conductor, 244a: layer, 244b: layer, 246a: conductor, 246b: conductor, 246: conductor, 250a: insulator, 250b: insulator, 250: insulator, 252: insulator, 254: insulator, 256: insulator, 260a: conductor, 260b: conductor, 260: conductor, 271a: insulator, 271b: insulator, 271: insulator, 274: insulator, 275: insulator, 280: insulator, 282: insulator, 283: insulator, 285: insulator, 300: transistor, 310: substrate, 312: element isolation layer, 313: semiconductor region, 314a: low-resistance region, 314b: low-resistance region, 315: insulator, 316: conductor, 320: insulator, 322: insulator, 324: insulator, 326: insulator, 328: conductor, 330: conductor, 350: insulator, 352: insulator, 354: insulator, 356: conductor, 700: electronic component, 702: printed circuit board, 704: circuit board, 711: mold, 712: land, 713: electrode pad, 714: wire, 720: memory device, 721: driver circuit layer, 722: memory circuit layer, 730: electronic component, 731: interposer, 732: package board, 733: electrode, 735: semiconductor device, 910: restoration electric power, 920: active electric power, 930: leakage electric power, 940: saving electric power, 1100: USB memory, 1101: housing, 1102: cap, 1103: USB connector, 1104: substrate, 1105: memory chip, 1106: controller chip, 1110: SD card, 1111: housing, 1112: connector, 1113: substrate, 1114: memory chip, 1115: controller chip, 1150: SSD, 1151: housing, 1152: connector, 1153: substrate, 1154: memory chip, 1155: memory chip, 1156: controller chip, 1200: chip, 1201: package board, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5100: information terminal, 5101: housing, 5102: display portion, 5200: notebook information terminal, 5201: main body, 5202: display portion, 5203: keyboard, 5300: portable game machine, 5301: housing, 5302: housing, 5303: housing, 5304: display portion, 5305: connection portion, 5306: operation key, 5400: stationary game machine, 5402: controller, 5500: supercomputer, 5501: rack, 5502: computer, 5504: substrate, 5701: display panel, 5702: display panel, 5703: display panel, 5704: display panel, 5800: electric refrigerator-freezer, 5801: housing, 5802: refrigerator door, 5803: freezer door

1. A semiconductor device comprising:
a first layer; and
a second layer over the first layer,
wherein the first layer comprises a p-channel first transistor comprising silicon in a first channel formation region,
wherein the second layer comprises an n-channel second transistor comprising a metal oxide in a second channel formation region,
wherein the first transistor and the second transistor form a CMOS circuit, and
wherein a channel length of the first transistor is longer than a channel length of the second transistor.

2. A semiconductor device comprising:
a first layer; and
a second layer over the first layer,
wherein the first layer comprises a p-channel first transistor comprising silicon in a first channel formation region,
wherein the second layer comprises an n-channel second transistor comprising a metal oxide in a second channel formation region,
wherein the first transistor and the second transistor form a CMOS circuit,
wherein a channel length of the first transistor is longer than a channel length of the second transistor,
wherein the channel length of the first transistor is greater than or equal to 15 nm, and
wherein the channel length of the second transistor is less than 15 nm.

3. A semiconductor device comprising:
a first layer; and
a second layer over the first layer,
wherein the first layer comprises a p-channel first transistor comprising silicon in a first channel formation region,
wherein the second layer comprises an n-channel second transistor comprising a metal oxide in a second channel formation region,
wherein the first transistor and the second transistor form a CMOS circuit,
wherein a channel length of the first transistor is longer than a channel length of the second transistor,
wherein the channel length of the first transistor is greater than or equal to 15 nm and less than or equal to 40 nm, and
wherein the channel length of the second transistor is greater than or equal to 3 nm and less than 15 nm.

4. The semiconductor device according to claim 1,
wherein the first layer comprises a single crystal silicon substrate, and
wherein the first transistor comprises the first channel formation region in the single crystal silicon substrate.

5. The semiconductor device according to claim 1, wherein the second layer comprises a memory circuit.

6. The semiconductor device according to claim 5,
the memory circuit further comprising:
a third transistor;
a fourth transistor, and
a capacitor,
wherein one of a source and a drain of the third transistor is electrically connected to a gate of the fourth transistor, and
wherein the gate of the fourth transistor is electrically connected to one electrode of the capacitor.

7. The semiconductor device according to claim 6,
wherein the third transistor and the fourth transistor each comprise the metal oxide of the second channel formation region in a channel formation region.

8. An electronic device comprising:
the semiconductor device according to claim 1, and
a display portion.

9. The semiconductor device according to claim 2,
wherein the first layer comprises a single crystal silicon substrate, and
wherein the first transistor comprises the first channel formation region in the single crystal silicon substrate.

10. The semiconductor device according to claim 2,
wherein the second layer comprises a memory circuit.

11. An electronic device comprising:
the semiconductor device according to claim 2; and
a display portion.

12. The semiconductor device according to claim 3,
wherein the first layer comprises a single crystal silicon substrate, and
wherein the first transistor comprises the first channel formation region in the single crystal silicon substrate.

13. The semiconductor device according to claim 3,
wherein the second layer comprises a memory circuit.

14. An electronic device comprising:
the semiconductor device according to claim 3; and
a display portion.
